(19) United States
(12) Patent Application Publication
(10) Pub. No.: US 2019/0324598 A1
(43) Pub. Date: Oct. 24, 2019

(54) OPTICAL FILM AND FRONT PANEL OF IMAGE DISPLAY APPARATUS, IMAGE DISPLAY APPARATUS, MIRROR WITH IMAGE DISPLAY FUNCTION, RESISTIVE FILM-TYPE TOUCH PANEL, AND CAPACITANCE-TYPE TOUCH PANEL HAVING OPTICAL FILM

(71) Applicant: FUJIFILM Corporation, Tokyo (JP)

(72) Inventors: Keigo UEKI, Kanagawa (JP); Takashi TAMADA, Kanagawa (JP); Akio TAMURA, Kanagawa (JP); Yutaka NOZOE, Kanagawa (JP); Yuki NAKAZAWA, Kanagawa (JP); Yuichi FUKUSHIGE, Kanagawa (JP); Katsuyuki TAKADA, Kanagawa (JP)

(73) Assignee: FUJIFILM Corporation, Tokyo (JP)

(21) Appl. No.: 16/450,133

(22) Filed: Jun. 24, 2019

Related U.S. Application Data
(63) Continuation of application No. PCT/JP2018/007666, filed on Mar. 1, 2018.

(30) Foreign Application Priority Data
Mar. 3, 2017 (JP) 2017-041156
Apr. 11, 2017 (JP) 2017-078486
Sep. 20, 2017 (JP) 2017-180717
Nov. 17, 2017 (JP) 2017-222140

(51) Int. Cl. G06F 3/044; G02F 1/1333; B32B 27/08; B32B 23/20; B32B 23/08; B32B 7/12; B32B 27/20

(52) U.S. Cl. CPC G06F 3/0446; B32B 2255/10; B32B 27/08; B32B 23/20; B32B 23/08; B32B 7/12; B32B 27/20; G02F 2001/133331; G02F 2201/50; G02F 1/13338; G06F 2203/04112; B32B 2551/00; B32B 2457/20; B32B 2264/107; B32B 2255/26; G02F 1/133308

(57) ABSTRACT

An optical film has a resin film and a hardcoat layer disposed on one surface of the resin film, in which the hardcoat layer contains a polysiloxane-containing compound and a fluorine-containing compound, and a film thickness of the resin film is equal to or greater than 80 μm.

### CROSS-REFERENCE TO RELATED APPLICATIONS

This application is a Continuation of PCT International Application No. PCT/JP2018/007666, filed on Mar. 1, 2018, which claims priority under 35 U.S.C. § 119(a) to Japanese Patent Application No. 2017-041156, filed on Mar. 3, 2017, Japanese Patent Application No. 2017-078486, filed on Apr. 11, 2017, Japanese Patent Application No. 2017-180717, filed on Sep. 20, 2017, and Japanese Patent Application No. 2017-222140, filed on Nov. 17, 2017. Each of the above application(s) is hereby expressly incorporated by reference, in its entirety, into the present application.

### BACKGROUND OF THE INVENTION

### 1. Field of the Invention

The present invention relates to an optical film and a front panel of an image display apparatus using the laminate, an image display apparatus, a mirror with an image display function, a resistive film-type touch panel, and a capacitance-type touch panel which have the optical film.

### 2. Description of the Related Art

In the related art, as an optical film for a front panel of an image display apparatus, particularly, a front panel of a touch panel or the like that is required to have high durability, glass such as chemically strengthened glass has been used. In recent years, various functionalities (lightweightness, toughness (breakproofness), thin film workability (capable of being thinned), and the like) of resin films have drawn attention, and it has been expected that the use of the resin films as substitute materials for glass could improve the functionality of optical films.

As a resin film which is a substitute material for glass, for example, JP2016-164641A describes a hardcoat film comprising a substrate and a hardcoat layer which is laminated on at least one surface of the substrate, in which a retardation in an in-plane direction is equal to or greater than 6,000 nm and equal to or smaller than 40,000 nm. Furthermore, JP2014-113705A describes a laminate in which a plurality of sheets of resin films with a hardcoat layer are laminated, in which each of the resin films with a hardcoat layer comprises a base layer containing a thermoplastic resin and a hardcoat layer containing a curable resin formed on the base layer.

### SUMMARY OF THE INVENTION

For a resin film used in the surface of a front panel of a touch panel or the like, it is important that the resin film has both the keystroke durability, which prevents the resin film from being broken or depressed no matter how many times the resin film is struck with a member such as a stylus pen, and rub resistance which makes it difficult for the resin film to be scratched even in a case where the resin film is rubbed against a hard object such as steel wool.

As a result of conducting an intensive examination, the inventors of the present invention have found that in a case where the film thickness of the resin film is increased, even though keystrokes are repeatedly performed using a member such as a stylus pen, a recess defect hardly occurs. Meanwhile, the inventors have also found that in a case where keystrokes are repeatedly performed using a member such as a stylus pen, contaminants derived from the stylus pen or the like adhere to the surface of the resin film, which leads to a new problem in which the contaminants are observed as a surface shape defect.

The present invention has been made in consideration of the above problem, and an object of the present invention is to provide an optical film, which can sufficiently inhibit both the occurrence of recesses after keystrokes and the adhesion of contaminants after keystrokes and has excellent rub resistance, and a front panel of an image display apparatus, an image display apparatus, a mirror with an image display function, a resistive film-type touch panel, and a capacitance-type touch panel which have the optical film.

That is, the object was achieved by the following means.
(1) An optical film having a resin film and a hardcoat layer disposed on one surface of the resin film in which the hardcoat layer contains a polysiloxane-containing compound and a fluorine-containing compound, and a film thickness of the resin film is equal to or greater than 80 μm.
(2) The optical film described in (1), in which within a surface of the hardcoat layer that is opposite to the resin film a surface roughness Sa in a visual field of 4 mm×5 mm for measurement is equal to or lower than 60 nm.
(3) The optical film described in (1) or (2), in which the hardcoat layer is formed by polymerizing and curing the polysiloxane-containing compound having a polymerizable group in a molecule, the fluorine-containing compound having a polymerizable group in a molecule, and a polymerizable compound which is neither the polysiloxane-containing compound nor the fluorine-containing compound and has a polymerizable group in a molecule.
(4) The optical film described in (3), in which the polymerizable group that each of the polysiloxane-containing compound, the fluorine-containing compound, and the polymerizable compound has is a radically polymerizable group.
(5) The optical film described in any one of (1) to (4), in which the film thickness of the resin film is equal to or greater than 100 μm.
(6) The optical film described in any one of (1) to (5), in which the film thickness of the resin film is equal to or greater than 150 μm.
(7) The optical film described in any one of (1) to (6), in which the film thickness of the resin film is equal to or greater than 200 μm.
(8) The optical film described in any one of (1) to (7), in which the resin film contains a cellulose ester resin.
(9) The optical film described in any one of (1) to (8), further having a cushioning layer on a surface of the resin film that is opposite to the surface of the resin film that is provided with the hardcoat layer.
(10) The optical film described in (9), in which the cushioning layer is constituted with at least one kind of resin selected from a urethane-modified polyester resin and a urethane resin.
(11) The optical film described in (9), in which provided that a ratio of a loss modulus to a storage modulus is represented by tan δ, the cushioning layer has a peak of tan δ within a frequency range of 10 to 10¹⁵ Hz at 25° C.
(12) The optical film described in (11), in which the cushioning layer is constituted with at least one kind of resin selected from a (meth)acrylate resin and an elastomer.
(13) The optical film described in (11) or (12), in which the cushioning layer contains at least one kind of copolymer selected from a block copolymer of methyl methacrylate and n-butyl acrylate and a block copolymer of isoprene and/or butene and styrene.
(14) The optical film described in any one of (11) to (13), in which the cushioning layer is further constituted with a polymerizable group-containing compound.
(15) The optical film described in any one of (1) to (14), in which the hardcoat layer further contains inorganic particles, and a content rate of the inorganic particles in the hardcoat layer is less than 8% by mass.
(16) The optical film described in any one of (9) to (15), in which the cushioning layer contains a filler.
(17) The optical film described in (16), in which the filler is silica particles.
(18) A front panel of an image display apparatus comprising the optical film described in any one of (1) to (17).
(19) An image display apparatus comprising the front panel described in (18) and an image display device.
(20) The image display apparatus described in (19), in which the image display device is a liquid crystal display device.
(21) The image display apparatus described in (19), in which the image display device is an organic electroluminescence display device.
(22) The image display apparatus described in any one of (19) to (21), in which the image display device is an in-cell touch panel display device.
(23) The image display apparatus described in any one of (19) to (21), in which the image display device is an on-cell touch panel display device.
(24) A resistive film-type touch panel comprising the front panel described in (18).
(25) A capacitance-type touch panel comprising the front panel described in (18).
(26) A mirror with an image display function comprising the image display apparatus described in any one of (19) to (23).

In the present specification, in a case where there is a plurality of substituents, linking groups, repeating structures, and the like (hereinafter, referred to as substituents and the like) represented by specific references or in a case where a plurality of substituents and the like are collectively defined, unless otherwise specified, the substituents and the like may be the same as or different from each other. The same is true for a case where the number of substituents and the like is defined. Furthermore, in a case where a plurality of substituents and the like are close to each other (particularly, adjacent to each other), unless otherwise specified, the substituents may form a ring by being linked to each other. In addition, rings such as an aliphatic ring, an aromatic ring, and a heterocyclic ring may form a fused ring by being further fused.

In the present specification, in a case where the number of carbon atoms in a certain group is defined, the number of carbon atoms means the total number of carbon atoms in the group. That is, in a case where the group further has a substituent, the number of carbon atoms means the total number of carbon atoms including the number of carbon atoms in the substituent.

In the present specification, a range of numerical values described using “to” means a range including numerical values listed before and after “to” as an upper limit and a lower limit respectively.

In the present specification, “(meth)acrylate” means “either or both of acrylate and methacrylate”. Furthermore, “(meth)acryloyl group” means “either or both of an acryloyl group and a methacryloyl group”, and “(meth)acryl” means “either or both of acryl and methacryl”.

In the present specification, “(co)polymer” means “either or both of a homopolymer and a copolymer”.

Regarding each component described in the present specification, one kind of the component may be used singly, or two or more kinds of the components having different structures may be used in combination. Regarding the content of each component, in a case where two or more kinds of the components having different structures are used in combination, the content means the total content thereof.

In the present specification, unless otherwise specified, a weight-average molecular weight (Mw) can be measured by GPC as a molecular weight expressed in terms of polystyrene. At this time, by using HLC-8220 (manufactured by Tosoh Corporation) as a GPC apparatus and using G3000HXL+G2000HXL as columns, the weight-average molecular weight is measured by detecting RI at 23° C. and a flow rate of 1 mL/min. The eluent can be selected from tetrahydrofuran (THF), chloroform, N-methyl-2-pyrrolidone (NMP), and m-cresol/chloroform (manufactured by Shonan Wako Junyaku K.K.). As the eluent, THF can be used as long as it dissolves a sample.

In the present specification, the thickness and the tensile modulus of each layer are measured by the methods described in Examples.

The optical film according to the embodiment of the present invention can be suitably used as a front panel of a touch panel and the like. Furthermore, the optical film according to the embodiment of the present invention can also be suitably used as an optical film such as a polarizing film, a phase difference film, or a brightness enhancement film for liquid crystal display.

The optical film according to an embodiment of the present invention can sufficiently inhibit both the occurrence of recesses after keystrokes and the adhesion of contaminants after keystrokes and has excellent rub resistance. Therefore, the optical film can be suitably used as a front panel of a touch panel and the like. Furthermore, the front panel of an image display apparatus, the image display apparatus, the mirror with an image display function, the resistive film-type touch panel, and the capacitance-type touch panel according to the embodiment of the present invention have the optical film according to the embodiment of the present invention. Accordingly, in the front panel, the image display apparatus, the mirror, the resistive film-type touch panel, and the capacitance-type touch panel, the occurrence of recesses after keystrokes and the adhesion of contaminants after keystrokes are sufficiently inhibited, and excellent rub resistance can be exhibited.

### BRIEF DESCRIPTION OF THE DRAWINGS

FIG. 1 is a vertical cross-sectional view showing an embodiment of the constitution of an optical film of the present invention.

FIG. 2 is a vertical cross-sectional view showing an embodiment of the constitution of the optical film of the present invention having a pressure sensitive adhesive layer.

FIG. 3 is a schematic cross-sectional view showing an embodiment of a capacitance-type touch panel.

FIG. 4 is a schematic view of a conductive film for a touch panel.

FIG. 5 is a schematic view showing portions in which a first electrode 11 and a second electrode 21 in FIG. 4 cross each other.

FIG. 6 is a schematic view showing an embodiment of a first dummy electrode 11A that a first conductive layer 8 in an active area S1 in FIG. 4 may have.

FIG. 7 is a cross-sectional view schematically showing a laminated structure used in Test Example 6 in Examples including a base.

FIG. 8 is a cross-sectional view schematically showing a laminated structure used in Test Example 7 in Examples including a base.

### DESCRIPTION OF THE PREFERRED EMBODIMENTS

Preferred embodiments of the optical film of the present invention will be described.

[Optical Film]

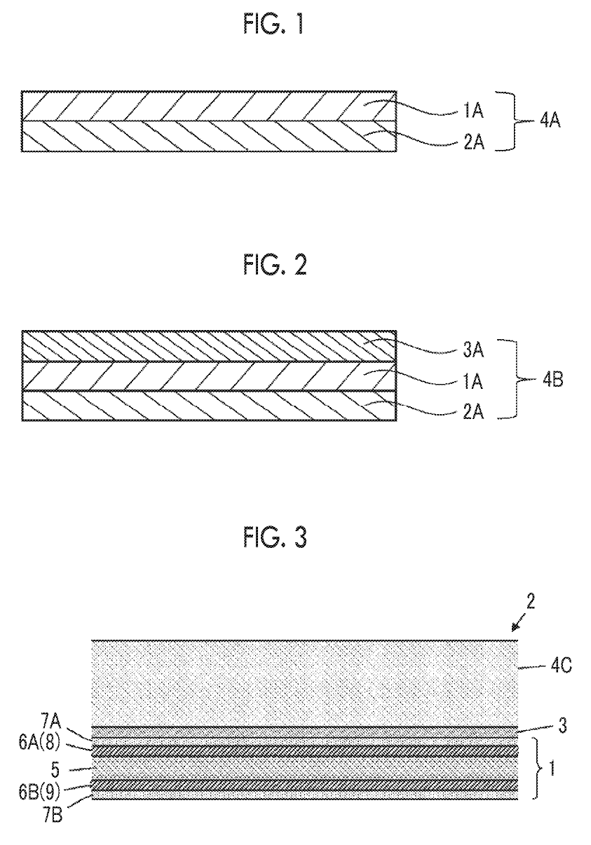

FIG. 1 shows a preferred embodiment of the optical film the present invention. An optical film 4A shown in FIG. 1 is an optical film having a resin film 1A and a hardcoat layer (hereinafter, referred to as “HC layer” as well) 2A disposed on one surface of the resin film 1A. In the optical film according to an embodiment of the present invention, the HC layer contains a polysiloxane-containing compound and a fluorine-containing compound, and a film thickness of the resin film is equal to or greater than 80 μm.

Because the optical film according to the embodiment of the present invention is constituted as above, the optical film can realize excellent keystroke durability which can sufficiently inhibit the occurrence of recesses after keystrokes, can realize excellent post-keystroke adhesion resistance which can sufficiently inhibit the adhesion of contaminants after keystrokes, and can realize excellent rub resistance.

The resin films and the HC layer may be isotropic or anisotropic.

In the optical film according to the embodiment of the present invention, the resin film, the hardcoat layer, and the like may be constituted with a single layer or multiple layers.

(Film Thickness of Optical Film)

In view of keystroke durability, the film thickness of the optical film according to the embodiment of the present invention is preferably equal to or greater than 120 μm, more preferably equal to or greater than 150 μm, even more preferably equal to or greater than 180 μm, and still more preferably equal to or greater than 220 μm. The upper limit thereof is substantially equal to or smaller than 320 μm.

(Retardation in in-Plane Direction)

In view of reducing the interference unevenness, the retardation of the optical film in an in-plane direction at a wavelength of 550 nm is preferably smaller than 6,000 nm, more preferably equal to or smaller than 1,000 nm, even more preferably equal to or smaller than 500 nm, and still more preferably equal to or smaller than 50 nm.

The phase difference (retardation) of the optical film in the in-plane direction is defined as below. Linear polarization is allowed to come into the optical film, and then the light passing through the optical film is decomposed into two linear polarizations polarized along a fast axis and a slow axis. At this time, a refractive index on the fast axis is represented by Nx, a refractive index on the slow axis is represented by Ny, and the thickness of the optical film is represented by d (unit: nm). From Nx, Ny, and d, R (unit: nm) defining the retardation is calculated by Equation (A).

R=dx(Nx−Ny) (A)

In the present invention, the retardation in the in-plane direction at a wavelength of 550 nm is measured by allowing light having a wavelength of 550 nm to come into a film or layer, which is a measurement target, along a normal direction of the film or the layer by using KOBRA 21ADH (manufactured by Oji Scientific Instruments). At the time of selecting a measurement wavelength, by manually replacing the wavelength-selective filter or by converting the measured value by using a program or the like, the retardation can be measured. The retardation in the in-plane direction can also be measured using AxoScan (manufactured by Axometrics, Inc).

Hereinafter, the components and the preparation methods of the films and the layers constituting the optical film according to the embodiment of the present invention will be specifically described.

(1) Resin Film

(Material of Resin Film)

The materials of the resin film used in the present invention are not particularly limited.

Examples of the resin film include an acrylic resin film, a polycarbonate (PC)-based resin film, a cellulose ester-based resin film such as a triacetyl cellulose (TAC)-based resin film, a polyethylene terephthalate (PET)-based resin film, a polyolefin-based resin film, a polyester-based resin film, and an acrylonitrile-butadiene-styrene copolymer film. Among these, a film selected from an acrylic resin film, a cellulose ester-based resin film, a polyethylene terephthalate-based resin film and a polycarbonate-based resin film is preferable. In view of moisture permeability, a cellulose ester-based resin film is more preferable, and cellulose acetate is even more preferable.

The acrylic resin film refers to a resin film of a polymer or a copolymer formed of one or more kinds of compounds selected from the group consisting of an acrylic acid ester and a methacrylic acid ester. Examples of the acrylic resin film include a polymethyl methacrylate resin (PMMA) film.

In view of increasing the tensile modulus, the weight-average molecular weight of the resin is preferably 10,000 to 1,000,000, and more preferably 100,000 to 1,000,000.

(Constitution of Resin Film)

The constitution of the resin film is not limited. The resin film may be a single layer or a laminated film including two or more layers, and is preferably a laminated film including two or more layers. The number of layers laminated to constitute the laminated film is preferably 2 to 10, more preferably 2 to 5, and even more preferably 2 or 3. In a case where the resin film includes three or more layers, it is preferable that outer layers and layers (core layers and the like) other than the outer layers are films of different compositions. Furthermore, it is preferable that the outer layers are films of the same composition.

Specifically, examples thereof include films having laminated structures of TAC-a/TAC-b/TAC-a, acryl-a/PC/acryl-a, and PET-a/PET-b/PET-a, and a film constituted with one polycarbonate-based resin layer. Herein, the films (for example, TAC-a) marked with the same reference (a or b) are films of the same composition.

(Additives)

The resin film may contain additives in addition to the resin described above. Examples of the additives include inorganic particles, matt particles, an ultraviolet absorber, a fluorine-containing compound, a surface conditioner, a leveling agent, and the like described later regarding the hardcoat layer which will be described later.

In a melt film-forming method which will be described later, a molten resin obtained by mixing and melting the aforementioned additives and resin together can be used for forming the resin film. In a solution film-forming method which will be described later, a dope solution obtained by mixing a solvent (description regarding a hardcoat which will be described later can be adopted), the resin, and the above additives together can be used for forming the resin film.

(Tensile Modulus of Resin Film)

The tensile modulus of a resin film can be changed, for example, according to the type of resin constituting the resin film. Generally, in a case where either or both of the molecular weight and degree of crystallinity of the resin are increased, the tensile modulus tends to be increased. Furthermore, by stretching the resin film, the tensile modulus of the resin film in the stretching direction can be increased. In a case where the resin film is constituted with multiple layers, the tensile modulus means the total tensile modulus of the resin film.

In view of further improving the keystroke durability, the tensile modulus of the resin film at 25° C. is preferably equal to or higher than 2.0 GPa, more preferably equal to or higher than 2.5 GPa, even more preferably equal to or higher than 3.0 GPa, particularly preferably equal to or higher than 3.5 GPa, and most preferably equal to or higher than 4.0 GPa. The upper limit thereof is not particularly limited, but is substantially equal to or lower than 12.0 GPa.

“Tensile modulus” of the resin film can be tested and calculated by the following method according to the method described in JIS K7127.

The resin film having a width of 1 cm is cut in a length of 15 cm in a measurement direction. The cut sample for measurement is installed in a tensile tester (manufactured by Toyo Seiki Seisaku-sho, Ltd., trade name “STROGRAPH-R2”) such that a chuck interval in the measurement direction becomes 10 cm. Under the condition of a measurement temperature of 25° C., the resin film is stretched at a stretching speed of 10 mm/min such that the chuck interval increased, thereby obtaining a stress-strain curve. By the linear regression of a curve between two specified points at strains as ε₁=0.0005 and ε₂=0.0025, a tensile modulus at 25° C. is calculated.

In a case where the resin film is anisotropic, the average of a tensile modulus of a sample for measurement whose long side extends in an alignment direction, along which a degree of alignment becomes the highest, within a surface perpendicular to the thickness direction of the resin film and a tensile modulus of a sample for measurement whose long side extends in a direction orthogonal to the alignment direction is adopted as a tensile modulus of the resin film.

(Film Thickness)

In view of inhibiting the occurrence of recesses after keystrokes, the film thickness of the resin film is equal to or greater than 80 μm, preferably equal to or greater than 100 μm, more preferably equal to or greater than 150 μm, and even more preferably equal to or greater than 200 μm. The upper limit thereof is not particularly limited, but is preferably equal to or smaller than 320 μm. In a case where the resin film is a laminated film including two or more layers, the film thickness of the resin film means the total film thickness of the laminated film.

Before and after the optical film according to the embodiment of the present invention is prepared, the thickness of the resin film substantially does not change.

(Easily Adhesive Layer)

The resin film used in the present invention may have an easily adhesive layer. For the easily adhesive layer, the details of an easily adhesive layer on a polarizer side and a manufacturing method of the easily adhesive layer on a polarizer side described in paragraphs “0098” to “0133” in JP2015-224267A can be combined with the present invention and incorporated into the present specification.

In this case, the easily adhesive layer means a layer constituting the resin film in the optical film according to the embodiment of the present invention.

(Method for Forming Resin Film)

The resin film may be formed by any method. For example, a melt film-forming method and a solution film-forming method can be used.

<Melt Film-Forming Method and Smoothing>

In a case where the resin film is formed by a melt film-forming method, the method preferably includes a melting step of melting a resin by using an extruder, a step of extruding the molten resin in the form of a sheet from a die, and a step of forming the resin into a film. Depending on the material of the resin, a step of filtering the molten resin may be performed after the melting step, or the molten resin may be cooled at the time of being extruded in the form of a sheet.

Hereinafter, the melt film-forming method will be specifically described, but the present invention is not limited thereto.

[Method for Forming Resin Film]

The method for manufacturing the resin film includes a melting step of melting a resin by using an extruder, a filtering step of filtering the molten resin through a filtering apparatus equipped with a filter, a film forming step of forming a non-stretched resin film by extruding the filtered resin in the form of a sheet from a die and then bringing the resin into close contact with the surface of a cooling drum so as to cool and solidify the resin, and a stretching step of uniaxially or biaxially stretching the non-stretched resin film.

The resin film can be manufactured by the above constitution. It is preferable that the pore size of the filter used in the filtering step of the molten resin is equal to or smaller than 1 m, because then foreign substances can be thoroughly removed, and as a result, the surface roughness of the obtained resin film in the film width direction can be controlled.

Specifically, the method for forming the resin film can include the following steps.

<Melting Step>

The method for manufacturing the resin film includes a melting step of melting a resin by using an extruder.

It is preferable that a resin or a mixture of a resin and additives is dried until the moisture content becomes equal to or lower than 200 ppm and then melted by being introduced into a single screw (one screw) or double screw extruder. At this time, in order to inhibit the decomposition of the resin, it is also preferable to melt the resin or the mixture in nitrogen or a vacuum. Specifically, the melting can be performed according to JP4962661B by adopting the conditions described in paragraphs “0051” and “0052” in the same publication (paragraphs “0085” and “0086” in US2013/0100378). The details described in the publication are incorporated into the present specification.

As the extruder, a single screw kneading extruder is preferable.

Furthermore, in order to improve transport accuracy of the molten resin (melt), it is preferable to use a gear pump.

<Filtering Step>

The method for manufacturing the resin film includes a filtering step of filtering the molten resin through a filtering apparatus equipped with a filter. The pore size of the filter used in a filtering step is preferably equal to or smaller than 1 μm.

As the filtering apparatus used in the filtering step that includes a filter having a pore size within the above range, one set of filtering apparatus or two or more sets of filtering apparatuses may be provided.

<Film Forming Step>

The method for manufacturing the resin film includes a film forming step of forming a non-stretched resin film by extruding the filtered resin in the form of a sheet from a die and bringing the resin into close contact with the surface of a cooling drum so as to cool and solidify the resin.

In a case where the resin (melt containing the resin), which has been melted (and kneaded) and filtered, is extruded in the form of a sheet from a die, the resin may be extruded as a single layer or multiple layers. In a case where the resin is extruded as multiple layers, for example, a layer containing an ultraviolet absorber and a layer free of an ultraviolet absorber may be laminated. It is more preferable to adopt a three-layer constitution in which a layer containing an ultraviolet absorber becomes an inner layer, because such a constitution can inhibit a polarizer from deteriorating due to ultraviolet rays and can inhibit the bleed out of the ultraviolet absorber.

In a case where the resin film is manufactured by being extruded as multiple layers, the thickness of the inner layer of the obtained resin film with respect to the total thickness of all the layers is preferably equal to or higher than 50% and equal to or lower than 99%, more preferably equal to or higher than 60% and equal to or lower than 99%, and even more preferably equal to or higher than 70% and equal to or lower than 99%. These layers can be laminated by using a feed block die or a multi-manifold die.

The non-stretched resin film (original film) is preferably obtained by extruding the resin (melt containing the resin), which has been extruded in the form of a sheet from a die, on a cooling drum (casting drum) and cooling and solidifying the resin according to paragraph “0059” in JP2009-269301A.

In the method for manufacturing the resin film, the temperature of the resin extruded from a die is preferably equal to or higher than 280° C. and equal to or lower than 320° C., and more preferably equal to or higher than 285° C. and equal to or lower than 310° C. It is preferable that the temperature of the resin extruded from a die in the melting step is equal to or higher than 280° C., because then the occurrence of foreign substances can be inhibited by the reduction of melting residues of the raw material resin. Furthermore, it is preferable that the temperature of the resin extruded from a die in the melting step is equal to or lower than 320° C., because then the occurrence of foreign substances can be inhibited by suppressing the decomposition of the resin.

The temperature of the resin extruded from a die can be measured on the surface of the resin in a non-contact manner by using a radiation thermometer (manufactured by Hayashi Denko co ltd., model number: RT61-2, used at a radiation factor of 0.95).

In a case where the resin is brought into close contact with the surface of the cooling drum in the film forming step of the method for manufacturing the resin film, it is preferable to use a static electricity applying electrode. In a case where such an electrode is used, the resin can be strongly brought into close contact with the surface of the cooling drum such that the film surface is not destroyed.

In the method for manufacturing the resin film, at the time of bringing the resin into close contact with the surface of the cooling drum (at a point in time when the molten resin having been extruded from a die contacts the cooling drum for the first time), the temperature of the resin is preferably equal to or higher than 280° C. In a case where the temperature of the resin is as described above, the electrical conductivity of the resin is improved, the resin can be strongly brought into close contact with the cooling drum by applying static electricity, and the destruction of the film surface can be inhibited.

The temperature of the resin at the time of bringing the resin into close contact with the surface of the cooling drum can be measured on the surface of the resin in a non-contact manner by using a radiation thermometer (manufactured by Hayashi Denko co ltd., model number: RT61-2, used at a radiation factor of 0.95).

<Stretching Step>

The method for manufacturing the resin film includes a stretching step of uniaxially or biaxially stretching the non-stretched resin film.

In a vertical stretching step (step of stretching the resin film in the same direction as the transport direction of the film), the resin film is preheated, and then in a state where the resin film stays hot, the resin film is stretched in the transport direction by a group of rollers having different circumferential speeds (that is, rollers having different transport speeds).

In the vertical stretching step, the preheating temperature is preferably equal to or higher than the glass transition temperature (Tg) of the resin film Tg−40° C. and equal to or lower than Tg+60° C., more preferably equal to or higher than Tg−20° C. and equal to or lower than Tg+40° C., and even more preferably equal to or higher than Tg and equal to or lower than Tg+30° C. Furthermore, in the vertical stretching step, the stretching temperature is preferably equal to or higher than Tg and equal to or lower than Tg+60° C., more preferably Tg+2° C. and equal to or lower than Tg+40° C., and even more preferably equal to or higher than Tg+5° C. and equal to or lower than Tg+30° C. The stretching ratio in the vertical direction is preferably equal to or higher than 100% and equal to or lower than 250%, and more preferably equal to or higher than 110% and equal to or lower than 200%.

By the cross-direction stretching step (step of stretching the resin film in a direction perpendicular to the transport direction of the film) performed in addition to or instead of the vertical stretching step, the resin film is horizontally stretched in the width direction. In the cross-direction stretching step, for example, a tenter can be suitably used. By using the tenter, both ends of the resin film in the width direction are held by grips, and the resin film is stretched in the cross direction. By the cross-direction stretching, the tensile modulus of the resin film in the optical film can be increased.

The cross-direction stretching is preferably performed using a tenter. The stretching temperature is preferably equal to or higher than the glass transition temperature (Tg) of the resin film and equal to or lower than Tg+60° C., more preferably equal to or higher than Tg+2° C. and equal to or lower than Tg+40° C., and even more preferably equal to or higher than Tg+4° C. and equal to or lower than Tg+30° C. The stretching ratio is preferably equal to or higher than 100% and equal to or lower than 500%, and more preferably equal to or higher than 110% and equal to or lower than 400%. It is also preferable to allow the resin film to relax in either or both of the vertical direction and the cross direction after the cross-direction stretching.

It is preferable that the resin film is stretched such that the change in the thickness becomes equal to or smaller than 10%, preferably becomes equal to or smaller than 8%, more preferably becomes equal to or smaller than 6%, even more preferably becomes equal to or smaller than 4%, and most preferably becomes equal to or smaller than 2% in both a place in the width direction and a place in the longitudinal direction.

The change in the thickness can be determined as below.

A 10 m (meter) sample is taken from the stretched resin film. Except for 20% of both ends of the resin film in the film width direction, from the central portion of the film, 50 spots are sampled at equal intervals in the width direction and the longitudinal direction respectively, and thicknesses thereof are measured.

An average thickness Th_{TD-av}, a maximum thickness Th_{TD-max}, and a minimum thickness Th_{TD-min} in the width direction are determined, and the change in the thickness in the width direction is calculated by (Th_{TD-max}−Th_{TD-min})÷Th_{TD-av}×100 [%].

Furthermore, an average thickness Th_{MD-av}, a maximum thickness Th_{MD-max}, and a minimum thickness Th_{MD-min} in the longitudinal direction are determined, and the change in the thickness in the longitudinal direction is calculated by (Th_{MD-max}−Th_{MD-min})÷Th_{MD-av}×100 [%].

By the aforementioned stretching step, the thickness accuracy of the resin film can be improved.

The resin film having undergone stretching can be wound up in the form of a roll by a winding step. At this time, the winding tension of the resin film is preferably set to be equal to or lower than 0.02 kg/mm².

Regarding the details of other conditions, for the melt film-forming method, the contents described in paragraphs “0134” to “0148” in JP2015-224267A can be combined with the present invention and incorporated into the present specification, and for the stretching step, the contents described in JP2007-137028A can be combined with the present invention and incorporated into the present specification.

<Solution Film-Forming Method and Smoothing>

In a case where the resin film is formed by a solution film-forming method, it is preferable that the method includes a step of forming a casting film by casting a dope solution on a casting band, a step of drying the casting film, and a step of stretching the casting film. Specifically, it is preferable to form the resin film by the method described in JP4889335B.

In the present invention, it is preferable to adopt the following method.

For example, it is possible to adopt the method described in JP1999-123732A (JP-H11-123732A) in which a drying rate of the casting film is set to be equal to or lower than 300% by mass/min (=5% by mass/s) in terms of the content of a solvent based on the dry measure such that the film is gradually dried. Furthermore, for example, it is possible to adopt the method described in JP2003-276037A in which in a co-casting method of a casting film having a multilayer structure including a skin layer (outer layer) on both surfaces of a core layer as an interlayer, the viscosity of a dope solution for forming the core layer is increased such that the hardness of the casting film is secured while the viscosity of a dope for forming the outer layer is reduced. In addition, for examples, a method of forming a film on the surface of a casting film by rapidly drying the casting film and smoothing the surface shape by the leveling effect of the formed film, a method of stretching a casting film, and the like are also preferable.

The constitution of the resin film used in the present invention is not particularly limited as long as the film thickness of the resin film is equal to or greater than a specific value. For obtaining a film thickness equal to or greater than a specific value, the resin film may be constituted with one sheet of resin film as described above or may be constituted with a resin film in which first resin film/adhesive layer/second resin film laminated in this order, by bonding two sheets of resin films by using an adhesive layer.

Hereinafter, the resin film obtained by bonding two sheets of resin films by using an adhesive layer will be described.

(Resin Film Obtained by Bonding Two Sheets of Resin Films by Using Adhesive Layer)

In view of making it difficult for the optical film to bend and making the optical film exhibit further improved keystroke durability, it is preferable that the two sheets of resin films bonded using an adhesive layer are the same films.

“The same films” means that the resin films are constituted with the same resin material (for example, both the resin films are TAC films). Particularly, the first resin films are preferably constituted with resins having the same molecular weight, more preferably constituted with resins having the same molecular weight and the same degree of crystallinity, and even more preferably constituted with resins having the same molecular weight, the same degree of crystallinity, and the same stretching rate. Furthermore, it is more preferable that two sheets of the resin films have the same thickness in addition to the above.

“The same” does not mean “completely the same”, and “substantially the same” is also included in the meaning of “the same”. Specifically, “the same” films are films prepared under the same manufacturing conditions (conditions under which the films have the same film thickness, the same stretching rate, and the like), and errors occurring under these conditions are also included in the films.

That is, it is preferable that the difference in the tensile modulus between two sheets of resin films bonded using an adhesive layer is small. Specifically, the difference is preferably equal to or smaller than 4.0 GPa, more preferably equal to or smaller than 3.0 GPa, even more preferably equal to or smaller than 2.0 GPa, and particularly preferably equal to or smaller than 1.0 GPa.

(Thickness of Resin Film)

In view of keystroke durability and manufacturing suitability, two sheets of the resin films preferably each independently have a thickness of 40 to 160 μm, more preferably each independently have a thickness of 50 to 160 μm, even more preferably each independently have a thickness of 80 to 160 μm, and particularly preferably each independently have a thickness of 100 to 160 μm.

Adhesive Layer

The adhesive layer is a layer that plays a role of bonding the resin films to each other. The adhesive layer is not particularly limited as long as it two sheets of the resin films to each other.

It is preferable that the adhesive layer is formed using a composition containing a component (adhesive) expressing adhesiveness through drying or a reaction. For example, an adhesive layer formed using a composition containing a component expressing adhesiveness through a curing reaction (hereinafter, referred to as “curable composition”) is a cured layer formed by curing the curable composition.

As the adhesive, a resin can be used. In an aspect, the adhesive layer can be a layer in which a proportion of the resin in the layer is equal to or higher than 50% by mass and preferably equal to or higher than 70% by mass. As the resin, a single resin or a mixture of a plurality of resins may be used. In a case where the resin mixture is used, the aforementioned proportion of the resin refers to the proportion of the resin mixture. Examples of the resin mixture include a mixture of a certain resin and a resin having a structure established by partially modifying the certain resin, a resin mixture obtained by reacting different polymerizable compounds, and the like.

As the adhesive, it is possible to use any adhesive having appropriate properties, form, and adhesion mechanism. Specifically, examples of the adhesive include a water-soluble adhesive, an ultraviolet curable type adhesive, an emulsion-type adhesive, a latex-type adhesive, a mastic adhesive, a multi-layered adhesive, a paste-like adhesive, a foaming adhesive, a supported film adhesive, a thermoplastic adhesive, a hot-melt adhesive, a thermally solidified adhesive, a thermally activated adhesive, a heat-seal adhesive, a thermosetting adhesive, a contact-type adhesive, a pressure-sensitive adhesive, a polymerizable adhesive, a solvent-type adhesive, a solvent-activated adhesive, and the like. As the adhesive, a water-soluble adhesive and an ultraviolet curable type adhesive are preferable. Among these, a water-soluble adhesive is preferably used, because this adhesive is excellent in transparency, adhesiveness, workability, product quality, and economic feasibility.

The water-soluble adhesive can contain a natural or synthetic water-soluble component such as a protein, starch, or a synthetic resin. Examples of the synthetic resin include a resol resin, a urea resin, a melamine resin, a polyethylene oxide resin, a polyacrylamide resin, a polyvinyl pyrrolidone resin, a polyacrylic acid ester resin, a polymethacrylic acid ester resin, a polyvinyl alcohol resin, a polyacrylic resin, and a cellulose derivative. Among these, a water-soluble adhesive containing a polyvinyl alcohol resin or a cellulose derivative is preferable, because this adhesive exhibits excellent adhesiveness at the time of bonding the resin films to each other. That is, it is preferable that the adhesive layer contains a polyvinyl alcohol resin or a cellulose derivative.

The cellulose derivative means a substance obtained by modifying cellulose. As the cellulose derivative, known cellulose derivatives can be used without particular limitation. For example, hydroxyethyl cellulose (HEC) and the like can be used.

In view of increasing the tensile modulus, the weight-average molecular weight of the resin is preferably equal to or greater than 1,000, and more preferably equal to or greater than 10,000. The upper limit of the weight-average molecular weight of the resin is not particularly limited, but is substantially equal to or smaller than 1,000,000.

Examples of the components that can be optionally incorporated into the composition containing the adhesive include a crosslinking agent (boric acid. Safelink SPM-01 (trade name, manufactured by Nippon Kasei Chemical Co., Ltd), and the like), and a durability improving agent (calcium iodide or the like).

(Tensile Modulus)

The tensile modulus of the adhesive layer can be changed, for example, according to the type of resin constituting the adhesive layer. Generally, in a case where the molecular weight or the degree of crystallinity of the resin is increased, the tensile modulus tends to be increased. Furthermore, in a case where the adhesive layer has a crosslinking group, by the addition of a crosslinking agent or the like, a degree of crosslinking of the adhesive layer can be improved, and hence the tensile modulus can be increased. In addition, in a case where the adhesive layer contains a polymerizable composition, by the reduction of a polymerizable group equivalent of a compound having a polymerizable group (polymerizable group equivalent=molecular weight of compound/total number of polymerizable groups contained in compound), the improvement of a polymerization rate of the adhesive layer, the addition of a highly elastic substance (for example, inorganic particles and the like) to the adhesive layer, the addition of a compound having a rigid molecular structure (for example, an adamantane skeleton), and the like, the tensile modulus of the adhesive layer tends to be increased.

In view of further improving the keystroke durability, the tensile modulus of the adhesive layer at 25° C. is preferably equal to or higher than 2.0 GPa, more preferably equal to or higher than 2.5 GPa, even more preferably equal to or higher than 3.0 GPa, still more preferably equal to or higher than 3.5 GPa, yet more preferably equal to or higher than 4.0 GPa, particularly preferably equal to or higher than 4.5 GPa, and most preferably equal to or higher than 5.0 GPa. The upper limit thereof is not particularly limited, but is substantially equal to or lower than 12.0 GPa.

By using a sample of the adhesive layer prepared using a solution for forming an adhesive layer, a modulus of elasticity of the adhesive layer can be calculated by testing the modulus of elasticity by the same method as that used for testing the tensile modulus of the resin film.

(Thickness of Adhesive Layer)

In view of bonding two sheets of the resin films to each other, the thickness of the adhesive layer is preferably equal to or greater than 10 nm. From the viewpoint of reducing interference unevenness as well, the thickness of the adhesive layer is more preferably 10 nm to 10 μm, even more preferably 10 nm to 5 μm, and still more preferably 10 nm to 1 μm.

The adhesive layer can be formed by, for example, coating at least one surface of the resin film with a coating solution containing an adhesive and then drying the coating solution. As the method for preparing the coating solution, any of appropriate methods can be adopted. As the coating solution, for example, a commercial solution or dispersion liquid, a coating solution obtained by adding a solvent to a commercial solution or dispersion liquid, or a coating solution obtained by dissolving or dispersing solid contents in various solvents may be used.

In an aspect, the adhesive layer can also be a cured layer obtained by curing an active energy ray-curable composition. It is preferable that the active energy ray-curable composition for forming the adhesive layer contains, as an active energy ray-curable component, a cationically polymerizable compound such as an epoxy-based compound, more specifically, an epoxy-based compound which does not have an aromatic ring in a molecule as described in JP2004-245925A. Examples of such an epoxy-based compound include a hydrogenated epoxy-based compound, which is obtained by performing nuclear hydrogenation of an aromatic polyhydroxy compound as a raw material of an aromatic epoxy-based compound that is represented by diglycidyl ether of bisphenol A and then performing glycidyl etherification of the nuclear-hydrogenated compound, an alicyclic epoxy-based compound having at least one epoxy group bonded to an alicyclic ring in a molecule, an aliphatic epoxy-based compound represented by glycidyl ether of an aliphatic polyhydroxy compound, and the like. The active energy ray-curable composition for forming the adhesive layer can also contain a cationically polymerizable compound represented by an epoxy-based compound, a polymerization initiator such as a photocation polymerization initiator which generates a cation species or a Lewis acid by being irradiated with active energy rays so as to initiate the polymerization of a cationically polymerizable compound, and a photobase generator which generates a base through light irradiation. The active energy ray-curable composition may further contain a thermal cationic polymerization initiator which initiates polymerization by heating and various additives such as a photosensitizer.

(Difference in Tensile Modulus Between Resin Film and Adhesive Layer)

In view of further improving the keystroke durability, a difference between the tensile modulus at 25° C. of each of two sheets of the resin films to be bonded and the tensile modulus at 25° C. of the adhesive layer is equal to or lower than 4.0 GPa, more preferably equal to or lower than 3.5 GPa, even more preferably equal to or lower than 3.0 GPa, still more preferably equal to or lower than 2.5 GPa, yet more preferably equal to or lower than 2.0 GPa, particularly preferably equal to or lower than 1.5 GPa, and most preferably equal to or lower than 1.0 GPa.

In a case where the optical film according to the embodiment of the present invention has a resin film obtained by bonding two sheets of resin films by using an adhesive layer, the optical film may additionally have an adhesive layer on a surface (the other surface) opposite to the surface provided with the adhesive layer. For example, on the other surface, a known polarizing plate protective film may be provided through the adhesive layer. In a case where both surfaces of the resin films are provided with the adhesive layer, the compositions for forming the adhesive layers may be the same as or different from each other. However, from the viewpoint of productivity, it is preferable that both surfaces are provided with the adhesive layers formed of the same composition.

The surface to be provided with the adhesive layer may be subjected to a surface treatment such as a saponification treatment, a corona discharge treatment, or a plasma treatment before the adhesive layer is provided.

For example, by performing an alkali saponification treatment as a saponification treatment on a cellulose ester-based resin film, the adhesiveness between the resin film and a polarizer material such as polyvinyl alcohol can be improved.

As the saponification method, it is possible to use the method described in paragraphs “0211” and “0212” in JP2007-086748A.

For example, the alkali saponification treatment for the cellulose ester-based resin film is preferably performed in a cycle in which the film surface is immersed in an alkaline solution, then neutralized using an acidic solution, rinsed with water, and dried. Examples of the alkaline solution include a potassium hydroxide solution and a sodium hydroxide solution. The concentration of hydroxide ions is preferably 0.1 to 5.0 mol/L, and more preferably 0.5 to 4.0 mol/L. The temperature of the alkaline solution is preferably room temperature to 90° C., and more preferably 40° C. to 70° C.

Instead of the alkali saponification treatment, the easy adhesive processing described in JP1994-094915A (JP-H06-094915A) or JP1994-118232A (JP-H06-118232A) may be performed.

As the method for bonding the resin films to each other by using an adhesive, known methods can be used.

For example, by allowing a belt-like long first or second resin film, which moves in a horizontal or vertical direction, to approach one surface of the first or second resin film at the same movement speed, coating the portion between the first resin film and the second resin film with an adhesive, which will become an adhesive layer, and pressing the resin films together by using pinch rolls, two sheets of the resin films can be bonded to each other. The adhesive used for coating may be diluted with a solvent such that the material constituting the adhesive layer can coat the resin films. In this case, by drying the solvent in the adhesive layer, bonding of two sheets of the resin films is finished. At this time, the drying temperature depends on the type of solvent in the adhesive layer, the type of resin in two sheets of the resin films, and the thickness of two sheets of the resin films. For example, in a case where the solvent in the adhesive layer is water, the drying temperature is preferably 30° C. to 85° C., and more preferably 45° C. to 80° C.

Furthermore, by coating either or both of two sheets of the resin films with an adhesive which will become the adhesive layer, performing a drying treatment so as to remove the solvent contained in the adhesive layer and to form the adhesive layer on the resin film, allowing one resin film to approach to the surface, on which the adhesive layer is formed, of the other resin film, which moves in a horizontal or vertical direction and has the belt-like long adhesive layer formed thereon, at the same movement speed, coating the portion between two sheets of the resin films, on which the adhesive layer is formed, with a solvent for swelling the adhesive layer, and pressing the resin films together by using pinch rolls, two sheets of the resin films can be bonded to each other. In this case, by drying the solvent, bonding of two sheets of the resin films is finished. At this time, the drying temperature depends on the type of solvent, the type of resin in two sheets of the resin films, and the thickness of two sheets of the resin films. For example, in a case where the solvent is water, the drying temperature is preferably 30° C. to 85° C., and more preferably 45° C. to 80° C.

(2) Hardcoat Layer (HC Layer)

The optical film according to the embodiment of the present invention has a hardcoat layer (HC layer) on one surface of the resin film, and the HC layer contains a polysiloxane-containing compound and a fluorine-containing compound.

As will be described later, the HC layer containing a polysiloxane-containing compound and a fluorine-containing compound can be prepared using a curable composition for forming an HC layer.

In view of realizing further improved post-keystroke adhesion resistance and rub resistance, the polysiloxane-containing compound and the fluorine-containing compound are preferably present on at least the surface of the HC layer, and more preferably localized on the surface of the HC layer.

Herein, the surface of the HC layer means a surface of the HC layer that is opposite to a surface of the HC layer provided with the resin film.

It is preferable that the HC layer in the present invention is preferably formed by polymerizing and curing a polysiloxane-containing compound having a polymerizable group in a molecule, a fluorine-containing compound having a polymerizable group in a molecule, and a polymerizable compound which is neither the polysiloxane-containing compound nor the fluorine-containing compound and has a polymerizable group in a molecule that will be described later. These polymerizable groups are more preferably radically polymerizable groups. In a case where the HC layer is constituted as above, the polysiloxane-containing compound and the fluorine-containing compound in the HC layer are present in a state of being bonded to the polymerizable compound forming the HC layer, and accordingly, further improved post-keystroke adhesion resistance can be imparted. In a case where each of the polysiloxane-containing compound and the fluorine-containing compound has a polymerizable group, the polymerizable groups in the polysiloxane-containing compound and the fluorine-containing compound which that be described later are present in the HC layer in a state of forming a bond by reacting with each other.

In a case where the HC layer has a laminated structure including two or more layers as will be described later, the polysiloxane-containing compound and the fluorine-containing compound are preferably contained in at least the HC layer farthest from the resin film, and more preferably contained in only the HC layer farthest from the resin film.

Hereinafter, a specific aspect of the HC layer will be described, but the present invention is not limited to the following aspect.

[Fluorine-Containing Compound]

The fluorine-containing compound in the present invention is not particularly limited as long as the compound can impart rub resistance to the HC layer by being used in combination with a polysiloxane-containing compound. As the fluorine-containing compound, compounds having a fluorine atom in a molecule can be used without particular limitation. As the fluorine-containing compound, a fluorine-containing antifoulant exhibiting the properties of an antifoulant is preferably used.

In the present invention, the fluorine-containing compound may be any of a monomer, an oligomer, or a polymer. It is preferable that the fluorine-containing compound has a substituent which forms a bond with other components (for example, a polysiloxane-containing compound, a polymerizable monomer as a constituent component of a resin, and a resin) in the HC layer or makes a contribution to the compatibility with those other components. It is preferable that the fluorine-containing compound has a plurality of substituents, and the substituents may be the same as or different from each other.

The substituent is preferably a polymerizable group and may be a polymerizable reactive group which exhibits any of radical polymerization properties, cationic polymerization properties, anionic polymerization properties, condensation polymerization properties, or addition polymerization properties. For example, as the substituent, an acryloyl group, a methacryloyl group, a vinyl group, an allyl group, a cinnamoyl group, an epoxy group, an oxetanyl group, a hydroxyl group, a polyoxyalkylene group, a carboxyl group, and an amino group are preferable. Among these, a radically polymerizable group is preferable, and an acryloyl group and a methacryloyl group are particularly preferable.

The fluorine-containing compound may be a polymer or oligomer with a compound which does not contain a fluorine atom.

The fluorine-containing antifoulant is preferably a fluorine-based compound represented by General Formula (F).

(R^{f})—[(W)—(R^{A})ₙ]ₘ General Formula (F):

(In the formula, R^{f} represents a (per)fluoroalkyl group or a (per)fluoropolyether group, W represents a single bond or a linking group, and R^{A} represents a polymerizable unsaturated group, n represents an integer of 1 to 3, m represents an integer of 1 to 3.)

In General Formula (F), R^{A} represents a polymerizable unsaturated group. The polymerizable unsaturated group is preferably a group having an unsaturated bond (that is, a radically polymerizable group) which can cause a radical polymerization reaction by being irradiated with active energy rays such as ultraviolet rays or electron beams. Examples of the polymerizable unsaturated group include a (meth)acryloyl group, a (meth)acryloyloxy group, a vinyl group, an allyl group, and the like. A (meth)acryloyl group, a (meth)acryloyloxy group, and groups obtained by substituting any hydrogen atom in these groups with a fluorine atom are preferably used.

In General Formula (F), R^{f} represents a (per)fluoroalkyl group or a (per)fluoropolyether group.

The (per)fluoroalkyl group represents at least one kind of group between a fluoroalkyl group and a perfluoroalkyl group, and the (per)fluoropolyether group represents at least one kind of group between a fluoropolyether group and a perfluoropolyether group. From the viewpoint of rub resistance, it is preferable that a fluorine content rate in R^{f} is high.

The number of carbon atoms in the (per)fluoroalkyl group is preferably 1 to 20, and more preferably 1 to 10.

The (per)fluoroalkyl group may have a linear structure (for example, —CF₂CF₃, —CH₂(CF₂)₄H, —CH₂(CF₂)CF₃, or —CH₂CH₂(CF₂)₄H), a branched structure (for example, —CH(CF₃)₂, —CH₂CF(CF)₂, —CH(CH₃)CF₂CF₃, or —CH(CH)(CF₂)₅CF₂H), or an alicyclic structure (preferably a 5- or 6-membered ring such as a perfluorocyclohexyl group, a perfluorocyclopentyl group, and an alkyl group substituted with these groups).

The (per)fluoropolyether group refers to a (per)fluoroalkyl group having an ether bond, and may be a monovalent group or a group having a valency of 2 or higher. Examples of the fluoropolyether group include —CH₂OCH₂CF₂CF₃, —CH₂CH₂OCH₂C₄F₈H, —CH₂CH₂OCH₂CH₂CF₁, —CH₂CH₂OCF₂CF₂OCF₂CF₂H, a fluorocycloalkyl group having 4 to 20 carbon atoms that has 4 or more fluorine atoms, and the like. Examples of the perfluoropolyether group include —(CF₂O)ₚ—(CF₂CF₂O)_{q}—, —[CF(CF₃)CF₂O]ₚ—[CF(CF₃)]_{q}—, —(CF₂CF₂CF₂O)ₚ—, —(CF₂CF₂O)ₚ—, and the like.

p and q each independently represent an integer of 0 to 20. Here, p+q equals an integer equal to or greater than 1.

The sum of p and q is preferably 1 to 83, more preferably 1 to 43, and even more preferably 5 to 23.

From the viewpoint of excellent rub resistance, the fluorine-containing antifoulant particularly preferably has a perfluoropolyether group represented by —(CF₂O)ₚ—(CF₂CF₂O)_{q}—.

In the present invention, it is preferable that the fluorine-containing antifoulant has a perfluoropolyether group and a plurality of polymerizable unsaturated groups in one molecule.

In General Formula (F), W represents a linking group. Examples of W include an alkylene group, an arylene group, a heteroalkylene group, and a linking group obtained by combining these groups. These linking groups may further have an oxy group, a carbonyl group, a carbonyloxy group, a carbonylimino group, a sulfonamide group, and a functional group obtained by combining these groups.

W is preferably an ethylene group, and more preferably an ethylene group bonded to a carbonylimino group.

The content of fluorine atoms in the fluorine-containing antifoulant is not particularly limited, but is preferably equal to or greater than 20% by mass, more preferably 30% to 70% by mass, and even more preferably 40% to 70% by mass.

As the fluorine-containing antifoulant, for example, R-2020, M-2020, R-3833, M-3833, and OPTOOL DAC (trade names) manufactured by DAIKIN INDUSTRIES, LTD., and MEGAFACE F-171, F-172, F-179A, RS-78, and RS-90 and DEFENSA MCF-300 and MCF-323 (trade names) manufactured by DIC Corporation are preferable, but the present invention is not limited to these.

From the viewpoint of rub resistance, in General Formula (F), the product of n and m (n×m) is preferably equal to or greater than 2, and more preferably equal to or greater than 4.

In a case where both of n and m in General Formula (F) are 1, specific examples of the following preferred aspect include General Formulae (F-1) to (F-3).

R^{f2}(CF₂CF₂)ₚR²²CH₂CH₂R²¹OCOCR¹¹═CH₂ General Formula (F-1):

(In the formula, R^{f2} represents a fluorine atom or a fluoroalkyl group having 1 to 10 carbon atoms, R¹¹ represents a hydrogen atom or a methyl group, R²¹ represents a single bond or an alkylene group, R²² represents a single bond or a divalent linking group, p represents an integer showing a degree of polymerization, and the degree of polymerization p is equal to or higher than k (k is an integer equal to or greater than 3).)

In a case where R²² represents a divalent linking group, examples of the divalent linking group are the same as the examples of W described above.

Examples of telomer-type (meth)acrylate containing fluorine atom represented by General Formula (F-1) include partially or totally fluorinated alkyl ester derivatives of (meth)acrylic acid.

In a case where telomerization is used at the time of synthesizing the compound represented by General Formula (F-1), depending on the telomerization condition, the reaction mixture separation condition, and the like, sometimes the compound contains a plurality of fluorine-containing (meth)acrylic acid esters in which p in R^{r2}(CF₂CF₂)ₚR²²CH₂CH₂R²¹O— as a group represented by General Formula (F-1) is k, k+1, k+2, . . . and the like.

F(CF₂)_{q}—CH₂—CHX—CH₂Y General Formula (F-2):

(In the formula, q represents an integer of 1 to 20, X and Y each represent a (meth)acryloyloxy group or a hydroxyl group, and at least one of X or Y is a (meth)acryloyloxy group.)

The fluorine-containing (meth)acrylic acid ester represented by General Formula (F-2) has a fluoroalkyl group having 1 to 20 carbon atoms that has a trifluoromethyl group (—CF₃) on a terminal. On the surface of the fluorine-containing (meth)acrylic acid ester, the trifluoromethyl group is effectively aligned even though the amount thereof is small.

In view of rub resistance and ease of manufacturing of the compound, q is preferably 6 to 20, and more preferably 8 to 10. Compared to other fluorine-containing (meth)acrylic acid esters having a long-chain fluoroalkyl group, the fluorine-containing (meth)acrylic acid ester having a fluoroalkyl group containing 8 to 10 carbon atoms more effectively reduces the friction coefficient and results in better rub resistance.

Specifically, examples of the fluorine-containing (meth)acrylic acid ester represented by General Formula (F-2) include 1-(meth)acryloyloxy-2-hydroxy-4,4,5,5,6,6,7,7,8,8,8,9,9,10,10,11,11,12,12,13,13,13-heneicosafluorotridecane, 2-(meth)acryloyloxy-1-hydroxy-4,4,5,5,6,6,7,7,8,8,9,9,10,10,11,11,12,12,13,13,13-heneicosafluorotridecane, 1,2-bis(meth)acryloyloxy-4,4,5,5,6,6,7,7,8,8,9,9,10,11,11,12,12,13,13,13-heneicosafluorotridecane, and the like. In the present invention, 1-acryloyloxy-2-hydroxy-4,4,5,5,6,6,7,7,8,8,9,9,10,10,11,11,12,12,13,13,13-heneicosafluorotridecane is preferable.

F(CF₂)ᵣO(CF₂CF₂CO)CF₂CH₂OCOCR³═CH₂ General Formula (F-3):

(In the formula, R³ represents a hydrogen atom or a methyl group, s represents an integer of 1 to 20, and r represents an integer of 1 to 4.)

The fluorine atom-containing monofunctional (meth)acrylate represented by General Formula (F-3) can be obtained by reacting a fluorine atom-containing alcohol compound represented by General Formula (FG-3) with a (meth)acrylic acid halide.

F(CF₂)ᵣO(CF₂CF₂CO)CF₂CH₂OH General Formula (FG-3):

(In General Formula (FG-3), s represents an integer of 1 to 20, and r represents an integer of 1 to 4.)

Specific examples of the fluorine atom-containing alcohol compound represented by General Formula (FG-3) include 1H, 1H-perfluoro-3,6-dioxaheptan-1-ol, 1H,1H-perfluoro-3,6-dioxaoctan-1-ol, 1H,1H-perfluoro-3,6-dioxadecan-1-ol, 1H, 1H-perfluoro-3,6,9-trioxadecan-1-ol, 1H, 1H-perfluoro-3,6,9-trioxaundecan-1-ol, 1H,1H-perfluoro-3,6,9-trioxatridecan-1-ol, 1H, 1H-perfluoro-3,6,9,12-tetraoxatridecan-1-ol, 1H, 1H-perfluoro-3,6,9,12-tetraoxatetradecan-1-ol, 1H, 1H-perfluoro-3,6,9,12-tetraoxahexadecan-1-ol, 1H, 1H-perfluoro-3,6,9,12,15-pentaoxahexadecan-1-ol, 1H, 1H-perfluoro-3,6,9,12,15-pentaoxaheptadecan-1-ol, 1H, 1H-perfluoro-3,6,9,12,15-pentaoxanonadecan-1-ol, 1H, 1H-perfluoro-3,6,9,12,15,18-hexaoxaeicosan-1-ol, 1H,1H-perfluoro-3,6,9,12,15,18-hexaoxadocosan-1-ol, 1H, 1H-perfluoro-3,6,9,12,15,18,21-heptaoxatricosan-1-ol, 1H, 1H-perfluoro-3,6,9,12,15,18,21-heptaoxapentacosan-1-ol, and the like.

These are available as commercial products, and specific examples thereof include 1H,1H-perfluoro-3,6-dioxaheptan-1-ol (trade name “C5GOL”, manufactured by EX FLOOR Inc.), 1H,1H-perfluoro-3,6,9-trioxadecan-1-ol (trade name “C7GOL”, manufactured by EX FLOOR Inc.), 1H,1H-perfluoro-3,6-dioxadecan-1-ol (trade name “C8GOL”, manufactured by EX FLOOR Inc.), 1H,1H-perfluoro-3,6,9-trioxatridecan-1-ol (trade name “C10GOL”, manufactured by EX FLOOR Inc.), 1H,1H-perfluoro-3,6,9,12-tetraoxahexadecan-1-ol (trade name “C12GOL”, manufactured by EX FLOOR Inc.), and the like.

In the present invention, it is preferable to use 1H, 1H-perfluoro-3,6,9,12-tetraoxatridecan-1-ol.

Examples of the (meth)acrylic acid halide to be reacted with the fluorine atom-containing alcohol compound represented by General Formula (FG-3) include (meth)acrylic acid fluoride, (meth)acrylic acid chloride, (meth)acrylic acid bromide, (meth)acrylic acid iodide, and the like. From the viewpoint of ease of availability and the like, (meth)acrylic acid chloride is preferable.

Specific examples preferred as the compound represented by General Formula (F-3) will be shown below, but the present invention is not limited thereto. Specific examples preferable as General Formula (F-3) are also described in JP2007-264221A.

F₉C₄OC₂F₄OC₂F₄OCF₂CH₂OCOCH═CH₂ (b-1):

F₉C₄OC₂F₄OC₂F₄OCF₂CH₂OCOC(CH₃)═CH₂ (b-2):

In addition to the compound represented by General Formula (F-3), a compound represented by General Formula (F-3)′ can also be preferably used.

R^{f3}—[(O)_{c}(O═C)_{b}(CX⁴X⁵)ₐ—CX³═CX¹X²] General Formula (F-3)′:

(In the formula. X¹ and X² each represent H or F, X³ represents H, F, CH₃, or CF₃, X⁴ and X⁵ each represent H, F, or CF₃, a, b, and c each represent 0 or 1, and R^{f3} represents a fluorine-containing organic group containing an ether bond having 18 to 200 carbon atoms.)

The compound represented by General Formula (F-3)′ is a fluorine-containing unsaturated compound in which the R^{f3} group has 6 or more repeating units represented by General Formula (FG-3)′: —(CX⁶₂CF₂CF₂O)— (in the formula, X⁶ represents F or H).

Examples of the fluorine-containing polyether compound represented by General Formula (F-3)′ include (c-1) R^{f3}—[(O)(O═C)_{b}—CX³═CX¹X²], (c-2) R^{f3}—[(O)(O═C)—CX³═CX¹X²], (c-3) R^{f}—[(O)_{c}(O═C)—CF═CH₂], and the like (each of the references in (c-1) to (c-3) has the same definition as each of the references in General Formula (FG-3)′).

As the polymerizable unsaturated group in the fluorine-containing polyether compound, those having the following structures can be preferably used.

The fluorine-containing polyether compound represented by General Formula (F-3)′ may have a plurality of polymerizable unsaturated groups.

In the present invention, a compound having a structure of —O(C═O)CF═CH₂ is preferable because this compound exhibits particularly high polymerization (curing) reactivity and makes it possible to obtain a cured substance with excellent efficiency.

It is important for the fluorine-containing polyether compound represented by General Formula (F-3)′ to have 6 or more fluorine-containing polyether chains represented by General Formula (FG-3)′ as repeating units in the R^{f3} group. In a case where the fluorine-containing polyether compound has such a structure, rub resistance can be imparted.

More specifically, the fluorine-containing polyether compound may be a mixture containing 6 or more fluorine-containing polyether chains as repeating units. In a case where the fluorine-containing polyether compound is used in the form of a mixture, it is preferable that the compound is a mixture in which in the distribution of fluorine-containing unsaturated compounds with no more than 6 repeating units described above and fluorine-containing unsaturated compounds with 6 or more repeating units described above, the abundance ratio of the fluorine-containing unsaturated compounds with 6 or more polyether chain repeating units is the highest.

The number of repeating units as the fluorine-containing polyether chains represented by General Formula (FG-3)′ is preferably equal to or greater than 6, more preferably equal to or greater than 10, even more preferably equal to or greater than 18, and particularly preferably equal to or greater than 20. In a case where the number of repeating units is within the above range, it is possible to reduce the dynamic friction coefficient and to improve the rub resistance. The fluorine-containing polyether chain may be present at the terminal of the R^{f3} group or present in the chain.

Specifically, the R^{f3} group is preferably a group represented by General Formula (c-4): R⁴—(CX⁶₂CF₂CF₂O)ₜ—(R⁵)ₑ—.

(In the formula, X⁶ has the same definition as X⁶ in the fluorine-containing polyether chain represented by General Formula (FG-3)′, R⁴ represents a hydrogen atom, a halogen atom, an alkyl group, a fluorine-containing alkyl group, an alkyl group containing an ether bond, or a fluorine-containing alkyl group containing an ether bond, R⁵ represents an organic group having a valency equal to or higher than 2, t represents an integer of 6 to 66, and e represents 0 or 1.)

That is, the R^{f3} group is a fluorine-containing organic group which is bonded to a reactive carbon-carbon double bond through the organic group R⁵ having a valency equal to or higher than 2 and further has R⁴ on a terminal.

R⁵ is not particularly limited as long as it is an organic group which can bond the fluorine-containing polyether chain represented by General Formula (FG-3)′ to a reactive carbon-carbon double bond. Examples of R⁵ include an alkylene group, a fluorine-containing alkylene group, an alkylene group containing an ether bond, and a fluorine-containing alkylene group containing an ether bond. Among these, in view of transparency and low refractive index, a fluorine-containing alkylene group and a fluorine-containing alkylene group containing an ether bond are preferable.

Specifically, for example, as the fluorine-containing polyether compound represented by General Formula (F-3)′, the compounds described in WO2003/022906A and the like are preferably used. In the present invention, CH₂═CF—COO—CH₂CF₂CF₂—(OCF₂CF₂CF₂)₇—OC₃F₇ can be particularly preferably used.

In a case where n and m in General Formula (F) do not simultaneously represent 1, for example, General Formula (F-4) and General Formula (F-5) described below are preferred aspects.

(R^{f1})—[(W)—(R^{A})ₙ]ₘ General Formula (F-4):

(In General Formula (F-4), R^{f1} represents a (per)fluoroalkyl group or a (per)fluoropolyether group, W represents a linking group, and R^{A} represents a polymerizable unsaturated group. n represents an integer of 1 to 3, and m represents an integer of 1 to 3. n and m do not simultaneously represent 1.)

General Formula (F-4) preferably represents a compound in which n represents 2 or 3 and m represents 1 to 3, more preferably represents a compound in which n represents 2 or 3 and m represents 2 or 3, and even more preferably represents a compound in which n represents 3 and m represents 2 or 3, because then water repellency and oil repellency become excellent, and water repellency and oil repellency are excellently maintained (antifouling durability).

As R^{f1}, a group having a valency of 1 to 3 can be used. In a case where R^{f1} is a monovalent group, the terminal group thereof is preferably (CₙF₂ₙ₊₁)—, (CₙF₂ₙ₊₁O)—, (XCₙF₂ₙ O)—, or (XCₙF₂ₙ₊₁)— (in the formulae, X represents a hydrogen atom, a chlorine atom, or a bromine atom, and n represents an integer of 1 to 10). Specifically, it is possible to preferably use CF₃O(C₂F₄O)ₚCF₂—, C₃F₇O(CF₂CF₂CF₂O)ₚCF₂CF₂—, C₃F₇O(CF(CF₃)CF₂O)ₚCF(CF₃)—, F(CF(CF₃)CF₂O)ₚCF(CF₃)—, and the like.

The average of p is 0 to 50, preferably 3 to 30, more preferably 3 to 20, and even more preferably 4 to 15.

In a case where R^{f1} represents a divalent group, it is possible to preferably use —(CF₂O)_{q}(C₂F₄O)CF₂—, —(CF₂)₃—(C₄F₈O)ᵣ(CF₂)₃, —CF₂O(C₂F₄O)ᵣCF₂—, —C₂F₄O(C₃F₆O)C₂F₄—, —CF(CF₃)(OCF₂CF(CF₃))ₛOCₜF₂ₜO(CF(CF₃)CF₂O)ᵣCF(CF₃)—, —(CF(CF₃)CF₂O)ₚCF(CF₃)—, and the like.

The average of p, q, r, and s in the formula is 0 to 50, preferably 3 to 30, more preferably 3 to 20, and most preferably 4 to 15. t represents an integer of 2 to 6.

Specific examples preferred as the compound represented by General Formula (F-4) or the method for synthesizing the compound are described in WO2005/113690A.

Hereinafter, the compound represented by F(CF(CF₃)CF₂O)ₚCF(CF₃)— in which the average of p is 6 or 7 will be described as “HFPO-”, the compound represented by —(CF(CF₃)CF₂O)ₚCF(CF₃)— in which the average of p is 6 or 7 will be described as “—HFPO-”, and specific compounds represented by General Formula (F-4) will be shown. However, the present invention is not limited thereto.

(d-1): HFPO—CONH—C—(CH₂OCOCH═CH₂)₂CH₂CH₃

(d-2): HFPO—CONH—C—(CH₂OCOCH═CH₂)₂H

(d-3): 1:1 Michael addition-polymerized substance of HFPO—CONH—C₃H₆NHCH₃ and trimethylolpropane triacrylate

(d-4): (CH₂═CHCOOCH₂)₂H—C—CONH—HFPO—CONH—(CH₂OCOCH═CH₂)₂H

(d-5): (CH₂═CHCOOCH₂)₃—C—CONH—HFPO—CONH—C—(CH₂OCOCH═CH₂)₃

Furthermore, as the compound represented by General Formula (F-4), a compound represented by General Formula (F-5) can also be used.

CH₂═CX¹—COO—CHY—CH₂—OCO—CX²═CH₂ General Formula (F-5):

(In the formula, X¹ and X² each represent a hydrogen atom or a methyl group, and Y represents a fluoroalkyl group having 2 to 20 carbon atoms that has 3 or more fluorine atoms or a fluorocycloalkyl group having 4 to 20 carbon atoms that has 4 or more fluorine atoms.)

In the present invention, the compound having a (meth)acryloyloxy group as a polymerizable unsaturated group may have a plurality of (meth)acryloyloxy groups. In a case where the fluorine-containing antifoulant has a plurality of (meth)acryloyloxy groups, by being cured, the compound has a three-dimensional network structure and a high glass transition temperature, the antifoulant is hardly transferred, and the durability against repeated wiping of contaminants can be improved. Furthermore, it is possible to obtain an HC layer having excellent heat resistance, weather fastness, and the like.

Specifically, for example, as the compound represented by General Formula (F-5), di(meth)acrylic acid-2,2,2-trifluoroethyl ethylene glycol, di(meth)acrylic acid-2,2,3,3,3-pentafluoropropyl ethylene glycol, di(meth)acrylic acid-2,2,3,3,4,4,4-heptafluorobutyl ethylene glycol, di(meth)acrylic acid-2,2,3,3,4,4,5,5,5-nonafluoropentyl ethylene glycol, di(meth)acrylic acid-2,2,3,3,4,4,5,5,6,6,6-undecafluorohexyl ethylene glycol, di(meth)acrylic acid-2,2,3,3,4,4,5,5,6,6,7,7,7-tridecafluoroheptyl ethylene glycol, di(meth)acrylic acid-2,2,3,3,4,4,5,5,6,6,7,7,8,8,8-pentadecafluorooctyl ethylene glycol, di(meth)acrylic acid-3,3,4,4,5,5,6,6,7,7,8,7,8,8-tridecafluorooctyl ethylene glycol, di(meth)acrylic acid-2,2,3,3,4,4,5,5,6,7,8,8,9,9,9-heptadecafluorononyl ethylene glycol, di(meth)acrylic acid-2,2,3,3,4,4,5,5,6,6,7,7,8,8,9,9,10,10,10-nonadecafluorodecyl ethylene glycol, di(meth)acrylic acid-3,3,4,4,5,5,6,6,7,7,8,8,9,9,10,10,10-heptadecafluorodecyl ethylene glycol, di(meth)acrylic acid-2-trifluoromethyl-3,3,3-trifluoropropyl ethylene glycol, di(meth)acrylic acid-3-trifluoromethyl-4,4,4-trifluorobutyl ethylene glycol, di(meth)acrylic acid-1-methyl-2,2,3,3,3-pentafluoropropyl ethylene glycol, di(meth)acrylic acid-1-methyl-2,2,3,3,4,4,4-heptafluorobutyl ethylene glycol, and the like are preferable. At the time of use, one kind of each of these compounds can be used singly, or these compounds can be used as a mixture. These di(meth)acrylic acid esters can be prepared by known methods exemplified in JP1994-306326A (JP-H06-306326A). In The present invention, diacrylic acid-2,2,3,3,4,4,5,5,6,6,7,7,8,8,9,9,9-heptadecafluorononyl ethylene glycol is preferably used.

In the present invention, the compound having a (meth)acryloyloxy group as a polymerizable unsaturated group may be a compound having a plurality of (per)fluoroalkyl groups or (per)fluoropolyether groups in one molecule.

(Molecular Weight of Fluorine-Containing Compound)

The weight-average molecular weight (Mw) of the fluorine-containing compound having a polymerizable unsaturated group can be measured by molecular exclusion chromatography such as gel permeation chromatography (GPC).

Mw of the fluorine-containing compound used in the present invention is preferably equal to or greater than 400 and less than 50,000, more preferably equal to or greater than 400 and less than 30,000, and even more preferably equal to or greater than 400 and less than 25,000. It is preferable that Mw is equal to or greater than the lower limit described above, because then the surface transitivity of the antifoulant in the HC layer is improved. Furthermore, it is preferable that Mw is less than the upper limit described above, because then the surface transitivity of the fluorine-containing compound is not hindered while the step of applying a curable composition for forming an HC layer and then curing the composition is being performed, the fluorine-containing compound is more easily uniformly localized within the surface of the HC layer, and the rub resistance and the film hardness are improved. The fluorine-containing compound may have multiple peaks regarding the weight-average molecular weight.

(Amount of Fluorine-Containing Compound Added)

The amount of the fluorine-containing compound added is preferably 0.01% to 5% by mass, more preferably 0.1% to 5% by mass, even more preferably 0.5% to 5% by mass, and particularly preferably 0.5% to 2% by mass, with respect to the total solid content in the curable composition for forming an HC layer. In a case where the amount of the fluorine-containing compound added is equal to or greater than the lower limit described above, the friction coefficient thereof with respect to steel wool can be reduced, and the rub resistance is further improved. It is preferable that the amount of the fluorine-containing compound added is equal to or smaller than the upper limit described above, because then the fluorine-containing compound, which is not thoroughly mixed with the polymerizable compound (resin component for forming the HC layer) in the curable composition for forming an HC layer, is not precipitated on the surface, and the bleaching of the HC layer or the occurrence of white powder on the surface is inhibited.

In a case where the HC layer has a laminated structure including two or more layers as will be described later, the amount of the fluorine-containing compound added means the amount of the fluorine-containing compound added to the curable composition for forming an HC layer that forms an HC layer containing a fluorine-containing compound and a polysiloxane-containing compound.

[Polysiloxane-Containing Compound]

The polysiloxane-containing compound in the present invention is not particularly limited as long as the compound can impart post-keystroke adhesion resistance to the HC layer by being used in combination with the fluorine-containing compound. As the polysiloxane-containing compound, a compound having a polysiloxane structure in a molecule can be used.

The polysiloxane structure that the polysiloxane-containing compound has may be any of a linear structure, a branched structure, or a cyclic structure.

As the polysiloxane-containing compound, a polysiloxane antifoulant exhibiting the properties of an antifoulant is preferably used.

The polysiloxane antifoulant is preferably represented by General Formula (F-6).

RₐR^{A}_{b}SiO_{(4-a-b)/2} General Formula (F-6):

(In the formula, R represents a hydrogen atom, a methyl group, an ethyl group, a propyl group, or a phenyl group, R^{A} represents an organic group containing a polymerizable unsaturated group, 0<a, 0<b, and a+b<4.)

a is preferably 1 to 2.75, and more preferably 1 to 2.5. In a case where a is equal to or greater than 1, industrially, the synthesis of the compound becomes easy. In a case where a is equal to or smaller than 2.75, it is easy to accomplish both the curing properties and the post-keystroke adhesion resistance.

Examples of the polymerizable unsaturated group represented by R^{A} are the same as the examples of the polymerizable unsaturated group (that is, a radically polymerizable group) represented by R^{A} in General Formula (F). The polymerizable unsaturated group is preferably a (meth)acryloyl group, a (meth)acryloyloxy group, and groups formed in a case where any hydrogen atom in these groups is substituted with a fluorine atom.

From the viewpoint of film hardness, it is preferable that the polysiloxane antifoulant has a plurality of polymerizable unsaturated groups in one molecule. It is more preferable that the polysiloxane antifoulant is polydimethylsiloxane having a plurality of polymerizable unsaturated groups in one molecule.

As the polysiloxane antifoulant, for example, a compound is preferable which contains a plurality of dimethylsilyloxy units as repeating units and has a substituent on a terminal of the chain of the compound and/or a side chain. The chain of the compound containing dimethylsilyloxy as a repeating unit may contain a structural unit other than dimethylsilyloxy. It is preferable that the compound has a plurality of substituents, and the substituents may be the same as or different from each other.

The substituent is preferably a polymerizable group. The polymerizable group may exhibit any of radical polymerization properties, cationic polymerization properties, anionic polymerization properties, condensation polymerization properties, or addition polymerization properties. For example, as the substituent, groups containing a (meth)acryloyl group, a (meth)acryloyloxy) group, a vinyl group, an allyl group, a cinnamoyl group, an epoxy group, an oxetanyl group, a hydroxyl group, a fluoroalkyl group, a polyoxyalkylene group, a carboxyl group, an amino group, and the like are preferable. Among these, a radically polymerizable group is preferable. Particularly, from the viewpoint of improving post-keystroke adhesion resistance, a (meth)acryloyloxy group is preferable.

The number of substituents in the compound expressed as a functional group equivalent is preferably 100 to 10,000 g/mol from the viewpoint of accomplishing both the film hardness and the post-keystroke adhesion resistance, more preferably 100 to 3,000 g/mol, even more preferably 100 to 2,000 g/mol, and particularly preferably 100 to 1,000 g/mol. It is preferable that the functional group equivalent is equal to or greater than the lower limit described above, because then the polymerizable compound (resin component for forming an HC layer) in the curable composition for forming an HC layer does not become unnecessarily compatible, and the surface transitivity of the antifoulant in the HC layer is improved. It is preferable that the functional group equivalent is equal to or smaller than the upper limit described above, because then the film hardness can be improved, and the post-keystroke adhesion resistance can be improved.

R^{A} is preferably an organic group containing a (meth)acryloyl group. In view of ease of industrial synthesis, it is more preferable that R^{A} forms a Si—O—C bond with a Si atom. b is preferably 0.4 to 0.8, and more preferably 0.6 to 0.8. In a case where b is equal to or greater than the lower limit described above, the curing properties are improved. In a case where b is equal to or smaller than the upper limit described above, the post-keystroke adhesion resistance is improved.

a+b preferably equals 3 to 3.7, and more preferably equals 3 to 3.5. In a case where a+b is equal to or greater than the lower limit described above, the compound is easily localized within the surface of the HC layer. In a case where a+b is equal to or smaller than upper limit described above, it is possible to more reliably accomplish both the curing properties and the post-keystroke adhesion resistance.

The polysiloxane antifoulant preferably has 3 or more Si atoms in one molecule, and more preferably has 3 to 40 Si atoms in one molecule. In a case where the polysiloxane antifoulant has 3 or more Si atoms, the localization of the compound within the surface of the HC layer is accelerated, and sufficient post-keystroke adhesion resistance is more easily obtained.

The polysiloxane antifoulant can be manufactured using known methods exemplified in JP2007-145884A and the like.

As additives having a polysiloxane structure, it is also preferable to add polysiloxane (for example, “KF-96-10CS”, “KF-100T”, “X-22-169AS”, “KF-102”, “X-22-3701IE”, “X-22-164”, “X-22-164A”, “X-22-164AS”, “X-22-164B”, “X-22-164C”, “X-22-5002”, “X-22-173B”, “X-22-174D”, “X-22-167B”, and “X-22-161AS” (trade names), manufactured by Shin-Etsu Chemical Co., Ltd: “AK-5”, “AK-30”, and “AK-32” (trade names), manufactured by TOAGOSEI CO., LTD.: “SILAPLANE FM0725” and “SILAPLANE FM0721” (trade names), manufactured by CHISSO CORPORATION; “DMS-U22”, “RMS-033”, and “UMS-182” (trade names), manufactured by GELEST. INC.; “ACRIT 8SS-723” (trade name), manufactured by TAISEI FINE CHEMICAL CO., LTD.), and the like). Furthermore, the polysiloxane-based compounds described in Table 2 and Table 3 in JP2003-112383A can also be preferably used.

[Molecular Weight of Polysiloxane-Containing Compound]

The weight-average molecular weight of the polysiloxane-containing compound is preferably equal to or greater than 300, more preferably equal to or greater than 300 and equal to or smaller than 100,000, and even more preferably equal to or greater than 300 and equal to or smaller than 30,000. In a case where the weight-average molecular weight of the polysiloxane-containing compound is equal to or greater than 300, the localization of the polysiloxane-containing compound within the surface of the HC layer is accelerated, and the rub resistance and the hardness are further improved.

[Amount of Polysiloxane-Containing Compound Added]

The amount of the polysiloxane-containing compound added is preferably 0.01% to 5% by mass, more preferably 0.1% to 5% by mass, even more preferably 0.5% to 5% by mass, and particularly preferably 0.5% to 2% by mass, with respect to the total solid content in the curable composition for forming an HC layer. In a case where the amount of the polysiloxane-containing compound added is equal to or greater than the lower limit described above, the post-keystroke adhesion resistance can be further improved. It is preferable that the amount of the polysiloxane-containing compound added is equal to or smaller than the upper limit described above, because then the polysiloxane-containing compound, which is not thoroughly mixed with the polymerizable compound (resin component for forming an HC layer) in the curable composition for forming an HC layer, is not precipitated on the surface, and the bleaching of the HC layer or the occurrence of white powder on the surface is inhibited.

In a case where the HC layer has a laminated structure including two or more layers as will be described later, the amount of the polysiloxane-containing compound added means the amount of the polysiloxane-containing compound added to the curable composition for forming an HC layer that forms an HC layer containing a polysiloxane-containing compound.

(Surface Roughness Sa of Hardcoat Layer in Optical Film)

In the present invention, a surface roughness Sa of the hardcoat layer in the optical film means a surface roughness (hereinafter, simply referred to as surface roughness Sa as well) of a surface of a hardcoat layer that is opposite to the other surface of the hardcoat layer that is provided with a resin film in a state where the resin film and the hardcoat layer are laminated.

The surface roughness Sa of the hardcoat layer in a visual field of 4 mm×5 mm for measurement is preferably equal to or lower 60 nm, more preferably equal to or lower than 20 nm, and even more preferably equal to or lower than 10 nm. The lower limit thereof is substantially equal to or higher than 1 nm.

In a case where the hardcoat layer has another layer, which will be described later, on the surface (hereinafter, referred to as viewing side surface as well) opposite to the surface of the hardcoat layer that is provided with the resin film, the “surface roughness Sa of the hardcoat layer” means a surface roughness Sa of the hardcoat layer measured for an optical film in which the hardcoat layer is positioned on a viewing side uppermost surface of the optical film.

(HC Layer Obtained by Curing a Curable Composition for Forming Hardcoat Layer (HC Layer))

The HC layer used in the present invention can be obtained by curing a curable composition for forming an HC layer by irradiating the composition with active energy rays. In the present specification, “active energy rays” refer to ionizing radiation, and include X-rays, ultraviolet rays, visible rays, infrared rays, electron beams, a rays. (3 rays, y rays, and the like.

The curable composition for forming an HC layer used for forming the HC layer contains at least one kind of component (hereinafter, described as “active energy ray-curable component” as well) having a property of being cured by the irradiation of active energy rays. As the active energy ray-curable component, at least one kind of polymerizable compound is preferable which is selected from the group consisting of a radically polymerizable compound and a cationically polymerizable compound. In the present specification, “polymerizable compound” is a compound having a polymerizable group in a molecule. The number of polymerizable groups in one molecule may be equal to or greater than 1. The polymerizable group is a group which can take a part in a polymerization reaction, and specific examples thereof include groups contained in various polymerizable compounds which will be described later. Examples of the polymerization reaction include various polymerization reactions such as radical polymerization, cationic polymerization, and anionic polymerization.

The HC layer in the present invention is preferably obtained by polymerizing and curing the curable composition for forming an HC layer, which contains a polysiloxane-containing compound having a polymerizable group in a molecule, a fluorine-containing compound having a polymerizable group in a molecule, and a polymerizable compound that is either the polysiloxane-containing compound nor the fluorine-containing compound and has a polymerizable group in a molecule, by irradiating the curable composition with active energy rays. In this case, the polymerizable group that each of the polysiloxane-containing compound, the fluorine-containing compound, and the polymerizable compound has is more preferably a radically polymerizable group.

The HC layer used in the present invention may have a single layer structure or a laminated structure including two or more layers, but is preferably an HC layer having a single layer structure or a laminated structure including two or more layers that will be specifically described below.

1) Single Layer Structure

Examples of the preferred aspect of the curable composition for forming an HC layer having a single layer structure include, as a first aspect, a curable composition for forming an HC layer containing at least one kind of polymerizable compound having two or more ethylenically unsaturated groups in one molecule. The ethylenically unsaturated group refers to a functional group containing an ethylenically unsaturated double bond. Furthermore, as a second aspect, a curable composition for forming an HC layer can be exemplified which contains at least one kind of radically polymerizable compound and at least one kind of cationically polymerizable compound.

Hereinafter, the curable composition for forming an HC layer of the first aspect will be described.

Examples of the polymerizable compound having two or more ethylenically unsaturated groups in one molecule that is contained in the curable composition for forming an HC layer of the first aspect include esters of a polyhydric alcohol and (meth)acrylic acid [for example, ethylene glycol di(meth)acrylate, butanediol di(meth)acrylate, hexanediol di(meth)acrylate, 1,4-cyclohexane diacrylate, pentaerythritol tetra(meth)acrylate, pentaerythritol tri(meth)acrylate, trimethylolpropane tri(meth)acrylate, trimethylolethane tri(meth)acrylate, dipentaerythritol tetra(meth)acrylate, dipentaerythritol penta(meth)acrylate, dipentaerythritol hexa(meth)acrylate, pentaerythritol hexa(meth)acrylate, 1,2,3-cyclohexanetetramethacrylate, polyurethane polyacrylate, and polyester polyacrylate], ethylene oxide-modified products, polyethylene oxide-modified products, and caprolactone-modified products of the above esters, vinyl benzene and derivatives thereof [for example, 1,4-divinylbenzene, 4-vinylbenzoic acid-2-acryloyl ethyl ester, and 1,4-divinylcyclohexanone], vinyl sulfone (for example, divinyl sulfone], acrylamide (for example, methylenebisacrylamide), and methacrylamide.

The polymerizable compound having an ethylenically unsaturated group can be polymerized by the irradiation of active energy rays in the presence of a radical photopolymerization initiator. As the radical photopolymerization initiator, radical photopolymerization initiators which will be described later are preferably used. Regarding the ratio of the content of the radical photopolymerization initiator to the content of the polymerizable compound having an ethylenically unsaturated group in the curable composition for forming an HC layer, the description regarding the ratio of the content of the radical photopolymerization initiator to the content of the radically polymerizable group that will be explained later is preferably adopted.

Next, the curable composition for forming an HC layer of the second aspect will be described.

The curable composition for forming an HC layer of the second aspect contains at least one kind of radically polymerizable compound and at least one kind of cationically polymerizable compound. As a preferred aspect, a curable composition for forming an HC layer can be exemplified which contains a radically polymerizable compound containing two or more radically polymerizable groups selected from the group consisting of an acryloyl group and a methacryloyl group in one molecule; and a cationically polymerizable compound.

It is preferable that the curable composition for forming an HC layer contains a radical photopolymerization initiator and a cationic photopolymerization initiator. As a preferred aspect of the second aspect, a curable composition for forming an HC layer can be exemplified which contains a radically polymerizable compound containing two or more radically polymerizable groups selected from the group consisting of an acryloyl group and a methacryloyl group in one molecule; a cationically polymerizable compound; a radical photopolymerization initiator; and a cationic photopolymerization initiator. Hereinafter, this aspect will be described as second aspect (1).

In the second aspect (1), it is preferable that the radically polymerizable compound contains two or more radically polymerizable groups in one molecule and one or more urethane bonds in one molecule.

As another preferred aspect of the second aspect, a curable composition for forming an HC layer can be exemplified which contains a) cationically polymerizable compound containing an alicyclic epoxy group and an ethylenically unsaturated group and having a molecular weight equal to or smaller than 300, in which the number of alicyclic epoxy groups contained in one molecule is 1 and the number of ethylenically unsaturated groups contained in one molecule is 1; b) radically polymerizable compound containing three or more ethylenically unsaturated groups in one molecule; c) radical polymerization initiator: and d) cationic polymerization initiator. Hereinafter, this aspect will be described as second aspect (2). Regarding the HC layer obtained by curing the curable composition for forming an HC layer of the second aspect (2), provided that the total solid content of the HC layer is equal to or greater than 100% by mass, the HC layer can contain a structure derived from a) in an amount of 15% to 70% by mass, a structure derived from b) in an amount of 25% to 80% by mass, c) in an amount of 0.1% to 10% by mass, and d) in an amount of 0.1% to 10% by mass. In an aspect, provided that the total solid content of the curable composition for forming an HC layer is 100% by mass, it is preferable that the curable composition for forming an HC layer of the second aspect (2) contains a) in an amount of 15% to 70% by mass. “Alicyclic epoxy group” refers to a monovalent functional group having a cyclic structure in which an epoxy ring and a saturated hydrocarbon-based ring are fused.

Hereinafter, each of the components which can be contained in the curable composition for forming an HC layer of the second aspect and preferably the second aspect (1) or the second aspect (2) will be more specifically described.

—Radically Polymerizable Compound—

The curable composition for forming an HC layer of the second aspect contains at least one kind of radically polymerizable compound and at least one kind of cationically polymerizable compound. The radically polymerizable compound in the second aspect (1) contains two or more radically polymerizable groups selected from the group consisting of an acryloyl group and a methacryloyl group in one molecule. The number of radically polymerizable groups selected from the group consisting of an acryloyl group and a methacryloyl group that can be contained in one molecule of the radically polymerizable compound is preferably 2 to 10 for example, and more preferably 2 to 6.

As the radically polymerizable compound, a radically polymerizable compound having a molecular weight equal to or greater than 200 and less than 1,000 is preferable. In the present specification, for a multimer, “molecular weight” refers to a weight-average molecular weight which is measured by Gel Permeation Chromatography (GPC) and expressed in terms of polystyrene. As an example of specific measurement conditions of the weight-average molecular weight, the following measurement conditions can be exemplified.

GPC apparatus: HLC-8120 (manufactured by Tosoh Corporation)

Column: TSK gel Multipore HXL-M (manufactured by Tosoh Corporation, inner diameter of 7.8 mm×column length of 30.0 cm)

Eluent: tetrahydrofuran

As described above, the radically polymerizable compound preferably contains one or more urethane bonds in one molecule. The number of urethane bonds contained in one molecule of the radically polymerizable compound is preferably equal to or greater than 1, more preferably equal to or greater than 2, and even more preferably 2 to 5. For example, the radically polymerizable compound can contain two urethane bonds in one molecule. In the radically polymerizable compound containing two urethane bonds in one molecule, the radically polymerizable group selected from the group consisting of an acryloyl group and a methacryloyl group may be bonded to one of the urethane bonds directly or through a linking group or may be bonded to each of the two urethane bonds directly or through a linking group. In an aspect, it is preferable that one or more radically polymerizable groups selected from the group consisting of an acryloyl group and a methacryloyl group are bonded to each of two urethane bonds bonded to each other through a linking group.

More specifically, in the radically polymerizable compound, a urethane bond and a radically polymerizable group selected from the group consisting of an acryloyl group and a methacryloyl group may be directly bonded to each other, or a linking group may be present between a urethane bond and a radically polymerizable group selected from the group consisting of an acryloyl group and a methacryloyl group. The linking group is not particularly limited, and examples thereof include a linear or branched saturated or unsaturated hydrocarbon group, a cyclic group, a group obtained by combining two or more of these groups, and the like. The number of carbon atoms on the hydrocarbon group is about 2 to 20 for example but is not particularly limited. As an example of a cyclic structure contained in the cyclic group, an aliphatic ring (such as a cyclohexane ring), an aromatic ring (such as a benzene ring or a naphthalene ring), or the like can be exemplified. These groups may be unsubstituted or may have a substituent. Unless otherwise specified, a group described in the present specification may have a substituent or may be unsubstituted. In a case where a certain group has a substituent, examples of the substituent include an alkyl group (such as an alkyl group having 1 to 6 carbon atoms), a hydroxyl group, an alkoxy group (such as an alkoxy group having 1 to 6 carbon atoms), a halogen atom (such as a fluorine atom, a chlorine atom, or a bromine atom), a cyano group, an amino group, a nitro group, an acyl group, a carboxy group, and the like.

The radically polymerizable compound described so far can be synthesized by a known method, or may be obtained as a commercial product. As an example of the synthesis method, a method can be exemplified in which an alcohol, a polyol, and/or a hydroxyl group-containing compound such as hydroxyl group-containing (meth)acrylate are reacted with an isocyanate, and then, if necessary, a urethane compound obtained by the reaction is esterified using (meth)acrylic acid. Herein, “(meth)acrylic acid” means either or both of acrylic acid and methacrylic acid.

Examples of commercial products of the radically polymerizable compound containing one or more urethane bonds in one molecule include, but are not limited to, UA-306H, UA-306I, UA-306T, UA-510H, UF-8001G, UA-101I, UA-101T, AT-600, AH-600, AI-600, BPZA-66, and BPZA-100 manufactured by KYOEISHA CHEMICAL Co., LTD., U-4HA, U-6HA, U-6LPA, UA-32P, U-15HA, and UA-1100H manufactured by SHIN-NAKAMURA CHEMICAL CO., LTD., SHIKOH UV-1400B, SHIKOH UV-1700B, SHIKOH UV-6300B, SHIKOH UV-7550B, SHIKOH UV-7600B, SHIKOH UV-7605B, SHIKOH UV-7610B, SHIKOH UV-7620EA, SHIKOH UV-7630B, SHIKOH UV-7640B, SHIKOH UV-6630B, SHIKOH UV-7000B, SHIKOH UV-7510B, SHIKOH UV-7461TE, SHIKOH UV-3000B, SHIKOH UV-3200B, SHIKOH UV-3210EA, SHIKOH UV-3310EA, SHIKOH UV-3310B, SHIKOH UV-3500BA, SHIKOH UV-3520TL, SHIKOH UV-3700B, SHIKOH UV-6100B, SHIKOH UV-6640B, SHIKOH UV-2000B, SHIKOH UV-2010B, SHIKOH UV-2250EA, and SHIKOH UV-2750B manufactured by NIPPON GOHSEI, UL-503LN manufactured by KYOEISHA CHEMICAL Co., LTD., UNIDIC 17-806, UNIDIC 17-813, UNIDIC V-4030, and UNIDIC V-4000BA manufactured by DIC Corporation, EB-1290K manufactured by Daicel-UCB Company, Ltd., HI-COAP AU-2010 and HI-COAP AU-2020 manufactured by TOKUSHIKI Co., Ltd., and the like.

As specific examples of the radically polymerizable compound containing one or more urethane bond in one molecule, example compounds A-1 to A-8 will be shown below, but the present invention is not limited to the following specific examples.

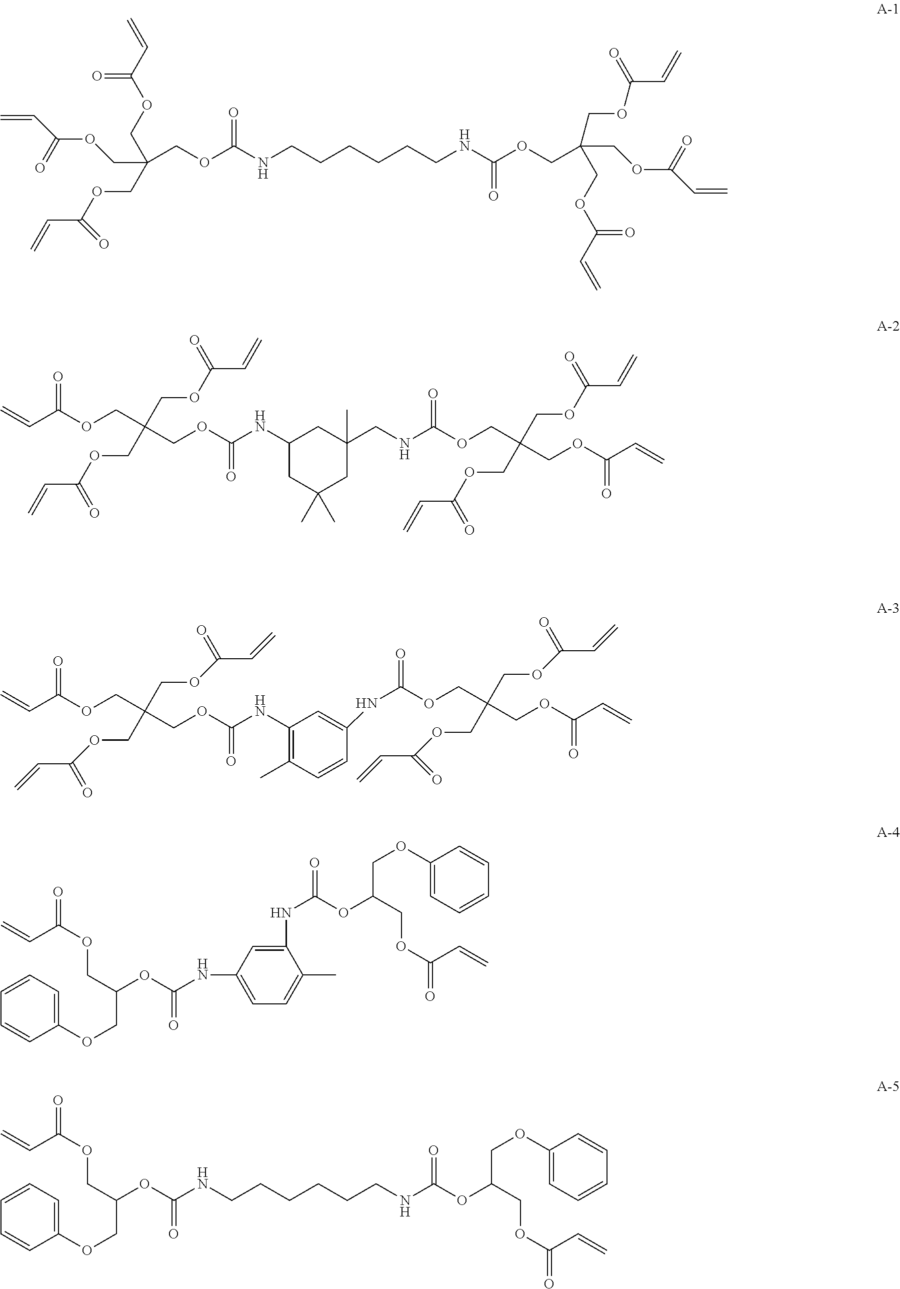

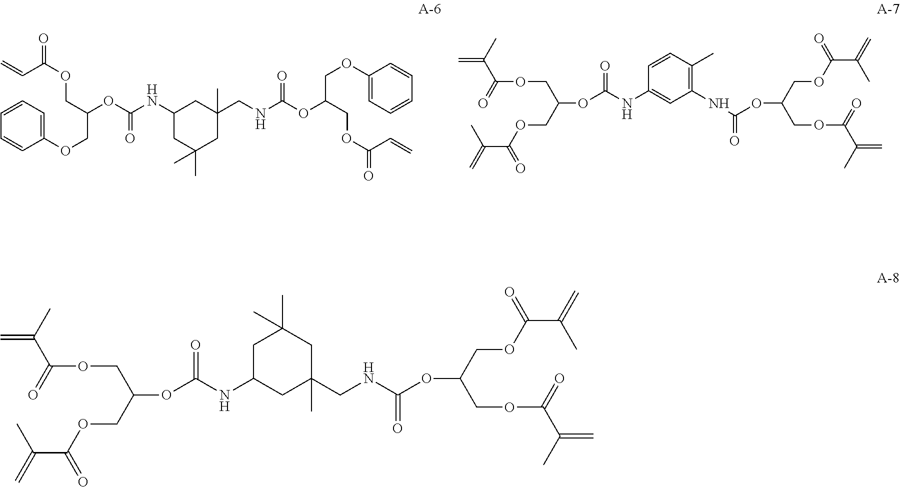 [SMILES: C=CC(=O)OCC(COc1ccccc1)OC(=O)NCC1(C)CC(NC(=O)OC(COC(=O)C=C)COc2ccccc2)CC(C)(C)C1 ; C=C(C)C(=O)OCC(COC(=O)C(=C)C)OC(=O)Nc1ccc(C)c(NC(=O)OC(COC(=O)C(=C)C)COC(=O)C(=C)C)c1 ; C=C(C)C(=O)OCC(COC(=O)C(=C)C)OC(=O)NCC1(C)CC(NC(=O)OC(COC(=O)C(=C)C)COC(=O)C(=C)C)CC(C)(C)C1]

Hitherto, the radically polymerizable compound containing one or more urethane bonds in one molecule has been described. The radically polymerizable compound containing two or more radically polymerizable groups selected from the group consisting of an acryloyl group and a methacryloyl group in one molecule may not have a urethane bond. Furthermore, the curable composition for forming an HC layer of the second aspect (1) may contain, in addition to the radically polymerizable compound containing two or more radically polymerizable groups selected from the group consisting of an acryloyl group and a methacryloyl group in one molecule, one or more kinds of radically polymerizable compounds other than the above radically polymerizable compound.

Hereinafter, the radically polymerizable compound which contains two or more radically polymerizable groups selected from the group consisting of an acryloyl group and a methacryloyl group in one molecule and contains one or more urethane bonds in one molecule methacryloyl group in one molecule and contains one or more urethane bonds in one molecule will be described as first radically polymerizable compound, and a radically polymerizable compound which does not correspond to the first radically polymerizable compound will be described as “second radically polymerizable compound” regardless of whether or not the radically polymerizable compound contains two or more radically polymerizable groups selected from the group consisting of an acryloyl group and a methacryloyl group in one molecule. The second radically polymerizable compound may have one or more urethane bonds in one molecule or may not have a urethane bond. In a case where the first radically polymerizable compound and the second radically polymerizable compound are used in combination, the mass ratio of first radically polymerizable compound/second radically polymerizable compound is preferably 3/1 to 1/30, more preferably 2/1 to 1/20, and even more preferably 1/1 to 1/10.

In the curable composition for forming an HC layer of the second aspect (1), the content of the radically polymerizable compound (it does not matter whether or not this compound contains a urethane bond) containing two or more radically polymerizable groups selected from the group consisting of an acryloyl group and a methacryloyl group in one molecule is preferably equal to or greater than 30% by mass, more preferably equal to or greater than 50% by mass, and even more preferably equal to or greater than 70% by mass, with respect to the total amount, 100% by mass, of the composition. Furthermore, in the curable composition for forming an HC layer of the second aspect (1), the content of the radically polymerizable compound (it does not matter whether or not this compound contains a urethane bond) containing two or more radically polymerizable groups selected from the group consisting of an acryloyl group and a methacryloyl group in one molecule is preferably equal to or smaller than 98% by mass, more preferably equal to or smaller than 95% by mass, and even more preferably equal to or smaller than 90% by mass, with respect to the total amount, 100% by mass, of the composition.

The content of the first radically polymerizable compound in the curable composition for forming an HC layer of the second aspect (1) with respect to the total amount, 100% by mass, of the composition is preferably equal to or greater than 30% by mass, more preferably equal to or greater than 50% by mass, and even more preferably equal to or greater than 70% by mass. Meanwhile, the content of the first radically polymerizable compound with respect to the total amount, 100% o by mass, of the composition is preferably equal to or smaller than 98% by mass, more preferably equal to or smaller than 95% by mass, and even more preferably equal to or smaller than 90% by mass.

In an aspect, the second radically polymerizable compound is preferably a radically polymerizable compound which contains two or more radically polymerizable groups in one molecule and does not have a urethane bond. The radically polymerizable group contained in the second radically polymerizable compound is preferably an ethylenically unsaturated group. In an aspect, the radically polymerizable group is preferably a vinyl group. In another aspect, the ethylenically unsaturated group is preferably a radically polymerizable group selected from the group consisting of an acryloyl group and a methacryloyl group. That is, it is preferable that the second radically polymerizable compound has one or more radically polymerizable groups selected from the group consisting of an acryloyl group and a methacryloyl group in one molecule and does not have a urethane bond. Furthermore, as a radically polymerizable compound, the second radically polymerizable compound can contain one or more radically polymerizable groups selected from the group consisting of an acryloyl group and a methacryloyl group and one or more radically polymerizable groups other than this in one molecule.

The number of radically polymerizable groups contained in one molecule of the second radically polymerizable compound is preferably at least 2, more preferably equal to or greater than 3, and even more preferably equal to or greater than 4. In an aspect, the number of radically polymerizable groups contained in one molecule of the second radically polymerizable compound is equal to or less than 10 for example, but may be greater than 10. As the second radically polymerizable compound, a radically polymerizable compound having a molecular weight equal to or greater than 200 and less than 1,000 is preferable.

The following compounds can be exemplified as the second radically polymerizable compound, but the present invention is not limited to the following example compounds.

Examples of the second radically polymerizable compound include bifunctional (meth)acrylate compounds such as polyethylene glycol 200 di(meth)acrylate, polyethylene glycol 300 di(meth)acrylate, polyethylene glycol 400 di(meth)acrylate, polyethylene glycol 600 di(meth)acrylate, triethylene glycol di(meth)acrylate, epichlorohydrin-modified ethylene glycol di(meth)acrylate (as a commercial product, for example, DENACOL DA-811 manufactured by NAGASE & CO., LTD.), polypropylene glycol 200 di(meth)acrylate, polypropylene glycol 400 di(meth)acrylate, polypropylene glycol 700 di(meth)acrylate, Ethylene Oxide (hereinafter, abbreviated to “EO” as well).Propylene Oxide (hereinafter, abbreviated to “PO” as well) block polyether di(meth)acrylate (as a commercial product, for example, a BLEMMER PET series manufactured by NOF CORPORATION), dipropylene glycol di(meth)acrylate, bisphenol A EO addition-type di(meth)acrylate (as a commercial product, for example, M-210 manufactured by TOAGOSEI CO., LTD. or NK ESTER A-BPE-20 manufactured by SHIN-NAKAMURA CHEMICAL CO., LTD.), hydrogenated bisphenol A EO addition-type di(meth)acrylate (such as NK ESTER A-HPE-4 manufactured by SHIN-NAKAMURA CHEMICAL CO., LTD.), bisphenol A PO-addition type di(meth)acrylate (as a commercial product, for example, LIGHT ACRYLATE BP-4PA manufactured by KYOEISHA CHEMICAL Co., LTD.), bisphenol A epichlorohydrin addition-type di(meth)acrylate (as a commercial product, for example, EBECRYL 150 manufactured by Daicel-UCB Company. Ltd.), bisphenol A EO.PO addition-type di(meth)acrylate (as a commercial product, for example, BP-023-PE manufactured by TOHO Chemical Industry Co., Ltd.), bisphenol F EO addition-type di(meth)acrylate (as a commercial product, for example, ARONIX M-208 manufactured by TOAGOSEI CO., LTD.), 1,6-hexanediol di(meth)acrylate, 1,6-hexanediol di(meth)acrylate modified with epichlorohydrin, neopentyl glycol di(meth)acrylate, hydroxypivalic acid neopentyl glycol di(meth)acrylate, hydroxypivalic acid neopentyl glycol di(meth)acrylate modified with caprolactone, 1,4-butanediol di(meth)acrylate, 1,9-nonanediol di(meth)acrylate, trimethylolpropane di(meth)acrylate, tricyclodecane dimethanol di(meth)acrylate, pentaerythritol di(meth)acrylate monostearate, trimethylolpropane acrylic acid-benzoic acid ester, and isocyanuric acid EO-modified di(meth)acrylate (as a commercial product, for example, ARONIX M-215 manufactured by TOAGOSEI CO., LTD.).

Examples of the second radically polymerizable compound also include trifunctional (meth)acrylate compounds such as trimethylolpropane tri(meth)acrylate, trimethylolpropane tri(meth)acrylate modified with EO. PO, or epichlorohydrin, pentaerythritol tri(meth)acrylate, glycerol tri(meth)acrylate, glycerol tri(meth)acrylate modified with EO, PO, or epichlorohydrin, isocyanuric acid EO-modified tri(meth)acrylate (as a commercial product, for example, ARONIX M-315 manufactured by TOAGOSEI CO., LTD.), tris(meth)acryloyloxyethyl phosphate, (2,2,2-tri-(meth)acryloyloxymethyl)ethyl hydrogen phthalate, glycerol tri(meth)acrylate, and glycerol tri(meth)acrylate modified with EO, PO, or epichlorohydrin: tetrafunctional (meth)acrylate compounds such as pentaerythritol tetra(meth)acrylate, pentaerythritol tetra(meth)acrylate modified with EO, PO, or epichlorohydrin, and ditrimethylolpropane tetra(meth)acrylate: pentafunctional (meth)acrylate compounds such as dipentaerythritol penta(meth)acrylate and dipentaerythritol penta(meth)acrylate modified with EO, PO, epichlorohydrin, fatty acid, or alkyl; and hexafunctional (meth)acrylate compounds such as dipentaerythritol hexa(meth)acrylate, dipentaerythritol hexa(meth)acrylate modified with EO, PO, epichlorohydrin, fatty acid, or alkyl, sorbitol hexa(meth)acrylate, and sorbitol hexa(meth)acrylate modified with EO, PO, epichlorohydrin, fatty acid, or alkyl.

Two or more kinds of second radically polymerizable compounds may be used in combination. In this case, a mixture “DPHA” (manufactured by Nippon Kayaku Co., Ltd) of dipentaerythritol pentaacrylate and dipentaerythritol hexaacrylate and the like can be preferably used.

As the second radically polymerizable compound, polyester (meth)acrylate and epoxy (meth)acrylate having a weight-average molecular weight equal to or greater than 200 and less than 1,000 are also preferable. Examples thereof include commercial polyester (meth)acrylate products such as a BEAMSET (trade name) 700 series, for example, BEAMSET 700 (hexafunctional), BEAMSET 710 (tetrafunctional), and BEAMSET 720 (trifunctional)) manufactured by Arakawa Chemical Industries, Ltd. Examples of the epoxy (meth)acrylate include an SP series such as SP-1506, 500, SP-1507, and 480 (trade names) as well as a VR series such as VR-77 manufactured by Showa Highpolymer Co., Ltd., EA-1010/ECA, EA-11020, EA-1025, EA-6310/ECA (trade names) manufactured by SHIN-NAKAMURA CHEMICAL CO., LTD., and the like.

Specific examples of the second radically polymerizable compound also include the following example compounds A-9 to A-11i.

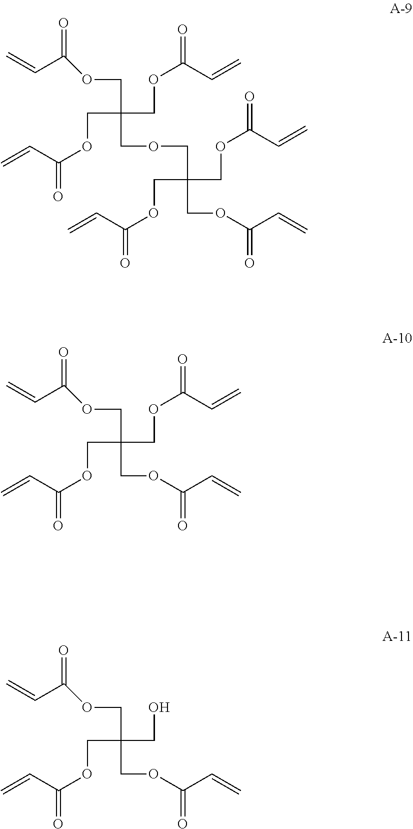

The curable composition for forming an HC layer of the second aspect (2), which is a preferred aspect of the second aspect, contains b) radically polymerizable compound containing three or more ethylenically unsaturated groups in one molecule. Hereinafter, b) compound containing three or more ethylenically unsaturated groups in one molecule will be described as “b) component” as well.

Examples of b) component include an ester of a polyhydric alcohol and (meth)acrylic acid, vinyl benzene and a derivative thereof, vinyl sulfone, (meth)acrylamide, and the like. Among these, a radically polymerizable compound containing three or more radically polymerizable groups selected from the group consisting of an acryloyl group and a methacryloyl group in one molecule is preferable. Specifically, examples thereof include a compound which is an ester of a polyhydric alcohol and (meth)acrylic acid and contains three or more ethylenically unsaturated groups in one molecule. More specifically, examples thereof include (di)pentaerythritol tetra(meth)acrylate, (di)pentaerythritol tri(meth)acrylate, trimethylolpropane tri(meth)acrylate, EO-modified trimethylolpropane tri(meth)acrylate, PO-modified trimethylolpropane tri(meth)acrylate, EO-modified phosphoric acid tri(meth)acrylate, trimethylolethane tri(meth)acrylate, ditrimethylolpropane tetra(meth)acrylate, dipentaerythritol tetra(meth)acrylate, (di)pentaerythritol penta(meth)acrylate, dipentaerythritol hexa(meth)acrylate, pentaerythritol hexa(meth)acrylate, 1,2,3-cyclohexanetetramethacrylate, polyurethane polyacrylate, polyester polyacrylate, caprolactone-modified tris(acryloxy ethyl)isocyanurate, tripentaerythritol triacrylate, tripentaerythritol hexatriacrylate, 1,2,4-cyclohexanetetra(meth)acrylate, pentaglycerol triacrylate, and the like. “(Di)pentaerythritol” described above means either or both of pentaerythritol and dipentaerythritol.

Furthermore, a resin is also preferable which contains three or more radically polymerizable groups selected from the group consisting of an acryloyl group and a methacryloyl group in one molecule.

Examples of the resin containing three or more radically polymerizable groups selected from the group consisting of an acryloyl group and a methacryloyl group in one molecule include a polyester-based resin, a polyether-based resin, an acrylic resin, an epoxy-based resin, a urethane-based resin, an alkyd-based resin, a spiroacetal-based resin, a polybutadiene-based resin, a polythiol polyene-based resin, a polymer of a polyfunctional compound such as a polyhydric alcohol, and the like.

Specific examples of the radically polymerizable compound containing three or more radically polymerizable groups selected from the group consisting of an acryloyl group and a methacryloyl group in one molecule include example compounds described in paragraph “0096” in JP2007-256844A, and the like.

Specific examples of the radically polymerizable compound containing three or more radically polymerizable groups selected from the group consisting of an acryloyl group and a methacryloyl group in one molecule include esterified substances of a polyol and (meth)acrylic acid such as KAYARAD DPHA, KAYARAD DPHA-2C, KAYARAD PET-30, KAYARAD TMPTA, KAYARAD TPA-320, KAYARAD TPA-330, KAYARAD RP-1040, KAYARAD T-1420, KAYARAD D-310, KAYARAD DPCA-20. KAYARAD DPCA-30, KAYARAD DPCA-60, and KAYARAD GPO-303 manufactured by Nippon Kayaku Co., Ltd., and V#400 and V#36095D manufactured by OSAKA ORGANIC CHEMICAL INDUSTRY LTD. Furthermore, it is also possible to suitably use urethane acrylate compounds having three or more functional groups such as SHIKOH UV-1400B, SHIKOH UV-1700B, SHIKOH UV-6300B, SHIKOH UV-7550B, SHIKOH UV-7600B, SHIKOH UV-7605B, SHIKOH UV-7610B, SHIKOH UV-7620EA, SHIKOH UV-7630B, SHIKOH UV-7640B, SHIKOH UV-6630B, SHIKOH UV-7000B, SHIKOH UV-7510B, SHIKOH UV-7461TE, SHIKOH UV-3000B, SHIKOH UV-3200B, SHIKOH UV-3210EA, SHIKOH UV-3310EA, SHIKOH UV-3310B, SHIKOH UV-3500BA, SHIKOH UV-3520TL, SHIKOH UV-3700B, SHIKOH UV-6100B, SHIKOH UV-6640B, SHIKOH UV-2000B, SHIKOH UV-2010B, SHIKOH UV-2250EA, and SHIKOH UV-2750B (manufactured by NIPPON GOHSEI), UL-503LN (manufactured by KYOEISHA CHEMICAL Co., LTD), UNIDIC 17-806, UNIDIC 17-813, UNIDIC V-4030, and UNIDIC V-4000BA (manufactured by DIC Corporation), EB-1290K, EB-220, EB-5129, EB-1830, and EB-4358 (manufactured by Daicel-UCB Company, Ltd.), HI-COAP AU-2010 and HI-COAP AU-2020 (manufactured by TOKUSHIKI Co., Ltd.), ARONIX M-1960 (manufactured by TOAGOSEI CO., LTD.), and ART RESIN UN-3320HA, UN-3320HC, UN-3320HS, UN-904, and HDP-4T, polyester compounds having three or more functional groups such as ARONIX M-8100, M-8030, and M-9050 (manufactured by TOAGOSEI CO., LTD.) and KBM-8307 (manufactured by Daicel SciTech), and the like.

As b) component, one kind of component may be used singly, or two or more kinds of components having different structures may be used in combination.

As described above, regarding the HC layer obtained by curing the curable composition for forming an HC layer of the second aspect (2), provided that the total solid content of the HC layer is 100% by mass, the HC layer can contain a structure derived from a) in an amount of 15% to 70% by mass, a structure derived from b) in an amount of 25% to 80% by mass, c) in an amount of 0.1% to 10%, by mass, and d) in an amount of 0.1% to 10% by mass. Provided that the total solid content of the HC layer is 100% by mass, the content of the structure derived from b) in the HC layer is preferably 40% to 75% by mass, and more preferably 60% to 75% by mass. Furthermore, provided that the total solid content of the curable composition for forming an HC layer of the second aspect (2) is 100% by mass, the content of b) component in the composition is preferably 40% to 75% by mass, and more preferably 60% to 75% by mass.

—Cationically Polymerizable Compound—

It is preferable that the curable composition for forming an HC layer of the second aspect contains at least one kind of radically polymerizable compound and at least one kind of cationically polymerizable compound. Any of cationically polymerizable compounds can be used without limitation as long as the compounds have a polymerizable group which can be cationically polymerized (cationically polymerizable group). The number of cationically polymerizable groups contained in one molecule is at least 1. The cationically polymerizable compound may be a monofunctional compound containing one cationically polymerizable group or a polyfunctional compound containing two or more cationically polymerizable groups in one molecule. The number of cationically polymerizable groups contained in the polyfunctional compound is not particularly limited. For example, the polyfunctional compound contains 2 to 6 cationically polymerizable groups in one molecule. Furthermore, the polyfunctional compound may contain two or more kinds of cationically polymerizable groups, which are the same as each other or have different structures, in one molecule.

In addition, in an aspect, it is preferable that the cationically polymerizable compound has one or more radically polymerizable groups in one molecule together with the cationically polymerizable groups. Regarding the radically polymerizable group that the cationically polymerizable compound has, the above description for the radically polymerizable compound can be referred to. The radically polymerizable group is preferably an ethylenically unsaturated group, and the ethylenically unsaturated group is more preferably a radically polymerizable group selected from the group consisting of a vinyl group, an acryloyl group, and a methacryloyl group. The number of radically polymerizable groups in one molecule of the cationically polymerizable compound having a radically polymerizable group is at least 1, preferably 1 to 3, and more preferably 1.

As the cationically polymerizable group, an oxygen-containing heterocyclic group and a vinyl ether group can be preferably exemplified. The cationically polymerizable compound may contain one or more oxygen-containing heterocyclic groups and one or more vinyl ether groups in one molecule.

The oxygen-containing heterocyclic ring may be a monocyclic ring or a condensed ring. Furthermore, it is also preferable that the oxygen-containing heterocyclic ring has a bicyclo skeleton. The oxygen-containing heterocyclic ring may be a non-aromatic ring or an aromatic ring, and is preferably a non-aromatic ring. Specific examples of the monocyclic ring include an epoxy ring, a tetrahydrofuran ring, and an oxetane ring. Examples of the oxygen-containing heterocyclic ring having a bicyclo skeleton include an oxabicyclo ring. The cationically polymerizable group containing the oxygen-containing heterocyclic ring is contained in the cationically polymerizable compound as a monovalent substituent or a polyvalent substituent with a valency of 2 or higher. The aforementioned condensed ring may be a ring formed by the condensation of two or more oxygen-containing heterocyclic rings or a ring formed by the condensation of one or more oxygen-containing heterocyclic rings and one or more ring structures other than the oxygen-containing heterocyclic ring. The ring structure other than the oxygen-containing heterocyclic ring is not limited to the above, and examples thereof include a cycloalkane ring such as a cyclohexane ring.

Specific examples of the oxygen-containing heterocyclic ring will be shown below but the present invention is not limited to the following specific examples.

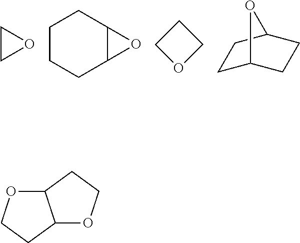

The cationically polymerizable compound may have a partial structure other than the cationically polymerizable group. The partial structure is not particularly limited, and may be a linear, branched, or cyclic structure. The partial structure may contain one or more heteroatoms such as oxygen atoms or nitrogen atoms.

As a preferred aspect of the cationically polymerizable compound, a compound (cyclic structure-containing compound) can be exemplified which has a cyclic structure as the cationically polymerizable group or as a partial structure other than the cationically polymerizable group. The cyclic structure-containing compound may have one cyclic structure in one molecule for example. The cyclic structure-containing compound may have two or more cyclic structures in one molecule. The number of cyclic structures contained in one molecule of the cyclic structure-containing compound is 1 to 5 for example, but is not particularly limited. In a case where the compound contains two or more cyclic structures in one molecule, the cyclic structures may be the same as each other. Alternatively, the compound may contain two or more kinds of cyclic structures having different structures.

As an example of the cyclic structure contained in the cyclic structure-containing compound, an oxygen-containing heterocyclic ring can be exemplified. The details of the oxygen-containing heterocyclic ring are as described above.

A cationically polymerizable group equivalent determined by dividing the molecular weight (hereinafter, described as “B”) by the number of cationically polymerizable groups (hereinafter, described as “C”) contained in one molecule of the cationically polymerizable compound (=B/C) is equal to or smaller than 300, for example. From the viewpoint of improving the adhesiveness between the HC layer obtained by curing the curable composition for forming an HC layer and the resin film, the cationically polymerizable group equivalent is preferably less than 150. In contrast, from the viewpoint of the hygroscopicity of the HC layer obtained by curing the curable composition for forming an HC layer, the cationically polymerizable group equivalent is preferably equal to or greater than 50. Furthermore, in an aspect, the cationically polymerizable group contained in the cationically polymerizable compound for which the cationically polymerizable group equivalent is determined can be an epoxy group (epoxy ring). That is, in an aspect, the cationically polymerizable compound is an epoxy ring-containing compound. For the epoxy ring-containing compound, from the viewpoint of improving the adhesiveness between the HC layer obtained by curing the curable composition for forming an HC layer and the resin film, an epoxy group equivalent, which is determined by dividing the molecular weight by the number of epoxy rings contained in one molecule, is preferably less than 150. The epoxy group equivalent of the epoxy ring-containing compound is equal to or greater than 50, for example.

The molecular weight of the cationically polymerizable compound is preferably equal to or smaller than 500, and more preferably equal to or smaller than 300. Presumably, the cationically polymerizable compound whose molecular weight is within the above range tends to easily permeate the resin film and can make a contribution to the improvement of the adhesiveness between the HC layer obtained by curing the curable composition for forming an HC layer and the resin film.

The curable composition for forming an HC layer of the second aspect (2) contains a) cationically polymerizable compound containing an alicyclic epoxy group and an ethylenically unsaturated group and having molecular weight equal to or smaller than 300, in which the number of alicyclic epoxy groups contained in one molecule is 1, and the number of ethylenically unsaturated groups contained in one molecule is 1. Hereinafter, a) will be described as “a) component”.

Examples of the ethylenically unsaturated group include a radically polymerizable group including an acryloyl group, a methacryloyl group, a vinyl group, a styryl group, an allyl group, and the like. Among these, an acryloyl group, a methacryloyl group, and C(O)OCH═CH₂ are preferable, and an acryloyl group and a methacryloyl group are more preferable. Each of the number of alicyclic epoxy groups in one molecule and the number of ethylenically unsaturated groups in one molecule is preferably 1.

The molecular weight of a) component is equal to or smaller than 300, preferably equal to or smaller than 210, and more preferably equal to or smaller than 200.

As a preferred aspect of a) component, a compound represented by General Formula (1) can be exemplified.

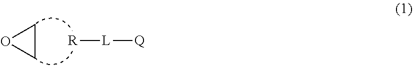

In General Formula (1), R represents monocyclic hydrocarbon or crosslinked hydrocarbon, L represents a single bond or a divalent linking group, and Q represents an ethylenically unsaturated group.

In a case where R in General Formula (1) is monocyclic hydrocarbon, the monocyclic hydrocarbon is preferably alicyclic hydrocarbon, more preferably an alicyclic group having 4 to 10 carbon atoms, even more preferably an alicyclic group having 5 to 7 carbon atoms, and particularly preferably an alicyclic group having 6 carbon atoms. Preferable specific examples thereof include a cyclobutyl group, a cyclopentyl group, a cyclohexyl group, a cycloheptyl group, and the like. Among these, a cyclohexyl group is more preferable.

In a case where R in General Formula (1) is crosslinked hydrocarbon, the crosslinked hydrocarbon is preferably a bicyclic crosslinked hydrocarbon (bicyclo ring) or a tricyclic crosslinked hydrocarbon (tricyclo ring). Specific examples thereof include crosslinked hydrocarbon having 5 to 20 carbon atoms such as a norbornyl group, a bornyl group, an isobornyl group, a tricyclodecyl group, a dicyclopentenyl group, a dicyclopentanyl group, a tricyclopentenyl group, a tricyclopentanyl group, an adamantyl group, or a lower alkyl group (having 1 to 6 carbon atoms for example)-substituted adamantyl group.

In a case where L represents a divalent linking group, the divalent linking group is preferably a divalent aliphatic hydrocarbon group. The number of carbon atoms in the divalent aliphatic hydrocarbon group is 1 to 6, more preferably 1 to 3, and even more preferably 1. As the divalent aliphatic hydrocarbon group, a linear, branched, or cyclic alkylene group is preferable, a linear or branched alkylene group is more preferable, and a linear alkylene group is even more preferable.

Examples of Q include an ethylenically unsaturated group including an acryloyl group, a methacryloyl group, a vinyl group, a styryl group, an allyl group, or the like. Among these, an acryloyl group, a methacryloyl group, and C(O)OCH═CH₂ are preferable, and an acryloyl group and a methacryloyl group are more preferable.

Specific examples of a) component include various compounds exemplified in paragraph “0015” in JP 1998-017614A (JP-H10-017614A), a compound represented by General Formula (1A) or (1B), 1,2-epoxy-4-vinylcyclohexane, and the like. Among these, the compound represented by General Formula (1A) or (1B) is more preferable. As the compound represented by General Formula (1A), an isomer thereof is also preferable.

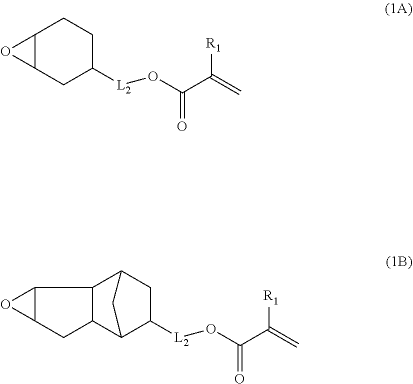

In General Formulae (1A) and (1B), R₁ represents a hydrogen atom or a methyl group, and L₂ represents a divalent aliphatic hydrocarbon group having 1 to 6 carbon atoms.

The number of carbon atoms in the divalent aliphatic hydrocarbon group represented by L₂ in General Formulae (1A) and (1B) is 1 to 6, more preferably 1 to 3, and even more preferably 1. As the divalent aliphatic hydrocarbon group, a linear, branched, or cyclic alkylene group is preferable, a linear or branched alkylene group is more preferable, and a linear alkylene group is even more preferable.

Regarding the HC layer obtained by curing the curable composition for forming an HC layer of the second aspect (2), provided that the total solid content of the HC layer is 100% by mass, the HC layer contains a structure derived from a) preferably in an amount of 15% to 70% o by mass, more preferably in an amount of 18% to 50% by mass, and even more preferably in an amount of 22% to 40% by mass. Furthermore, provided that the total solid content of the curable composition for forming an HC layer of the second aspect (2) is 100% by mass, the composition contains a) component preferably in an amount of 15% to 70% by mass, more preferably in an amount of 18% to 50% by mass, and even more preferably in an amount of 22% to 40% by mass.

As another example of the cyclic structure contained in the cyclic structure-containing compound, a nitrogen-containing heterocyclic ring can be exemplified. The nitrogen-containing heterocyclic ring-containing compound is the cationically polymerizable compound which is preferable from the viewpoint of improving the adhesiveness between the HC layer obtained by curing the curable composition for forming an HC layer and the resin film. As the nitrogen-containing heterocyclic ring-containing compound, a compound is preferable which has one or more nitrogen-containing heterocyclic rings selected from the group consisting of an isocyanurate ring (nitrogen-containing heterocyclic ring contained in example compounds B-1 to B-3 which will be described later) and a glycoluril ring (nitrogen-containing heterocyclic ring contained in an example compound B-10 which will be described later) in one molecule. Among these, from the viewpoint improving the adhesiveness between the HC layer obtained by curing the curable composition for forming an HC layer and the resin film, the compound containing an isocyanurate ring (isocyanurate ring-containing compound) is more preferably a cationically polymerizable compound. The inventors of the present invention assume that this is because the isocyanurate ring has excellent affinity with the resin constituting the resin film. In this respect, a resin film including an acrylic resin film is more preferable, and a resin film is more preferable which includes an acrylic resin film as a surface directly contacting the HC layer obtained by curing the curable composition for forming an HC layer.

As another example of the cyclic structure contained in the cyclic structure-containing compound, an alicyclic structure can be exemplified. Examples of the alicyclic structure include a cyclo ring structure, a dicyclo ring structure, and a tricyclo ring structure. Specific examples thereof include a dicyclopentanyl ring, a cyclohexane ring, and the like.

The cationically polymerizable compound described so far can be synthesized by a known method, and can be obtained as a commercial product.

Specific examples of the cationically polymerizable compound containing an oxygen-containing heterocyclic ring as a cationically polymerizable group include 3,4-epoxycyclohexylmethyl methacrylate (commercial products such as CYCLOMER M100 manufactured by Daicel Corporation), 3,4-epoxycyclohexylmethyl-3′,4′-epoxycyclohexane carboxylate (for example, commercial products such as UVR 6105 and UVR 6110 manufactured by Union Carbide Corporation and CELLOXIDE 2021 manufactured by Daicel Corporation), bis(3,4-epoxycyclohexylmethyl)adipate (such as UVR 6128 manufactured by Union Carbide Corporation), vinylcyclohexene monoepoxide (such as CELLOXIDE 2000 manufactured by Daicel Corporation), e-caprolactam-modified 3,4-epoxycyclohexylmethyl 3′,4′-epoxycyclohexane carboxylate (such as CELLOXIDE 2081 manufactured by Daicel Corporation), 1-methyl-4-(2-methyloxiranyl)-7-oxabicyclo[4,1,0]heptane (such as CELLOXIDE 3000 manufactured by Daicel Corporation), 7,7′-dioxa-3,3′-bi[bicyclo[4.1.0]heptane] (such as CELLOXIDE 8000 manufactured by Daicel Corporation), 3-ethyl-3-hydroxymethyloxetane, 1,4 bis {[(3-ethyl-3-oxetanyl)methoxy]methyl}benzene, 3-ethyl-3-(phenoxymethyl)oxetane, 3-ethyl-3-(2-ethylhexyloxymethyl)oxetane, di[1-ethyl(3-oxetanyl)]methyl ether, and the like.

Specific examples of the cationically polymerizable compound containing a vinyl ether group as a cationically polymerizable group include 1,4-butanediol divinyl ether, 1,6-hexanediol divinyl ether, nonanediol divinyl ether, cyclohexanediol divinyl ether, cyclohexane dimethanol divinyl ether, triethylene glycol divinyl ether, trimethylolpropane trivinyl ether, pentaerythritol tetravinyl ether, and the like. As the cationically polymerizable compound containing a vinyl ether group, those having an alicyclic structure are also preferable.

Furthermore, as the cationically polymerizable compound, it is possible to use the compounds exemplified in JP1996-143806A (JP-H08-143806A), JP 996-283320A (JP-H08-283320A), JP2000-186079A, JP2000-327672A, JP2004-315778A, JP2005-029632A, and the like.

As specific examples of the cationically polymerizable compound, example compounds B-1 to B-14 will be shown below, but the present invention is not limited to the following specific examples.

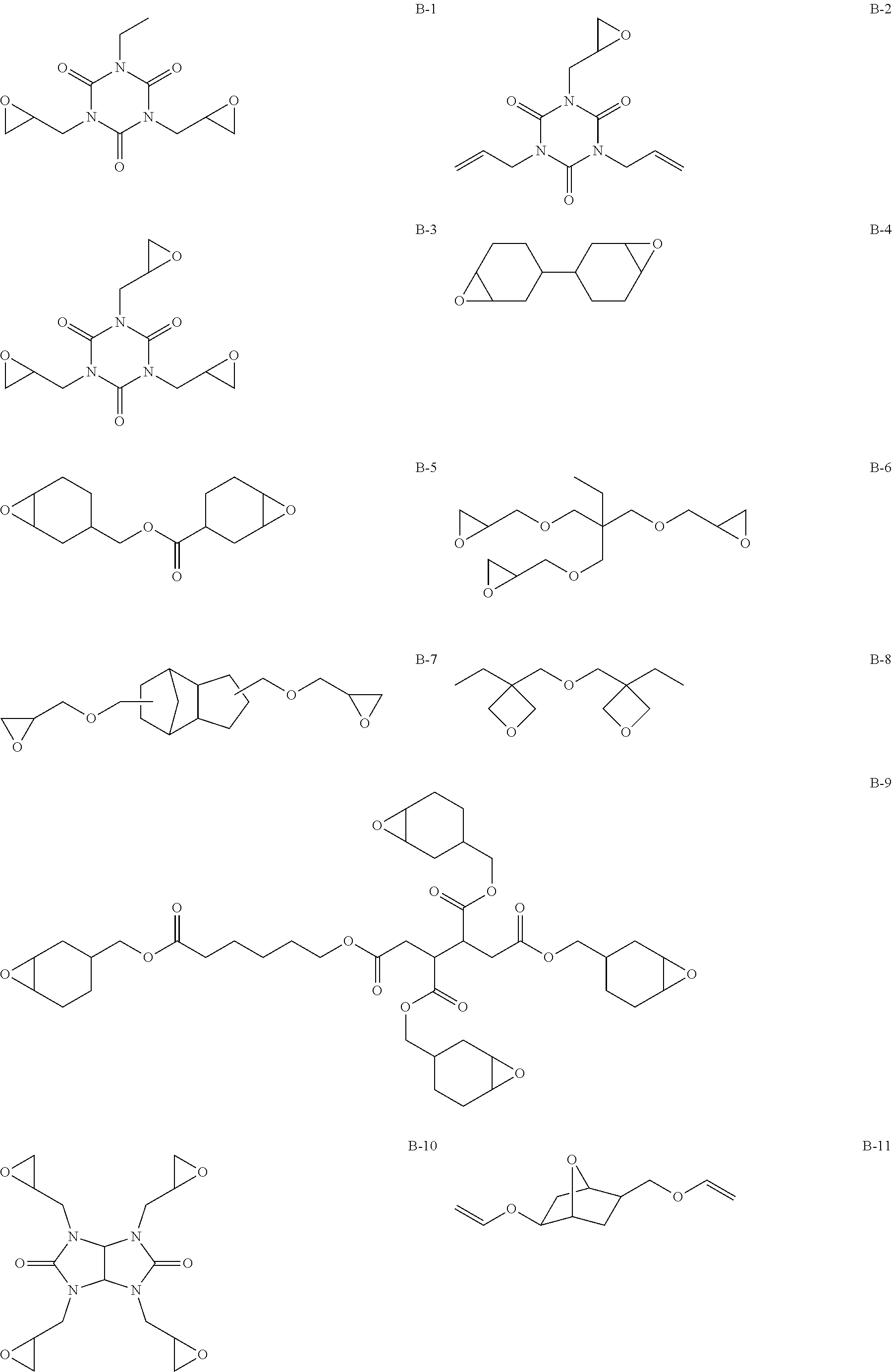

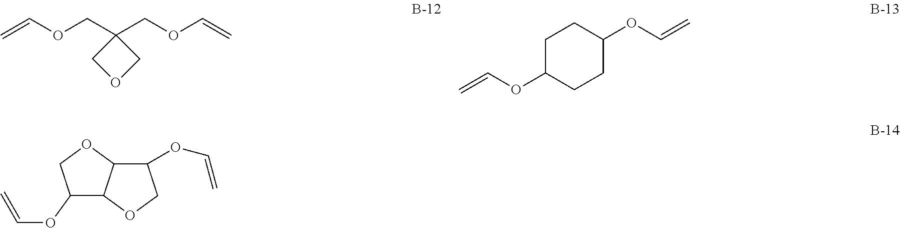

From the viewpoint of improving the adhesiveness between the HC layer obtained by curing the curable composition for forming an HC layer and the resin film, as preferred aspects of the curable composition for forming an HC layer, the following aspects can be exemplified. The curable composition for forming an HC layer more preferably satisfies one or more aspects among the following aspects, even more preferably satisfies two or more aspects, still more preferably satisfies three or more aspects, and yet more preferably satisfies all of the following aspects. It is preferable that one cationically polymerizable compound satisfies a plurality of aspects. For example, an aspect is preferable in which the cationically polymerizable group equivalent of the nitrogen-containing heterocyclic ring-containing compound is less than 150.

(1) The curable composition for forming an HC layer contains a nitrogen-containing heterocyclic ring-containing compound as a cationically polymerizable compound. The nitrogen-containing heterocyclic ring contained in the nitrogen-containing heterocyclic ring-containing compound is preferably selected from the group consisting of an isocyanurate ring and a glycoluril ring. The nitrogen-containing heterocyclic ring-containing compound is more preferably an isocyanurate ring-containing compound. The isocyanurate ring-containing compound is even more preferably an epoxy ring-containing compound containing one or more epoxy rings in one molecule.

(2) The curable composition for forming an HC layer contains a cationically polymerizable compound having a cationically polymerizable group equivalent less than 150 as a cationically polymerizable compound, and preferably contains an epoxy group-containing compound having an epoxy group equivalent less than 150.

(3) The cationically polymerizable compound contains an ethylenically unsaturated group.

(4) The curable composition for forming an HC layer contains, as cationically polymerizable compounds, an oxetane ring-containing compound containing one or more oxetane rings in one molecule in addition to another cationically polymerizable compound. The oxetane ring-containing compound is preferably a compound which does not contain a nitrogen-containing heterocyclic ring.

The content of the cationically polymerizable compound in the curable composition for forming an HC layer with respect to the total content, 100 parts by mass, of the radically polymerizable compound and the cationically polymerizable compound is preferably equal to or greater than 10 parts by mass, more preferably equal to or greater than 15 parts by mass, and even more preferably equal to or greater than 20 parts by mass. The content of the cationically polymerizable compound in the curable composition for forming an HC layer with respect to the total content, 100 parts by mass, of the radically polymerizable compound and the cationically polymerizable compound is preferably equal to or smaller than 50 parts by mass.

The content of the cationically polymerizable compound in the curable composition for forming an HC layer with respect to the total content, 100 parts by mass, of the first radically polymerizable compound and the cationically polymerizable compound is preferably equal to or greater than 0.05 parts by mass, more preferably equal to or greater than 0.1 parts by mass, and even more preferably equal to or greater than 1 part by mass. Meanwhile, the content of the cationically polymerizable compound with respect to the total content, 100 parts by mass, of the first radically polymerizable compound and the cationically polymerizable compound is preferably equal to or smaller than 50 parts by mass, and more preferably equal to or smaller than 40 parts by mass.

In the present specification, a compound having both the cationically polymerizable group and the radically polymerizable group is classified as a cationically polymerizable compound so as to specify content thereof in the curable composition for forming an HC layer.

—Polymerization Initiator—

The curable composition for forming an HC layer preferably contains a polymerization initiator, and more preferably contains a photopolymerization initiator. The curable composition for forming an HC layer containing the radically polymerizable compound preferably contains a radical photopolymerization initiator, and the curable composition for forming an HC layer containing the cationically polymerizable compound preferably contains a cationic photopolymerization initiator. Only one kind of radical photopolymerization initiator may be used, or two or more kinds of radical photopolymerization initiators having different structures may be used in combination. The same shall be applied for the cationic photopolymerization initiator.

Hereinafter, each of the photopolymerization initiators will be sequentially described.

(i) Radical Photopolymerization Initiator

The radical photopolymerization initiator may be a compound that generates a radical as an active species by light irradiation, and known radical photopolymerization initiators can be used without limitation. Specific examples thereof include acetophenones such as diethoxyacetophenone, 2-hydroxy-2-methyl-1-phenylpropan-1-one, benzyl dimethyl ketal, 4-(2-hydroxyethoxy)phenyl-(2-hydroxy-2-propyl)ketone, 1-hydroxycyclohexyl phenyl ketone, 2-methyl-2-morpholino(4-thiomethylphenyl)propan-1-one, 2-benzyl-2-dimethylamino-1-(4-morpholinophenyl)-1-butanone, a 2-hydroxy-2-methyl-1-[4-(1-methylvinyl)phenyl]propane oligomer, and 2-hydroxy-1-{4-[4-(2-hydroxy-2-methyl-propionyl)-benzyl]phenyl}-2-methyl-propan-1-one; oxime esters such as 1,2-octanedione, 1-[4-(phenylthio)-,2-(O-benzoyloxime)], ethanone, 1-[9-ethyl-6-(2-methylbenzoyl)-9H-carbazol-3-yl]-,1-(0-acetyloxime): benzoins such as benzoin, benzoin methyl ether, benzoin ethyl ether, benzoin isopropyl ether, and benzoin isobutyl ether: benzophenones such as benzophenone, methyl o-benzoyl benzoate, 4-phenylbenzophenone, 4-benzoyl-4′-methyl-diphenyl sulfide, 3,3′,4,4′-tetra(t-butylperoxycarbonyl)benzophenone, 2,4,6-trimethylbenzophenone, 4-benzoyl-N,N-dimethyl-N-[2-(1-oxo-2-propenyloxy)ethyl]benzene methanaminium bromide, and (4-benzoylbenzyl)trimethyl ammonium chloride; thioxanthones such as 2-isopropylthioxanthone, 4-isopropylthioxanthone, 2,4-diethylthioxanthone, 2,4-dichlorothioxanthone, 1-chloro-4-propoxythioxanthone, and 2-(3-dimethylamino-2-hydroxy)-3,4-dimethyl-9H-thioxanthone-9-one methochloride; acylphosphine oxides such as 2,4,6-trimethylbenzoyl-diphenylphosphine oxide, bis(2,6-dimethoxybenzoyl)-2,4,4-trimethyl-pentylphosphine oxide, and bis(2,4,6-trimethylbenzoyl)-phenylphosphine oxide; and the like. Furthermore, as an aid for the radical photopolymerization initiator, triethanolamine, triisopropanolamine, 4,4′-dimethylaminobenzophenone (Michler's ketone), 4,4′-diethylaminobenzophenone, 2-dimethylaminoethyl benzoate, ethyl 4-dimethylaminobenzoate, (n-butoxy)ethyl 4-dimethylaminobenzoate, isoamyl 4-dimethylaminobenzoate, 2-ethylhexyl 4-dimethylaminobenzoate, 2,4-diethylthioxanthone, 2,4-diisopropylthioxanthone, and the like may be used in combination.

The aforementioned radical photopolymerization initiators and aids can be synthesized by a known method or can be obtained as commercial products. Examples of preferable commercial radical photopolymerization initiators include IRGACURE (127, 651, 184, 819, 907, 1870 (CGI-403/Irg184=7/3 mixed initiator, 500, 369, 1173, 2959, 4265, 4263, or the like), and OXE01) manufactured by BASF SE, KAYACURE (DETX-S, BP-100, BDMK, CTX, BMS, 2-EAQ, ABQ, CPTX, EPD, ITX, QTX, BTC, MCA, and the like) manufactured by Nippon Kayaku Co., Ltd., Esacure (KIP100F, KBI, EB3, BP, X33, KT046, KT37, KIP150, TZT, and the like) manufactured by Sartomer, and the like.

The content of the radical photopolymerization initiator in the curable composition for forming an HC layer may be appropriately adjusted within a range in which the polymerization reaction (radical polymerization) of the radically polymerizable compound is excellently carried out, and is not particularly limited. The content of the radical photopolymerization initiator with respect to 100 parts by mass of the radically polymerizable compound contained in the curable composition for forming an HC layer is 0.1 to 20 parts by mass for example, preferably 0.5 to 10 parts by mass, and even more preferably 1 to 10 parts by mass.

(ii) Cationic Photopolymerization Initiator

As the cationic photopolymerization initiator, a compound which can generate a cation as an active species by light irradiation is preferable, and known cationic photopolymerization initiators can be used without limitation. Specific examples thereof include a sulfonium salt, an ammonium salt, an iodonium salt (such as a diaryl iodonium salt), a triaryl sulfonium salt, a diazonium salt, an iminium salt, and the like that are known. More specifically, examples thereof include the cationic photopolymerization initiators represented by Formulae (25) to (28) shown in paragraphs “0050” to “0053” in JP1996-143806A (JP-H08-143806A), the compounds exemplified as cationic polymerization catalysts in paragraph “0020” in JP1996-283320A (JP-H08-283320A), and the like. The cationic photopolymerization initiator can be synthesized by a known method, or can be obtained as a commercial product. For example, as the commercial product, it is possible to use CI-1370, CI-2064, CI-2397, CI-2624, CI-2639, CI-2734, CI-2758, CI-2823, CI-2855, CI-5102, and the like manufactured by NIPPON SODA CO., LTD., PHOTOINITIATOR 2047 and the like manufactured by Rhodia, UVI-6974 and UVI-6990 manufactured by Union Carbide Corporation, CPI-10P manufactured by San-Apro Ltd., and the like.

In view of the sensitivity of the photopolymerization initiator with respect to light, the compound stability, and the like, a diazonium salt, an iodonium salt, a sulfonium salt, and an iminium salt are preferable as the cationic photopolymerization initiator. In view of weather fastness, an iodonium salt is most preferable.

Specific examples of commercial products of the iodonium salt-based cationic photopolymerization initiator include B2380 manufactured by TOKYO CHEMICAL INDUSTRY CO., LTD., BBI-102 manufactured by Midori Kagaku Co., Ltd., WPI-113, WPI-124, WPI-169, WPI-170 manufactured by Wako Pure Chemical Industries, Ltd., and DTBPI-PFBS manufactured by Toyo Gosei Co., Ltd.

Specific examples of iodonium salt compounds which can be used as the cationic photopolymerization initiator include the following compounds PAG-1 and PAG-2.

Cationic photopolymerization initiator (iodonium salt compound) PAG-1

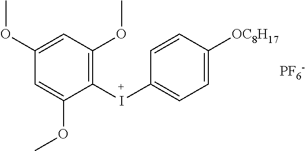

Cationic photopolymerization initiator (iodonium salt compound) PAG-2

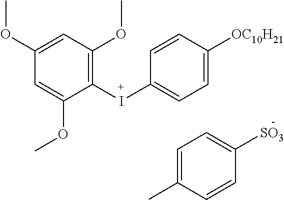

The content of the cationic photopolymerization initiator in the curable composition for forming an HC layer may be appropriately adjusted within a range in which the polymerization reaction (cationic polymerization) of the cationically polymerizable compound is excellently carried out, and is not particularly limited. The content of the cationic photopolymerization initiator with respect to 100 parts by mass of the cationically polymerizable compound is 0.1 to 200 parts by mass for example, preferably 1 to 150 parts by mass, and more preferably 2 to 100 parts by mass.

As other photopolymerization initiators, the photopolymerization initiators described in paragraphs “0052” to “0055” in JP2009-204725A can be exemplified, and the content of the publication is incorporated into the present invention.

—Components which can be Optionally Incorporated into Curable Composition for Forming HC Layer—

The curable composition for forming an HC layer contains at least one kind of component having a property of being cured by being irradiated with active energy rays, a fluorine-containing compound, and a polysiloxane-containing compound, and can optionally contain at least one kind of polymerization initiator. It is preferable that the composition contains the polymerization initiator. The details of the polymerization initiator are as described above.

Next, each of the components that can be optionally incorporated into the curable composition for forming an HC layer will be described.

(i) Inorganic Particles

The curable composition for forming an HC layer can contain inorganic particles having an average primary particle diameter less than 2 μm. From the viewpoint of improving the hardness of the front panel having the HC layer obtained by curing the curable composition for forming an HC layer (and improving the hardness of a liquid crystal panel having the front panel), it is preferable that the curable composition for forming an HC layer and the HC layer obtained by curing the composition contain inorganic particles having an average primary particle diameter less than 2 μm. The average primary particle diameter of the inorganic particles is preferably 10 nm to 1 μm, more preferably 10 nm to 100 nm, and even more preferably 10 nm to 50 nm.

For determining the average primary particle diameter of the inorganic particles and matt particles which will be described later, the particles are observed using a transmission electron microscope (500,000× to 2,000,000× magnification), randomly selected 100 particles (primary particles) are observed, and the average of the particle diameters thereof is taken as the average primary particle diameter.

Examples of the inorganic particles include silica particles, titanium dioxide particles, zirconium oxide particles, aluminum oxide particles, and the like. Among these, silica particles are preferable.

In order to improve the affinity of the inorganic particles with organic components contained in the curable composition for forming an HC layer, it is preferable that the surface of the inorganic particles is treated with a surface modifier including an organic segment. It is preferable that the surface modifier has a functional group, which can form a bond with the inorganic particles or can be adsorbed onto the inorganic particles, and a functional group, which has high affinity with an organic component, in the same molecule. As the surface modifier having a functional group which can form a bond with the inorganic particles or can be adsorbed onto the inorganic particles, a silane-based surface modifier, a metal alkoxide surface modifier such as aluminum, titanium, and zirconium, or a surface modifier having an anionic group such as a phosphoric acid group, a sulfuric acid group, a sulfonic acid group, or a carboxylic acid group is preferable. Examples of the functional group having high affinity with an organic component include a functional group having the same hydrophilicity and hydrophobicity as those of the organic component, a functional group which can be chemically bonded to the organic component, and the like. Among these, the functional group which can be chemically bonded to the organic component and the like are preferable, and an ethylenically unsaturated group or a ring-opening polymerizable group is more preferable.

As the surface modifier for the inorganic particles, a metal alkoxide surface modifier or a polymerizable compound, which has an anionic group and an ethylenically unsaturated group or a ring-opening polymerizable group in the same molecule, is preferable. By chemically bonding the inorganic particles and the organic components to each other by using these surface modifiers, and crosslinking density of the HC layer can be increased. As a result, the hardness of the front panel (and the hardness of a liquid crystal panel including the front panel) can be improved.

Specific examples of the surface modifier include the following example compounds S-1 to S-8.

S-1H₂C═C(X)COOC₃H₆Si(OCH₃)₃

S-2H₂C═C(X)COOC₂H₄OTi(OC₂H)₃

S-3H₂C═C(X)COOC₂H₄OCOC₅H₁₀OPO(OH)₂

S-4 (H₂C═C(X)COOC₂H₄OCOC₅H₁₀O)₂POOH

S-5H₂C═C(X)COOC₂H₄OSO₃H

S-6H₂C═C(X)COO(C₅H₁₀COO)₂H

S-7H₂C═C(X)COOC₅H₁₀COOH

S-8 CH₂CH(O)CH₂OC₃H₆Si(OCH₃)₃

(X represents a hydrogen atom or a methyl group.)

It is preferable that the surface modification for the inorganic particles by the surface modifier is performed in a solution. The surface modification may be performed by a method in which a surface modifier is allowed to coexist at the time of mechanically dispersing the inorganic particles, a method in which the inorganic particles are mechanically dispersed and then a surface modifier is added thereto and stirred, or a method in which the surface modification is performed before the inorganic particles are mechanically dispersed (if necessary, the inorganic particles are warmed and dried and then subjected to heating or changing of pH (power of hydrogen)) and then the inorganic particles are dispersed. As a solvent for dissolving the surface modifier, an organic solvent having high polarity is preferable, and specific examples thereof include known solvents such as an alcohol, a ketone, and an ester.

Provided that the total solid content in the curable composition for forming an HC layer is 100% by mass, the content of the inorganic particles is preferably equal to or smaller than 20% by mass, more preferably equal to or smaller than 17% by mass, and even more preferably less than 8% by mass. The lower limit of the content is not particularly limited, and may be 0% by mass (the HC layer may not contain the inorganic particles). In a case where the HC layer contains the inorganic particles, the lower limit of the content of the inorganic particles is preferably equal to or greater than 1% by mass, and more preferably equal to or greater than 7% by mass. It does not matter whether the primary particles of the inorganic particles have a spherical shape or a non-spherical shape. However, it is preferable that the primary particles of the inorganic particles have a spherical shape. From the viewpoint of further improving the hardness, it is more preferable that in the HC layer obtained by curing the curable composition for forming an HC layer, the inorganic particles are present as non-spherical high-order particles of the order equal to or higher than that of secondary particles in which two to ten spherical inorganic particles (primary particles) are linked to each other.

Specific examples of the inorganic particles include ELCOM V-8802 (spherical silica particles having an average primary particle diameter of 15 nm manufactured by JGC CORPORATION), ELCOM V-8803 (silica particles of irregular shapes manufactured by JGC CORPORATION). MiBK-SD (spherical silica particles having an average primary particle diameter of 10 to 20 nm manufactured by NISSAN CHEMICAL INDUSTRIES, LTD.), MEK-AC-2140Z (spherical silica particles having an average primary particle diameter of 10 to 20 nm manufactured by NISSAN CHEMICAL INDUSTRIES, LTD.), MEK-AC-4130 (spherical silica particles having an average primary particle diameter of 45 nm manufactured by NISSAN CHEMICAL INDUSTRIES, LTD.), MiBK-SD-L (spherical silica particles having an average primary particle diameter of 40 to 50 nm manufactured by NISSAN CHEMICAL INDUSTRIES, LTD.), MEK-AC-5140Z (silica particles having an average primary particle diameter of 85 nm manufactured by NISSAN CHEMICAL INDUSTRIES, LTD.), and the like. Among these, from the viewpoint of further improving hardness, ELCOM V-8802 manufactured by JGC CORPORATION is preferable.

(ii) Matt Particles

The curable composition for forming an HC layer can also contain matt particles. The matt particles mean particles having an average primary particle diameter equal to or greater than 2 μm. The matt particles may be inorganic particles or organic particles, or may be particles of an inorganic-organic composite material. It does not matter whether the matt particles have a spherical shape or a non-spherical shape. The average primary particle diameter of the matt particles is preferably 2 to 20 μm, more preferably 4 to 14 μm, and even more preferably 6 to 10 μm.

Specific examples of the matt particles preferably include inorganic particles such as silica particles and TiO₂ particles and organic particles such as crosslinked acryl particles, crosslinked acryl-styrene particles, crosslinked styrene particles, melamine resin particles, and benzoguanamine resin particles. Among these, organic particles are preferable as the matt particles, and crosslinked acryl particles, crosslinked acryl-styrene particles, or crosslinked styrene particles are more preferable.

The content of the matt particles per unit volume of the HC layer obtained by curing the curable composition for forming an HC layer is preferably equal to or greater than 0.10 g/cm³, more preferably 0.10 g/cm³ to 0.40 g/cm³, and even more preferably 0.10 g/cm³ to 0.30 g/cm³.

(iii) Ultraviolet Absorber

It is also preferable that the curable composition for forming an HC layer contains an ultraviolet absorber. Examples of the ultraviolet absorber include a benzotriazole compound and a triazine compound. The benzotriazole compound mentioned herein is a compound having a benzotriazole ring, and specific examples thereof include various benzotriazole-based ultraviolet absorbers described in paragraph “0033” in JP2013-111835A. The triazine compound is a compound having a triazine ring, and specific examples thereof include various triazine-based ultraviolet absorbers described in paragraph “0033” in JP2013-111835A. The content of the ultraviolet absorber in the resin film is, for example, about 0.1 to 10 parts by mass with respect to 100 parts by mass of the resin contained in the film, but is not particularly limited. Regarding the ultraviolet absorber, paragraph “0032” in JP2013-111835A can also be referred to. In the present specification, the ultraviolet rays mean the light having a central emission wavelength in a wavelength range of 200 to 380 nm.

(iv) Leveling Agent

It is also preferable that the curable composition for forming an HC layer contains a leveling agent and an antifoulant.

As the leveling agent, a fluorine-containing polymer is preferably used. Examples thereof include the fluoroaliphatic group-containing polymer described in JP5175831B. Furthermore, a fluoroaliphatic group-containing polymer, in which the content of a fluoroaliphatic group-containing monomer represented by General Formula (1) constituting the fluoroaliphatic group-containing polymer is equal to or smaller than 50% by mass with respect to all polymerization units, can also be used as a leveling agent.

The curable composition for forming an HC layer can also contain the leveling agent described in (vi) Other components, which will be described later, in addition to the above components.

In a case where the curable composition for forming an HC layer contains the leveling agent, the content of the leveling agent with respect to the solid content of the curable composition for forming an HC layer is preferably 0.01% to 7% by mass, more preferably 0.05% to 5% by mass, and even more preferably 0.1% to 2% by mass.

The curable composition for forming an HC layer may contain only one kind of leveling agent or two or more kinds of leveling agents. In a case where the composition contains two or more kinds of leveling agents, it is preferable that the total content thereof is within the above range.

(v) Solvent

It is also preferable that the curable composition for forming an HC layer contains a solvent. As the solvent, an organic solvent is preferable. One kind of organic solvent can be used, or two or more kinds of organic solvents can be used by being mixed together at any ratio. Specific examples of the organic solvent include alcohols such as methanol, ethanol, propanol, n-butanol, and i-butanol; ketones such as acetone, methyl isobutyl ketone, methyl ethyl ketone, and cyclohexanone; cellosolves such as ethyl cellosolve; aromatic solvents such as toluene and xylene; glycol ethers such as propylene glycol monomethyl ether; acetic acid esters such as methyl acetate, ethyl acetate, and butyl acetate; diacetone alcohol; and the like. Among these, cyclohexanone, methyl ethyl ketone, methyl isobutyl ketone, and methyl acetate are preferable, and a mixture of cyclohexanone, methyl ethyl ketone, methyl isobutyl ketone, and methyl acetate which are mixed at any ratio is more preferably used. In a case where the above constitution is adopted, an optical film having better rub resistance, punching properties, and adhesiveness is obtained.

The amount of the solvent in the curable composition for forming an HC layer can be appropriately adjusted within a range in which coating suitability of the composition can be secured. For example, the content of the solvent with respect to the total amount, 100 parts by mass, of the polymerizable compound and the photopolymerization initiator can be 50 to 500 parts by mass, and preferably 80 to 200 parts by mass.

The solid content in the curable composition for forming an HC layer is preferably 10% to 90% by mass, more preferably 50% to 80% by mass, and particularly preferably 65% to 75% by mass.

(vi) Other Components

The curable composition for forming an HC layer can contain one or more kinds of known additives in any amount, in addition to the above components. Examples of the additives include a surface conditioner, a leveling agent, a polymerization inhibitor, polyrotaxane, and the like. For the details of these, paragraphs “0032” to “0034” in JP2012-229412A can be referred to. However, the additives are not limited to these, and various additives generally added to the curable composition for forming an HC layer can be used.

The curable composition for forming an HC layer can be prepared by simultaneously mixing together the various components described above or by sequentially mixing them together in an arbitrary order. The preparation method is not particularly limited, and a known stirrer or the like can be used for preparation.

2) Laminated Structure Including Two or More Layers

For the optical film according to the embodiment of the present invention, an aspect is also preferable in which the HC layer 2A shown in FIG. 1 has at least a first HC layer and a second HC layer in this order from the resin film 1A side.

The first HC layer may be positioned on the surface of the resin film 1A, or there may be another layer between the resin film 1A and the first HC layer. Likewise, the second HC layer may be positioned on the surface of the first HC layer, or there may be another layer between the first HC layer and the second HC layer. From the viewpoint of improving the adhesiveness between the first HC layer and the second HC layer, it is preferable that the second HC layer is positioned on the surface of the first HC layer, that is, the first and second HC layers contact each other in at least a portion within the film surface.

Each of the first HC layer and the second HC layer may be constituted with one layer or two or more layers, and is preferably constituted with one layer.

In a case where the optical film according to the embodiment of the present invention is used in a touch panel as will be specifically described later, it is preferable that the optical film is disposed such that the second HC layer becomes the front surface side of the image display device. In order to improve the rub resistance and the punching properties of the surface of the optical film, it is preferable that the second HC layer is disposed on the surface side, particularly, on the uppermost surface of the optical film.

<First HC Layer and Curable Composition for Forming First HC Layer>

The first HC layer used in the present invention is formed of a curable composition for forming a first HC layer.

It is preferable that the curable composition for forming a first HC layer contains a polymerizable compound 1 having a radically polymerizable group and a polymerizable compound 2 which has a cationically polymerizable group and a radically polymerizable group in the same molecule and is different from the polymerizable compound 1.

(Polymerizable Compound)

As the polymerizable compound 1, the description of the aforementioned radically polymerizable compound is preferably adopted, and as the polymerizable compound 2, the description of a) component in the aforementioned cationically polymerizable compound is preferably adopted.

The curable composition for forming a first HC layer may have another polymerizable compound different from the polymerizable compound 1 and the polymerizable compound 2.

Another polymerizable compound described above is preferably a polymerizable compound having a cationically polymerizable group. The cationically polymerizable group has the same definition as the cationically polymerizable group described above regarding the polymerizable compound 2, and the preferable range thereof is also the same. Particularly, in the present invention, as another polymerizable compound described above, a nitrogen-containing heterocyclic ring-containing compound containing a cationically polymerizable group is preferable. In a case where such a compound is used, the adhesiveness between the resin film and the first HC layer can be more effectively improved.

Examples of the nitrogen-containing heterocyclic ring include a nitrogen-containing heterocyclic ring selected from the group consisting of isocyanurate rings (nitrogen-containing heterocyclic rings contained in the example compounds B-1 to B-3 which will be described later) and glycoluril rings (nitrogen-containing heterocyclic rings contained in the example compound B-10 which will be described later). As the nitrogen-containing heterocyclic ring, an isocyanurate ring is more preferable. The number of cationic groups contained in another polymerizable compound described above is preferably 1 to 10, and more preferably 2 to 5. In a case where a polymerizable compound having a cationically polymerizable group and a nitrogen-containing heterocyclic ring structure is used as another polymerizable compound described above, as the resin film, a resin film including an acrylic resin film is preferable. In a case where this constitution is adopted, the adhesiveness between the resin film and the first HC layer tends to be further improved.

Specific examples of another polymerizable compound described above include example compounds B-1 to B-14 described above, but the present invention is not limited to the specific examples.

(Others)

In addition, the description of the polymerization initiator, the inorganic particles, the matt particles, the ultraviolet absorber, the fluorine-containing compound, the solvent, and other components can also be preferably adopted.

Particularly, the curable composition for forming a first HC layer preferably contains a solvent, and a curable composition for forming a second HC layer preferably contains a polysiloxane-containing compound and a fluorine-containing compound.

(Thickness of HC Layer)

The thickness of the HC layer is preferably equal to or greater than 3 μm and equal to or smaller than 100 μm more preferably equal to or greater than 5 μm and equal to or smaller than 70 μm, and even more preferably equal to or greater than 10 μm and equal to or smaller than 50 μm.

(Pencil Hardness of HC Layer)

The higher the pencil hardness of the HC layer, the better. Specifically, the pencil hardness of the HC layer is preferably equal to or higher than 3H, more preferably equal to or higher than 5H, and even more preferably equal to or higher than 7H.

—Method for Forming HC Layer—

By coating the resin film with the curable composition for forming an HC layer directly or through another layer such as an easily adhesive layer and irradiating the composition with active energy rays, the HC layer can be formed. The coating can be performed by known coating methods such as a dip coating method, an air knife coating method, a curtain coating method, a roller coating method, a die coating method, a wire bar coating method, and a gravure coating method. By simultaneously or sequentially coating the resin film with two or more kinds of compositions having different makeups, an HC layer having a laminated structure including two or more layers (for example, about two to five layers) can also be formed.

By irradiating the curable composition for forming an HC layer, with which the resin film is coated, with active energy rays, the HC layer can be formed. For example, in a case where the curable composition for forming an HC layer contains a radically polymerizable compound, a cationically polymerizable compound, a radical photopolymerization initiator, and a cationic photopolymerization initiator, a polymerization reaction between the radically polymerizable compound and the cationically polymerizable compound can be initiated and proceed by the action of a radical photopolymerization initiator and a cationic photopolymerization initiator respectively. The wavelength of radiated light may be determined according to the type of the polymerizable compound and the polymerization initiator used. Examples of light sources for light irradiation include a high-pressure mercury lamp, an ultrahigh-pressure mercury lamp, a carbon arc lamp, a metal halide lamp, a xenon lamp, a chemical lamp, an electrodeless discharge lamp, a Light Emitting Diode (LED), and the like that emit light in a wavelength range of 150 to 450 nm. The light irradiation amount is generally 30 to 3,000 mJ/cm², and preferably 100 to 1,500 mJ/cm². If necessary, a drying treatment may be performed before or after the light irradiation or before and after the light irradiation. The drying treatment can be performed by hot air blowing, disposing the resin film with the composition in a heating furnace, or transporting the resin film with the composition in a heating furnace, and the like. In a case where the curable composition for forming an HC layer contains a solvent, the heating temperature may be set to be a temperature at which the solvent can be dried and removed, but the heating temperature is not particularly limited. Herein, the heating temperature means the temperature of hot air or the internal atmospheric temperature of the heating furnace.

(3) Other Layers

If necessary, the optical film according to the embodiment of the present invention may be provided with other layers such as a pressure sensitive adhesive layer and a cushioning layer (a shock absorbing layer) in addition to the resin film and the HC layer described above.

(Pressure Sensitive Adhesive Layer)

The optical film according to the embodiment of the present invention may have a pressure sensitive adhesive layer on a surface of the resin film that is opposite to the surface of the resin film provided with the HC layer. For example, an aspect of the optical film having the pressure sensitive adhesive layer includes an optical film 4B according to an embodiment of the present invention that is constituted with an HC layer 2A, a resin film 1A, and a pressure sensitive adhesive layer 3A laminated in this order as shown in FIG. 2.

The material of the pressure sensitive adhesive layer is not particularly limited, and may be a pressure sensitive adhesive or an adhesive. Examples thereof include an acrylic pressure sensitive adhesive, a urethane-based pressure sensitive adhesive, a synthetic rubber-based pressure sensitive adhesive, a natural rubber-based pressure sensitive adhesive, and a silicon-based pressure sensitive adhesive. Among these, an acrylic pressure sensitive adhesive is preferable. From the viewpoint of productivity, it is preferable that the material of the pressure sensitive adhesive layer contains an ionizing radiation-curable group and can be cured by ionizing radiation.

The thickness of the pressure sensitive adhesive layer is preferably equal to or smaller than 100 μm, more preferably equal to or smaller than 50 μm, and even more preferably equal to or smaller than 15 μm. Provided that the pressure sensitive adhesive layer is excessively thick, in a case where a laminate is formed by pressure-bonding the resin film and the pressure sensitive adhesive layer by using a roller or the like, a variation in pressure occurs, and as a result, sometimes an optical film having a predetermined surface roughness Sa cannot be obtained.

Hereinafter, as a specific aspect, a pressure sensitive adhesive layer containing an acrylic pressure sensitive adhesive will be described, but the present invention is not limited to the following specific aspect.

(Specific Aspect of Pressure Sensitive Adhesive Layer)

Examples of the acrylic pressure sensitive adhesive include an acrylic pressure sensitive adhesive containing at least a (meth)acrylic acid ester polymer A having a weight-average molecular weight of 500,000 to 3,000,000 or containing a component obtained by crosslinking the (meth)acrylic acid ester polymer A and a (meth)acrylic acid ester polymer B having a weight-average molecular weight of 8,000 to 300,000. By increasing the proportion of the (meth)acrylic acid ester polymer B having a smaller weight-average molecular weight between the (meth)acrylic acid ester polymer A and the (meth)acrylic acid ester polymer B, the stress relaxation rate of the pressure sensitive adhesive layer can be increased. By decreasing the proportion of the (meth)acrylic acid ester polymer B, a stress relaxation rate of the pressure sensitive adhesive layer can be reduced. In the components described above, the proportion of the (meth)acrylic acid ester polymer B with respect to 100 parts by mass of the (meth)acrylic acid ester polymer A is preferably 5 to 50 parts by mass, and more preferably 10 to 30 parts by mass.

For the details of the (meth)acrylic acid ester polymer A and the (meth)acrylic acid ester polymer B included in the components described above, paragraphs “0020” to “0046” in JP2012-214545A can be referred to. Furthermore, for the details of crosslinking agents for crosslinking these, paragraphs “0049” to “0058” in JP2012-214545A can be referred to.

It is preferable that the acrylic pressure sensitive adhesive contains a silane coupling agent. For the details of the silane coupling agent, paragraphs “0059” to “0061” in JP2012-214545A can be referred to. Furthermore, for the details of the method for preparing the acrylic pressure sensitive adhesive and the additives or solvents which can be optionally incorporated into the acrylic pressure sensitive adhesive, paragraphs “0062” to “0071” in JP2012-214545A can be referred to.

In an aspect, the acrylic pressure sensitive adhesive is applied to a release-treated surface of a release sheet having undergone a release treatment and dried so as to form a pressure sensitive adhesive layer, and in this way, a pressure sensitive adhesive sheet including the pressure sensitive adhesive layer can be formed. By bonding the pressure sensitive adhesive layer of the pressure sensitive adhesive sheet to the resin film described above, an optical film having a pressure sensitive adhesive layer can be formed.

(Cushioning Layer)

The optical film according to the embodiment of the present invention may have a cushioning layer on a surface of the resin film that is opposite to the surface (that is, the viewing side surface) of the resin film provided with the HC layer. For example, in a case where the optical film according to the embodiment of the present invention is used as a front panel of an image display device, by absorbing the impact received from the HC layer side, the cushioning layer can prevent the damage of the image display device disposed on the side opposite to the HC layer side. For example, an aspect of the optical film having the cushioning layer includes the optical film according to the embodiment of the present invention that is constituted with the HC layer, the resin film, and the cushioning layer that are laminated in this order.

(Material of Cushioning Layer)

In a case where the optical film according to the embodiment of the present invention is used as a front panel of an image display device, as long as the cushioning layer has transparency which can secure the visibility of what is displayed and can prevent the damage of the image display device resulting from pressing of the front panel, collision, and the like, the cushioning layer may be constituted with a resin or an elastomer (including oil extended rubber).

Examples of the resin include a 1,2-polybutadiene resin, an ethylene-vinyl acetate copolymer (abbreviated to “EVA”, generally containing a vinyl acetate constitutional unit in an amount equal to or greater than 3% by mass), a polyolefin resin such as polyethylene, a polyvinyl chloride resin, a polystyrene resin, a vinyl ester resin (excluding EVA), a saturated polyester resin, a polyamide resin, a fluororesin (polyvinylidene fluoride or the like), a polycarbonate resin, a polyacetal resin, a urethane resin, an epoxy resin, a (meth)acrylate resin (referred to as (meth)acrylic resin as well, meaning a (meth)acrylic acid ester resin or the like), an unsaturated polyester resin, a silicon resin, resins obtained by modifying the above resins, and the like. Examples of the urethane resin include a urethane-modified polyester resin and a urethane resin.

Examples of the elastomer include a block (co)polymer of a conjugated diene, an acrylic block (co)polymer, a styrene-based block (co)polymer, a block copolymer of an aromatic vinyl compound and a conjugated diene, a hydrogenated substance of a block (co)polymer of a conjugated diene, a hydrogenated substance of a block copolymer of an aromatic vinyl compound and a conjugated diene, an ethylene-α-olefin-based copolymer, a polar group-modified olefin-based copolymer, an elastomer formed of a polar group-modified olefin-based copolymer and a metal ion and/or a metal compound, nitrile-based rubber such as acrylonitrile-butadiene-based rubber, butyl rubber, acrylic rubber, a thermoplastic elastomer such as a thermoplastic polyolefin elastomer (TPO), a thermoplastic polyurethane elastomer (TPU), a thermoplastic polyester elastomer (TPEE), a thermoplastic polyamide elastomer (TPAE), or a diene-based elastomer (1,2-polybutadiene or the like), a silicone-based elastomer, a fluorine-based elastomer, and the like.

At 25° C., the cushioning layer has a peak of tan δ preferably within a frequency range of 10 to 10¹⁵ Hz, more preferably within a frequency range of 10³ to 10¹⁵ Hz, even more preferably within a frequency range of 10⁵ to 10¹⁵ Hz, and particularly preferably within a frequency range of 10⁵ to 10¹⁰ Hz. In this case, at 25° C., the cushioning layer may have at least one peak of tan δ within a frequency range of 10 to 10¹⁵ Hz or have two or more peaks of tan δ within a frequency range of 10 to 10¹⁵ Hz. Furthermore, the cushioning layer has a peak of tan δ within a frequency range other than the frequency range of 10 to 10¹⁵ Hz, and the peak may be a maximum value.

From the viewpoint of impact absorption, the peak of tan δ of the cushioning layer at 25° C. is preferably equal to or greater than 0.1, and more preferably equal to or greater than 0.2. Furthermore, from the viewpoint of hardness, the peak of tan δ of the cushioning layer at 25° C. is preferably equal to or smaller than 3.0.

In the present invention, regarding the frequency-tan δ relationship of the cushioning layer at 25° C., a graph of frequency-tan δ is created by the following method, and the peak of tan δ and the frequency at which the peak is found are determined.

<Method for Preparing Sample>

A cushioning material is dissolved or melted in a solvent, thereby obtaining a coating solution. A release-treated surface of a release PET sheet having undergone a release treatment is coated with the coating solution such that the thickness becomes 40 μm after drying, the solution is dried, and then a cushioning layer is peeled from the release PET sheet, thereby preparing a test piece of a cushioning layer.

<Measurement Method>

The test piece humidified in advance for 2 hours or longer in an atmosphere with a temperature of 25° C. and a relative humidity of 60% is measured using a viscoelasticity measurement apparatus (DVA-225 manufactured by ITS JAPAN) in a “Stepwise heating.Frequency dispersion” mode under the following conditions. Then, by “Master curve” edition, a master curve of tan δ with respect to a frequency at 25° C., a storage modulus, and a loss modulus is obtained. From the obtained master curve, a peak of tan δ and a frequency at which the peak is found are determined.

Sample: 5 mm×20 mm

Distance between grippers: 20 mm

Set stress: 0.10%

Measurement temperature: −40° C. to 40° C.

Heating condition: 2° C./min

It is preferable that the cushioning layer has a storage modulus (E′) of equal to or higher than 30 MPa at the frequency showing the peak of tan δ. In a case where E′ of the cushioning layer at the frequency showing the peak of tan δ is equal to or higher than 30 MPa, the deterioration of pencil hardness can be inhibited. E′ of the cushioning layer at the frequency showing the peak of tan δ is more preferably equal to or higher than 50 MPa. Although the upper limit of E′ of the cushioning layer at the frequency showing the peak of tan δ is not particularly limited, from the viewpoint of impact absorption, the upper limit is practically equal to or lower than 10⁵ MPa.

Examples of cushioning layer forming materials constituting the cushioning layer having a peak of tan δ within a frequency range of 10 to 10¹⁵ Hz at 25° C. include a (meth)acrylate resin and an elastomer. As the elastomer, an acrylic block (co)polymer and a styrene-based block (co)polymer are preferable. Examples of the acrylic block copolymer include a block copolymer of methyl methacrylate and n-butyl acrylate (referred to as “PMMA-PnBA copolymer” as well) and the like. Examples of the styrene-based block (co)polymer include a block copolymer of isoprene and/or butene and styrene, and the like. The resin or the elastomer that the cushioning layer can contain may be synthesized by known methods, or commercial products may be used as the resin or the elastomer. Examples of the commercial products include KURARITY LA1114, KURARITY LA2140, KURARITY LA2250, KURARITY LA2330, KURARITY LA4285, HYBRAR 5127, and HYBRAR 7311F (manufactured by KURARAY CO., LTD., trade names), and the like.

The cushioning layer may be constituted with a resin containing at least one kind of resin selected from a urethane-modified polyester resin and a urethane resin. Furthermore, the cushioning layer may have a peak of tan δ within a frequency range of 10 to 10¹⁵ Hz at 25° C. It is preferable that the cushioning layer having a predetermined peak described above is constituted with at least one kind of material selected from a (meth)acrylate resin and an elastomer.

From the viewpoint of balance between solubility in a solvent and hardness, the weight-average molecular weight of the resin or the elastomer is preferably 10,000 to 1,000,000, and more preferably 50,000 to 500,000.

In a case where the cushioning layer is constituted with the resin or the elastomer described above, only a polymer may be adopted as a constituent material. However, as the constituent material, a composition can also be adopted which contains additives such as a softener, a plasticizer, a lubricant, a crosslinking agent, a crosslinking aid, a photosensitizer, an antioxidant, an antistaling agent, a heat stabilizer, a flame retardant, an antibacterial agent, a fungicide, a weathering agent, an ultraviolet absorber, a viscosity imparting agent, a nucleating agent, a pigment, a dye, an organic filler, an inorganic filler, a silane coupling agent, and a titanium coupling agent, a polymerizable group-containing compound, or other polymers. That is, the cushioning layer may be constituted with a resin composition or an elastomer composition.

The inorganic filler to be added to the cushioning layer is not particularly limited. For example, it is possible to use silica particles, zirconia particles, alumina particles, mica, talc, and the like. One kind of inorganic filler can be used, or two or more kinds of inorganic fillers can be used in combination. In view of dispersion in the cushioning layer, silica particles are preferable.

The surface of the inorganic filler may be treated with a surface modifier, which has a functional group capable of being bonded to or adsorbed onto the inorganic filler, so as to improve the affinity of the inorganic filler with the resin constituting the cushioning layer. Examples of the surface modifier include a metal alkoxide surface modifier such as silane, aluminum, titanium, or zirconium, and a surface modifier having an anionic group such as a phosphoric acid group, a sulfuric acid group, a sulfonic acid group, or a carboxylic acid group.

Considering the balance between the modulus of elasticity and tan δ of the cushioning layer, the content of the inorganic filler in the solid contents of the cushioning layer is preferably 1% to 40% by mass, more preferably 5% to 30% by mass, and even more preferably 5% to 15% by mass. The size (average primary particle diameter) of the inorganic filler is preferably 10 nm to 100 nm, and more preferably 15 to 60 nm. The average primary particle diameter of the inorganic filler can be determined from an electron micrograph. In a case where the particle diameter of the inorganic filler is too small, the effect of improving the modulus of elasticity is not obtained. In a case where the particle diameter of the inorganic filler is too large, sometimes haze increases. The inorganic filler may have any of a plate shape, a spherical shape, or a non-spherical shape.

Specific examples of the inorganic filler include ELECOM V-8802 (manufactured by JGC CORPORATION, spherical silica particles having an average particle diameter of 12 nm), ELECOM V-8803 (manufactured by JGC CORPORATION, silica particles of irregular shapes), MiBK-ST (manufactured by NISSAN CHEMICAL INDUSTRIES, LTD., spherical silica particles having an average particle diameter of 10 to 20 nm), MEK-AC-2140Z (manufactured by NISSAN CHEMICAL INDUSTRIES, LTD., spherical silica particles having an average particle diameter of 10 to 20 nm). MEK-AC-4130 (manufactured by NISSAN CHEMICAL INDUSTRIES, LTD., spherical silica particles having an average particle diameter of 40 to 50 nm). MIBK-SD-L (manufactured by NISSAN CHEMICAL INDUSTRIES, LTD., spherical silica particles having an average particle diameter of 40 to 50 nm), MEK-AC-5140Z (manufactured by NISSAN CHEMICAL INDUSTRIES, LTD., spherical silica particles having an average particle diameter of 70 to 100 nm), and the like.

The additives to be added to the cushioning layer are not particularly limited. For example, it is possible to use a rosin ester resin, a hydrogenated rosin ester resin, a petrochemical resin, a hydrogenated petrochemical resin, a terpene resin, a terpene phenyl resin, an aromatic modified terpene resin, a hydrogenated terpene resin, an alkyl phenyl resin, and the like. One kind of each of these may be used singly, or two or more kinds of these may be used in combination.

Considering the balance between the storage modulus and tan δ of the cushioning layer, the content of the additives in the solid contents of the cushioning layer is preferably 1% to 40% by mass, more preferably 5% to 30% by mass, and even more preferably 5% to 15% by mass.

Specific examples of the additives include SUPER ESTER A75, SUPER ESTER A115, and SUPER ESTER A125 (manufactured by Arakawa Chemical Industries, Ltd., rosin ester resins), PETROTAC 60, PETROTAC 70, PETROTAC 90, PETROTAC 100, PETROTAC 100V, and PETROTAC 90HM (manufactured by Tosoh Corporation, petrochemical resins), YS POLYSTER T30, YS POLYSTER T80, YS POLYSTER T100, YS POLYSTER T115, YS POLYSTER T130, YS POLYSTER T145, and YS POLYSTER T160 (manufactured by YASUHARA CHEMICAL CO., LTD., terpene phenol resins), and the like.

Examples of the polymerizable group-containing compound which can be incorporated into the resin composition or the elastomer composition used for forming the cushioning layer include a polymerizable group-containing polymer, a polymerizable group-containing oligomer, and a polymerizable group-containing monomer. Specifically, examples thereof include ARTCURE RA331 MB and ARTCURE RA341 (manufactured by Negami Chemical Industrial Co., Ltd.), KURAPRENE UC-102M and KURAPRENE 203M (manufactured by KURARAY CO., LTD.). SERM ELASTOMER SH3400M (manufactured by ADVANCED SOFTMATERIALS Inc.), and the radically polymerizable compound and the cationically polymerizable compound described above.

In a case where the polymerizable group-containing compound is incorporated into the resin composition or the elastomer composition used for forming the cushioning layer, it is preferable that the composition further contains a polymerization initiator. Specific examples of the polymerization initiator include the polymerization initiators described above.

(Method for Forming Cushioning Layer)

The method for forming the cushioning layer is not particularly limited, and examples thereof include a coating method, a casting method (a solventless casting method or a solvent casting method), a press method, an extrusion method, an injection molding method, a cast molding method, an inflation method, and the like. Specifically, by steps of preparing a liquid substance, in which the aforementioned cushioning material is dissolved or dispersed, or a melt of components constituting the aforementioned cushioning material, then coating a resin film with the liquid substance or the melt, and then removing the solvent if necessary, and the like, a cushioning layer can be prepared on the resin film (or the resin film in the resin film with an HC layer).

Furthermore, by coating a release-treated surface of a release sheet having undergone a release treatment with the cushioning material as described above, drying the cushioning material so as to form a sheet having a cushioning layer, and bonding the cushioning layer of this sheet to a resin film, a cushioning layer can be prepared on the resin film (or the resin film in the resin film with an HC layer).

In a case where the cushioning layer is constituted with a resin, the cushioning layer may be constituted with a non-crosslinked resin, or at least a portion of the cushioning layer may be constituted with a crosslinked resin. The method for crosslinking the resin is not particularly limited, and examples thereof include means selected from methods using electron beam irradiation, ultraviolet irradiation, and a crosslinking agent (for example, an organic peroxide or the like). In a case where the resin is crosslinked by electron beam irradiation, by irradiating the obtained cushioning layer, which has not yet been crosslinked, with electron beams from an electron beam irradiation apparatus, crosslinks can be formed. In the case of ultraviolet irradiation, by irradiating the obtained cushioning layer, which has not yet been crosslinked, with ultraviolet rays from an ultraviolet irradiation apparatus, crosslinks can be formed by the effect of a photosensitizer which is optionally mixed in. Furthermore, in a case where a crosslinking agent is used, generally, by heating the obtained cushioning layer, which has not yet been crosslinked, in an anaerobic atmosphere such as a nitrogen atmosphere, crosslinks can be formed by the crosslinking agent such as an organic peroxide optionally mixed and a crosslinking aid.

In view of cushioning properties, the film thickness of the cushioning layer is preferably equal to or greater than 5 μm, more preferably equal to or greater than 10 μm, and even more preferably equal to or greater than 20 μm. The upper limit thereof is substantially equal to or smaller than 100 μm.

(Protective Film Layer of Cushioning Layer)

In a case where the optical film according to the embodiment of the present invention has the cushioning layer, it is preferable to provide a peelable protective film layer on a surface of the cushioning layer that is opposite to the resin film. In a case where the optical film has the protective film layer, it is possible to prevent the damage of the cushioning layer included in the optical film before use and prevent dirt, contaminants, and the like from adhering the cushioning layer. At the time of use, the protective film layer can be peeled off.

In order to make it easy to peel the protective film layer, a release layer can be provided between the protective film layer and the cushioning layer. The method for providing the release layer is not particularly limited. For example, the release layer can be provided by coating the surface of at least any of the protective film layer or the cushioning layer with a release coating agent. The type of the release coating agent is not particularly limited, and examples thereof include a silicone-based coating agent, an inorganic coating agent, a fluorine coating agent, an organic-inorganic hybrid coating agent, and the like.

Generally, the optical film comprising the protective film layer and the release layer can be obtained by providing the release layer on the surface of the protective film layer and then laminating the resulting film on the surface of the cushioning layer. In this case, the release layer may be provided not on the surface of the protective film layer but on the surface of the cushioning layer.

(4) Articles Having Optical Film

Examples of articles including the optical film according to the embodiment of the present invention include various articles required to have improved keystroke durability and manufacturing suitability in various industrial fields such as the field of home appliances, the field of electricity and electronics, the field of automobiles, and the field of housing. Specifically, examples of such articles include a touch sensor, a touch panel, an image display apparatus such as a liquid crystal display, window glass of automobiles, window glass for home, and the like. By providing the optical film according to the embodiment of the present invention preferably as a surface protect film in these articles, it is possible to provide articles excellent in keystroke durability, post-keystroke adhesion resistance, and rub resistance. The optical film according to the embodiment of the present invention is an optical film used in a front panel of an image display apparatus, and more preferably an optical film used in a front panel of an image display device of a touch panel.

The touch panel in which the optical film according to the embodiment of the present invention can be used is not particularly limited, and can be appropriately selected according to the purpose. Examples of the touch panel include a surface capacitance-type touch panel, a projected capacitance-type touch panel, a resistive film-type touch panel, and the like. The details of the touch panel will be specifically described later.

The touch panel includes a so-called touch sensor. In the touch panel, the layer constitution of a touch panel sensor-electrode portion may be established by any of a bonding method in which two sheets of transparent electrodes are bonded to each other, a method of providing a transparent electrode on both surfaces of one sheet of substrate, a method using a single-face jumper or a through hole, or a single-face lamination method.

<<Image Display Apparatus>>

The image display apparatus having the optical film according to the embodiment of the present invention is an image display apparatus including a front panel having the optical film according to the embodiment of the present invention and an image display device.

As the image display apparatus, it is possible to use image display apparatuses such as a Liquid Crystal Display (LCD), a plasma display panel, an electroluminescence display, a cathode tube display, and a touch panel.

Examples of the liquid crystal display include a Twisted Nematic (TN) type, a Super-Twisted Nematic (STN) type, a Triple Super Twisted Nematic (TSTN) type, a multi domain type, a Vertical Alignment (VA) type, an In Plane Switching (IPS) type, an Optically Compensated Bend (OCB) type, and the like.

It is preferable that the image display apparatus has ameliorated brittleness and excellent handleability, does not impair display quality by surface smoothness or wrinkles, and can suppress the leakage of light at the time of a moisture-heat test.

That is, the image display apparatus having the optical film according to the embodiment of the present invention preferably includes a liquid crystal display as an image display device. Examples of the image display apparatus having a liquid crystal display include Xperia P manufactured by Sony Ericsson Mobile, and the like.

It is also preferable that the image display apparatus having the optical film according to the embodiment of the present invention has an organic Electroluminescence (EL) display device as an image display device.

For the organic electroluminescence display device, known techniques can be adopted without any limitation. Examples of the image display apparatus having an organic electroluminescence display device include GALAXY SII manufactured by SAMSUNG ELECTRONICS CO., LTD., and the like.

It is also preferable that the image display apparatus having the optical film according to the embodiment of the present invention has an In-Cell touch panel display device as an image display device. The in-cell touch panel display device is a device in which the touch panel function is built in the cell of the image display device.

For the in-cell touch panel display device, for example, known techniques described in JP2011-076602A. JP2011-222009A, and the like can be adopted without any limitation. Examples of the image display apparatus having the in-cell touch panel display device include Xperia P manufactured by Sony Ericsson Mobile, and the like.

It is also preferable that the image display apparatus having the optical film according to the embodiment of the present invention has an On-Cell touch panel display device as an image display device. The on-cell touch panel display device is a device in which the touch panel function is built on the outside of the cell of the image display device.

For the on-cell touch panel display device, for example, known techniques described in JP2012-088683A and the like can be adopted without any limitation. Examples of the image display apparatus having the on-cell touch panel display device include GALAXY SII manufactured by SAMSUNG ELECTRONICS CO., LTD., and the like.

<<Touch Panel>>

The touch panel having the optical film according to the embodiment of the present invention is a touch panel including a touch sensor obtained by bonding a touch sensor film to the optical film according to the embodiment of the present invention. Because the optical film according to the embodiment of the present invention has the HC layer, it is preferable that the touch sensor film is bonded to the resin film surface opposite to the surface on which the HC layer is disposed.

The touch sensor film is not particularly limited, but is preferably a conductive film in which a conductive layer is formed.

The conductive film is preferably a conductive film obtained by forming a conductive layer on any support.

The material of the conductive layer is not particularly limited, and examples thereof include indium-tin composite oxide (Indium Tin Oxide; ITO), tin oxide, antimony tin composite oxide (Antimony Tin Oxide; ATO), copper, silver, aluminum, nickel, chromium, an alloy of these, and the like.

It is preferable that the conductive layer is an electrode pattern. Furthermore, it is preferable that the conductive layer is a transparent electrode pattern. The electrode pattern may be obtained by patterning a transparent conductive material layer or obtained by forming a layer of non-transparent conductive material by patterning.

As the transparent conductive material, it is possible to use an oxide such as ITO or ATO, silver nanowires, carbon nanotubes, a conductive polymer, and the like.

Examples of the layer of a non-transparent conductive material include a metal layer. As the metal layer, any metal having conductivity can be used, and silver, copper, gold, aluminum, and the like are suitably used. The metal layer may be a simple metal or an alloy, or may be a layer in which metal particles are bonded to each other through a binder. If necessary, the surface of the metal may be subjected to a blackening treatment, a rust-proofing treatment, and the like. In a case where a metal is used, a substantially transparent sensor portion and a peripheral wiring portion can be collectively formed.

It is preferable that the conductive layer contains a plurality of metal thin wires. The metal thin wires are preferably formed of silver or an alloy containing silver. The conductive layer containing metal thin wires formed of silver or an alloy containing silver is not particularly limited, and known conductive layers can be used. For example, it is preferable to use the conductive layer described in paragraphs “0040” and “0041” in JP2014-168886A, and the content of the publication is incorporated into the present specification.

It is also preferable that the metal thin wires are formed of copper or an alloy containing copper. The alloy is not particularly limited, and known conductive layers can be used. For example, it is preferable to use the conductive layer described in paragraphs “0038” to “0059” in JP2015-049852A, and the content of the publication is incorporated into the present specification.

It is also preferable that the conductive layer is formed of an oxide. In a case where the conductive layer is formed of an oxide, it is more preferable that the oxide is formed of indium oxide containing tin oxide or of tin oxide containing antimony. The conductive layer formed of an oxide is not particularly limited, and known conductive layers can be used. For example, it is preferable to use the conductive layer described in paragraphs “0017” to “0037” in JP2010-027293A, and the content of the publication is incorporated into the present specification.

Among these conductive layers constituted as above, a conductive layer is preferable which includes a plurality of metal thin wires that are disposed in a mesh shape or a random shape, and a conductive layer is more preferable in which the metal thin wires are disposed in a mesh shape. Particularly, a conductive layer is preferable in which the metal thin wires are disposed in a mesh shape and formed of a silver or an alloy containing silver. It is also preferable that the touch sensor film has a conductive layer on both surfaces thereof.

Paragraphs “0016” to “0042” in JP2012-206307A describe preferred aspects of the touch sensor film, and the content of the publication is incorporated into the present specification.

<<Resistive Film-Type Touch Panel>>

The resistive film-type touch panel having the optical film according to the embodiment of the present invention is a resistive film-type touch panel which has the front panel having the optical film according to the embodiment of the present invention.

Basically, the resistive film-type touch panel has a constitution in which conductive films including a pair of upper and lower substrates each having a conductive film are disposed with a spacer therebetween such that the conductive films face each other. The constitution of the resistive film-type touch panel is known, and in the present invention, known techniques can be applied without any limitation.

<<Capacitance-Type Touch Panel>>

The capacitance-type touch panel having the optical film according to the embodiment of the present invention is a capacitance-type touch panel which has the front panel having the optical film according to the embodiment of the present invention.

Examples of the capacitance-type touch panel include a surface capacitance-type touch panel and a projected capacitance-type touch panel. The projected capacitance-type touch panel has a basic constitution in which an X electrode and a Y electrode orthogonal to the X-axis electrode are disposed having an insulator therebetween. Specific aspects thereof include an aspect in which the X electrode and the Y electrode are formed on each surface of one substrate, an aspect in which the X electrode, the insulating layer, and the Y electrode are formed in this order on one substrate, an aspect in which the X electrode is formed on one substrate and the Y electrode is formed on the other substrate (in this aspect, a constitution in which two substrates are bonded to each other is the aforementioned basic constitution), and the like. The constitution of the capacitance-type touch panel is known, and in the present invention, known techniques can be adopted without any limitation.

FIG. 3 shows an example of the constitution of an embodiment of a capacitance-type touch panel. A touch panel 2 is used in combination with a display apparatus. The display apparatus is used by being disposed on a protective layer 7B side in FIG. 3, that is, on a display apparatus side. In FIG. 3, the optical film 4C side of the present invention is a viewing side (that is, a side on which a person operating the touch panel visually recognizes an image displayed on the display apparatus). The optical film 4C according to the embodiment of the present invention is used by being bonded to a conductive film 1 for a touch panel. The conductive film 1 for a touch panel includes a conductive member 6A (first conductive layer 8) and a conductive member 6B (second conductive layer 9) on both surfaces of a flexible transparent insulating substrate 5. Each of the conductive member 6A and the conductive member 6B at least constitutes an electrode, peripheral wiring, an external connection terminal, and a connector portion as a touch panel which will be described later.

As shown in FIG. 3, for the purpose of flattening or protecting the conductive members 6A and 6B, transparent protective layers 7A and 7B may be disposed to cover the conductive member 6A and the conductive member 6B.

In the optical film 4C, a decorative layer for shielding a peripheral region S2, which will be described later, from light may be formed.

As the material of the transparent insulating substrate 5, glass, polyethylene terephthalate (PET), polyethylene naphthalate (PEN), a cycloolefin polymer (COP), a cycloolefin copolymer (COC), polycarbonate (PC), and the like can be used. The thickness of the transparent insulating substrate 5 is preferably 20 to 200 μm.

A pressure sensitive adhesive layer 3 may be disposed between the optical film 4C and the conductive film 1 for a touch panel. As the pressure sensitive adhesive layer 3, it is possible to use an Optical Clear Adhesive or an Optical Clear Resin. The thickness of the pressure sensitive adhesive layer 3 is preferably 10 to 100 μm. As the optical clear adhesive, for example, an 8146 series manufactured by 3M can be preferably used. The relative permittivity of the pressure sensitive adhesive layer 3 is preferably 4.0 to 6.0, and more preferably 5.0 to 6.0.

As the protective layer 7A and the protective layer 7B, for example, it is possible to use an organic film such as gelatin, an acrylic resin, or a urethane resin and an inorganic film such as silicon dioxide. The thickness thereof is preferably equal to or greater than 10 nm and equal to or smaller than 100 nm, and the relative permittivity thereof is preferably 2.5 to 4.5.

The concentration of halogen impurities in the protective layer 7A and the protective layer 7B is preferably equal to or lower than 50 ppm. It is more preferable that the protective layer 7A and the protective layer 7B do not contain halogen impurities. According to this aspect, it is possible to inhibit the corrosion of the conductive member 6A and the conductive member 6B.

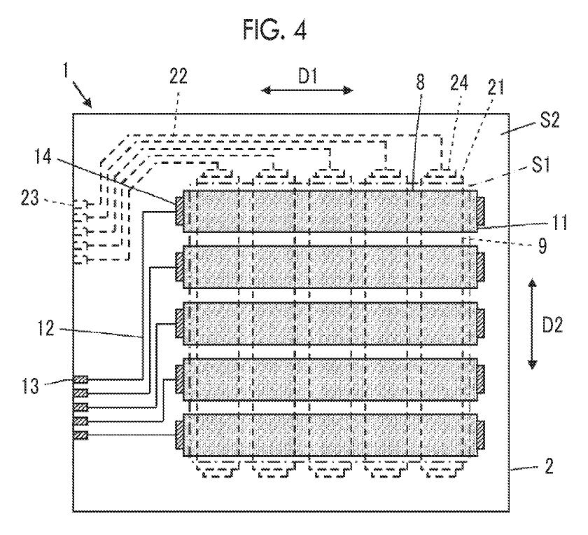

As shown in FIG. 4, the conductive film 1 for a touch panel is divided into a transparent active area S1 and a peripheral region S2 which is on the outside of the active area S1.

Within the active area S1, the first conductive layer 8 formed on the front surface (first surface) of the transparent insulating substrate 5 and the second conductive layer 9 formed on the rear surface (second surface) of the transparent insulating substrate 5 are disposed such that they overlap each other. The first conductive layer 8 and the second conductive layer 9 are disposed in a state where they are insulated from each other through the transparent insulating substrate 5.

The first conductive layer 8 on the front surface of the transparent insulating substrate 5 forms a plurality of first electrodes 11 which each extend along a first direction DI and are disposed in parallel to each other along a second direction D2 orthogonal to the first direction D1. The second conductive layer 9 on the rear surface of the transparent insulating substrate 5 forms a plurality of second electrodes 21 which each extend along the second direction D2 and are disposed in parallel to each other along the first direction DI.

The plurality of first electrodes 11 and the plurality of second electrodes 21 constitute detection electrodes of the touch panel 2. Each of the first electrode 11 and the second electrode 21 preferably has an electrode width of 1 to 5 mm, and an interelectrode pitch thereof is preferably 3 to 6 mm.

On the front surface of the transparent insulating substrate 5 in the peripheral region S2, a plurality of first peripheral wiring 12 connected to the plurality of first electrodes 11 are formed, and a plurality of first external connection terminals 13 are arrayed and formed in the border portion of the transparent insulating substrate 5. Furthermore, at both ends of each of the first electrodes 11, a first connector portion 14 is formed. The first connector portion 14 is connected to one end of the corresponding first peripheral wiring 12, and the other end of the first peripheral wiring 12 is connected to the corresponding first external connection terminal 13.

Likewise, on the rear surface of the transparent insulating substrate 5 in the peripheral region S2, a plurality of second peripheral wiring 22 connected to the plurality of second electrodes 21 are formed, and a plurality of second external connection terminals 23 are arrayed and formed in the border portion of the transparent insulating substrate 5. Furthermore, at both ends of each of the second electrodes 21, a second connector portion 24 is formed. The second connector portion 24 is connected to one end of the corresponding second peripheral wiring 22, and the other end of the second peripheral wiring 22 is connected to the corresponding second external connection terminal 23.

The conductive film 1 for a touch panel has a conductive member 6A which has the first electrode 11, the first peripheral wiring 12, the first external connection terminal 13, and the first connector portion 14 on the front surface of the transparent insulating substrate 5 and the conductive member 6B which has the second electrode 21, the second peripheral wiring 22, the second external connection terminal 23, and the second connector portion 24 on the rear surface of the transparent insulating substrate 5.

In FIG. 4, although the first electrode 11 and the first peripheral wiring 12 are connected to each other through the first connector portion 14, a constitution may also be adopted in which the first connector portion 14 is not provided such that the first electrode 11 and the first peripheral wiring 12 are directly connected to each other. Furthermore, a constitution may also be adopted in which the second connector portion 24 is not provided such that the second electrode 21 and the second peripheral wiring 22 are directly connected to each other.

In a case where the first connector portion 14 and the second connector portion 24 are provided, electricity can be effectively excellently conducted at the site where the electrode and the peripheral wiring are connected to each other. Particularly, in a case where the electrode and the peripheral wiring are formed of different materials, it is preferable to provide the first connector portion 14 and the second connector portion 24. The width of each of the first connector portion 14 and the second connector portion 24 is preferably equal to or greater than 1/3 of the width of the electrode connected to each of the connector portions and equal to or smaller than the width of the electrode. The first connector portion 14 and the second connector portion 24 may have the shape of a solid film, the frame shape shown in WO2013/089085A, or a mesh shape.

The wiring width of the first peripheral wiring 12 and the second peripheral wiring 22 is equal to or greater than 10 μm and equal to or smaller than 200 μm, and the minimum wiring interval (minimum interwiring distance) is preferably equal to or greater than 20 μm and equal to or smaller than 100 μm.

Each of the peripheral wiring may be covered with a protective insulating film formed of a urethane resin, an acrylic resin, an epoxy resin, or the like. In a case where the protective insulating film is provided, it is possible to prevent the migration, rusting, and the like of the peripheral wiring. It is preferable that the insulating film does not contain halogen impurities because the impurities are likely to cause the corrosion of the peripheral wiring. The thickness of the protective insulating film is preferably 1 to 20 μm.

In a case where the conductive film 1 for a touch panel is used as a touch panel, the first external connection terminal 13 and the second external connection terminal 23 are electrically connected to Flexible Printed Circuits through an Anisotropic Conductive Film. The flexible printed circuits are connected to a touch panel control board having a driving function and a position detection function.

For the purpose of improving the electric connectivity with respect to the flexible printed circuits, the first external connection terminal 13 and the second external connection terminal 23 are formed to have a terminal width larger than the wiring width of the first peripheral wiring 12 and the second peripheral wiring 22. Specifically, each of the first external connection terminal 13 and the second external connection terminal 23 preferably has a terminal width equal to or greater than 0.1 mm and equal to or smaller than 0.6 mm and a terminal length equal to or greater than 0.5 mm and equal to or smaller than 2.0 mm.

The transparent insulating substrate 5 corresponds to a substrate having a first surface and a second surface facing the first surface. The first conductive layer 8 is disposed on the first surface (front surface), and the second conductive layer 9 is disposed on the second surface (rear surface). Although FIG. 3 shows a state where the transparent insulating substrate 5 directly contact the first conductive layer 8 and the second conductive layer 9, one or more functional layers such as an adhesion enhancing layer, an undercoat layer, a hardcoat layer, and an optical adjustment layer can be formed between the transparent insulating substrate 5 and the first conductive layer 8 as well as the second conductive layer 9.

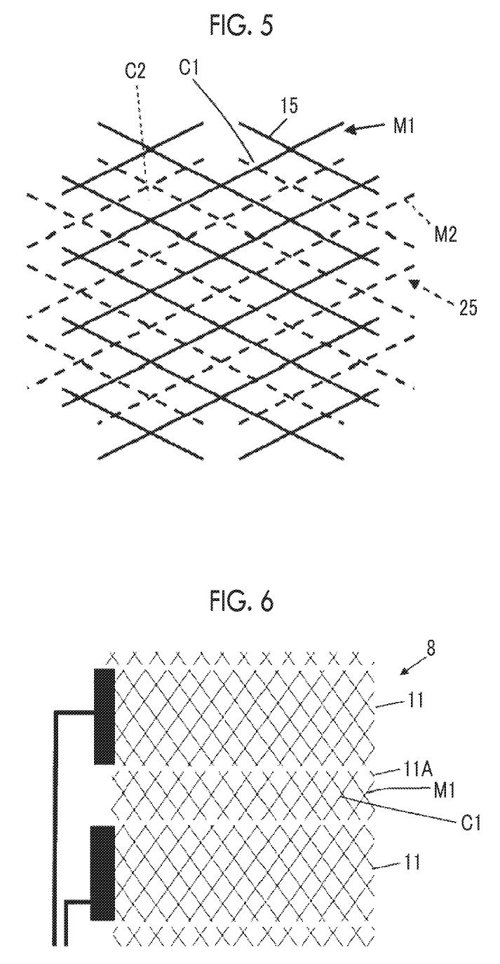

FIG. 5 shows portions in which the first electrode 11 and the second electrode 21 cross each other. The first electrode 11 disposed on the front surface of the transparent insulating substrate 5 is formed of a mesh pattern M1 formed of a first metal thin wire 15, and the second electrode 21 disposed on the rear surface of the transparent insulating substrate 5 is formed of a mesh pattern M2 formed of a second metal thin wire 25. In a case where the touch panel is viewed from the viewing side, the first metal thin wire 15 and the second metal thin wire 25 are found to be disposed such that they cross each other in the portions in which the first electrode 11 and the second electrode 21 cross each other. In FIG. 5, in order to make it easy for the first metal thin wire 15 and the second metal thin wire 25 to be differentiated from each other, the second metal thin wire 25 is indicated by a dotted line, but in reality, the second metal thin wire 25 is formed of a connected wire just like the first metal thin wire 15.

It is preferable that the mesh pattern has a pattern shape in which the same mesh (regular cell) as shown in FIG. 5 is repeatedly disposed, and the mesh shape is particularly preferably a diamond shape. The pattern shape may be a quadrangular shape such as a parallelogram, a square, or a rectangle, a regular hexagon shape, or other polygon shapes. In a case where the mesh shape is a diamond shape, from the viewpoint of reducing moire formed between the pattern and the pixels of the display apparatus, an acute angle of the diamond is preferably equal to or greater than 20° and equal to or smaller than 70°. From the viewpoint of visibility, the center-to-center distance between meshes (mesh pitch) is preferably 100 to 600 μm. It is preferable that the mesh pattern M1 formed of the first metal thin wire 15 and the mesh pattern M2 formed of the second metal thin wire 25 have the same shape. Furthermore, from the viewpoint of visibility, it is preferable that the mesh pattern M1 formed of the first metal thin wire 15 and the mesh pattern M2 formed of the second metal thin wire 25 are disposed by being caused to deviate from each other by a distance corresponding to 1/2 of the mesh pitch as shown in FIG. 5 such that a mesh pattern having a mesh pitch that is 1/2 of the aforementioned mesh pitch is formed from the viewing side. In another aspect, the mesh shape may be a random pattern or a semi-random shape obtained by imparting a certain degree of randomicity to a regular cell shape as described in JP2013-214545A in which about 10% of randomicity is imparted to the pitch of regular diamond cells.

Furthermore, a dummy mesh pattern, which is insulated from the electrodes formed of the first metal thin wire 15 and the second metal thin wire 25 respectively, may be provided between the first electrodes 11 adjacent to each other and between the second electrodes 21 adjacent to each other. It is preferable that the dummy mesh pattern is formed to have the same mesh shape as that of the mesh pattern forming the electrodes.

The touch panel 2 and the display apparatus may be bonded to each other by a method of directly bonding them to each other by using a transparent pressure sensitive adhesive (direct bonding method) or a method of bonding only the peripheries of the touch panel 2 and the display apparatus to each other by using a double-sided tape (air gap method), and any of these may be used. At the time of bonding the touch panel 2 and the display apparatus to each other, a protective film may be additionally provided on the conductive member 6B or the protective layer 7B. As the protective film, for example, a PET film (thickness: 20 to 150 μm) with a hardcoat is used. It is possible to adopt a constitution in which the protective film is bonded to the surface of the conductive member 6B or the protective layer 7B by using an Optical Clear Adhesive.

As the transparent pressure sensitive adhesive used in the direct bonding method, it is possible to use an Optical Clear Adhesive or an Optical Clear Resin used as the transparent pressure sensitive adhesive layer described above, and the thickness thereof is preferably equal to or greater than 10 μm and equal to or smaller than 100 μm. As the optical clear adhesive, for example, an 8146 series manufactured by 3M can be preferably used as described above. It is preferable that the relative permittivity of the transparent pressure sensitive adhesive used in the direct bonding method is lower than the relative permittivity of the aforementioned transparent pressure sensitive adhesive layer, because then the detection sensitivity of the touch panel 2 is improved. The relative permittivity of the transparent pressure sensitive adhesive used in the direct bonding method is preferably 2.0 to 3.0.

In view of further improving the effects of the present invention, the visible light reflectance of each of the viewing side surface of the first metal thin wire 15 and the viewing side surface of the second metal thin wire 25 is preferably equal to or lower than 5%, and more preferably less than 1%. In a case where the visible light reflectance is within this range, the mesh can be effectively inhibited from being noticed, or haze can be effectively reduced.

The visible light reflectance is measured as below, for example. First, by using an ultraviolet-visible spectrophotometer V660 (single reflection measurement unit SLM-721) manufactured by JASCO Corporation, a reflectance spectrum is measured at a measurement wavelength of 350 nm to 800 nm and an incidence angle of 5°. At this time, the regular reflection light from a vapor-deposited aluminum flat mirror is used as a base line. From the obtained reflectance spectrum, the Y value in the XYZ color space (color-matching function JIS Z9701-1999) with a light source of D65 at a 2 degree field of view is calculated using a color computation program manufactured by JASCO Corporation, and the calculated value is taken as the visible light reflectance.

As the materials constituting the first metal thin wire 15 and the second metal thin wire 25, it is possible to use metals such as silver, aluminum, copper, gold, molybdenum, and chromium, and an alloy of these. These materials can be used as a single layer or a laminate. From the viewpoint of inhibiting the mesh of the metal thin wire from being noticed and reducing moire, the line width of each of the first metal thin wire 15 and the second metal thin wire 25 is preferably equal to or greater than 0.5 μm and equal to or smaller than 5 μm. The first metal thin wire 15 and the second metal thin wire 25 may be in the form of a straight line, a folded line, a curved line, or a wavy line. The thickness of each of the first metal thin wire 15 and the second metal thin wire 25 is preferably equal to or greater than 0.1 μm from the viewpoint of the value of resistance, and preferably equal to or smaller than 3 μm from the viewpoint of the visibility in an oblique direction. From the viewpoint of the visibility in an oblique direction and from the viewpoint of the workability of patterning, the thickness is more preferably equal to or smaller than 1/2 of the line width of the metal thin wire. In addition, in order to reduce the visible light reflectance of the first metal thin wire 15 and the second metal thin wire 25, a blackened layer may be provided on the viewing side of the first metal thin wire 15 and the second metal thin wire 25.

The conductive member 6A including the first electrode 11, the first peripheral wiring 12, the first external connection terminal 13, and the first connector portion 14 can be formed of the material constituting the first metal thin wire 15. Accordingly, all the conductive members 6A each including the first electrode 11, the first peripheral wiring 12, the first external connection terminal 13, and the first connector portion 14 can be simultaneously formed of the same metal at the same thickness.

The same is true for the conductive member 6B including the second electrode 21, the second peripheral wiring 22, the second external connection terminal 23, and the second connector portion 24.

The sheet resistance of the first electrode 11 and the second electrode 21 is preferably equal to or higher than 0.1 Ω/square and equal to or lower than 200 Ω/square. Particularly, in a case where the electrodes are used in a projected capacitance-type touch panel, the sheet resistance thereof is preferably equal to or higher than 10 Ω/square and equal to or lower than 100 Ω/square.

As shown in FIG. 6, the first conductive layer 8 disposed on the front surface of the transparent insulating substrate 5 in the active area S may have a plurality of first dummy electrodes 11A each of which is disposed between the plurality of first electrodes 11. These first dummy electrodes 11A are insulated from the plurality of first electrodes 11, and have the first mesh pattern M1 constituted with a number of first cells C1 just like the first electrodes 11.

A disconnection portion having a width equal to or greater than 5 μm and equal to or smaller than 30 μm is provided in the metal thin wire disposed along the continuous first mesh pattern M1, and in this way, the first electrode 11 and the adjacent first dummy electrode 11A are electrically insulated from each other. Although FIG. 6 shows a state where the disconnection portion is formed only in the border line between the first electrode 11 and the adjacent first dummy electrode 11A, the disconnected portion may be formed in all or some of the sides of the first cell C1 in the first dummy electrode 11A.

The second conductive layer 9 disposed on the rear surface of the transparent insulating substrate 5 in the active area S1 may have a plurality of second dummy electrodes each of which is disposed between the plurality of second electrodes 21, although second conductive layer 9 is not shown in the drawing. These second dummy electrodes are insulated from the plurality of second electrodes 21, and have the second mesh pattern M2 constituted with a number of second cells C2 just like the second electrodes 21.

A disconnection portion having a width equal to or greater than 5 μm and equal to or smaller than 30 μm is provided in the metal thin wire disposed along the continuous second mesh pattern M2, and in this way, the second electrode 21 and the adjacent second dummy electrode are electrically insulated from each other. The disconnection portion may be formed only in the border line between the second electrode 21 and the adjacent second dummy electrode, or may be formed in all or some of the sides of the second cell C2 in the second dummy electrode.

As described above, the conductive film 1 for a touch panel is manufactured by forming the conductive member 6A, which includes the first electrode 11, the first peripheral wiring 12, the first external connection terminal 13, and the first connector portion 14, on the front surface of the transparent insulating substrate 5 and forming the conductive member 6B, which includes the second electrode 21, the second peripheral wiring 22, the second external connection terminal 23, and the second connector portion 24, on the rear surface of the transparent insulating substrate 5.

At this time, the first electrode 11 is formed of the first conductive layer 8 in which the first metal thin wire 15 is disposed along the first mesh pattern M1, the second electrode 21 is formed of the second conductive layer 9 in which the second metal thin wire 25 is disposed along the second mesh pattern M2, and the first conductive layer 8 and the second conductive layer 9 are disposed such that the conductive layers overlap each other in the active area S1 as shown in FIG. 4 in a state of interposing the transparent insulating substrate 5 therebetween.

The method for forming the conductive member 6A and the conductive member 6B is not particularly limited. For example, as described in paragraphs “0067” to “0083” in JP2012-185813A, paragraphs <0115> to <0126> in JP2014-209332A, or paragraphs “0216” and “0238” in JP2015-005495A, by exposing a photosensitive material, which has an emulsion layer containing a photosensitive silver halide salt, to light and performing a development treatment, the conductive members 6A and 6B can be formed.

The conductive members can also be formed by forming a metal thin film on each of the front surface and the rear surface of the transparent insulating substrate 5 and pattern-wise printing a resist on each of the metal thin film or by performing exposure and development on a resist, with which the entire surface of the substrate is coated, such that a pattern is formed and etching the metal in the opening portion. In addition, it is possible to use a method in which a paste containing the fine particles of a material constituting the conductive member is printed on the front surface and the rear surface of the transparent insulating substrate 5 and plated with a metal, a method of using an ink jet method in which an ink containing the fine particles of a material constituting the conductive member is used, a method of forming the conductive member through screen printing by using an ink containing the fine particles of a material constituting the conductive member, a method of forming grooves in the transparent insulating substrate 5 and coating the grooves with a conductive ink, a patterning method exploiting a microcontact printing, and the like.

In the aspect described above, the conductive member 6A including the first electrode 11, the first peripheral wiring 12, the first external connection terminal 13, and the first connector portion 14 is disposed on the front surface of the transparent insulating substrate 5, and the conductive member 6B including the second electrode 21, the second peripheral wiring 22, the second external connection terminal 23, and the second connector portion 24 is disposed on the rear surface of the transparent insulating substrate 5. However, the present invention is not limited to this aspect.

For example, a constitution may be adopted in which the conductive member 6A and the conductive member 6B are disposed on one surface of the transparent insulating substrate 5 through an interlayer insulating film.

Furthermore, a constitution can be adopted in which two sheets of substrates are used. That is, the conductive member 6A can be disposed on the front surface of a first transparent insulating substrate, the conductive member 6B can be disposed on the front surface of a second transparent insulating substrate, and the first transparent insulating substrate and the second transparent insulating substrate can be used by being bonded to each other by using an Optical Clear Adhesive.

Moreover, a constitution may be adopted in which the conductive member 6A and the conductive member 6B are disposed on a surface of the optical film 4C shown in FIG. 3 through an interlayer insulating film without using the transparent insulating substrate 5.

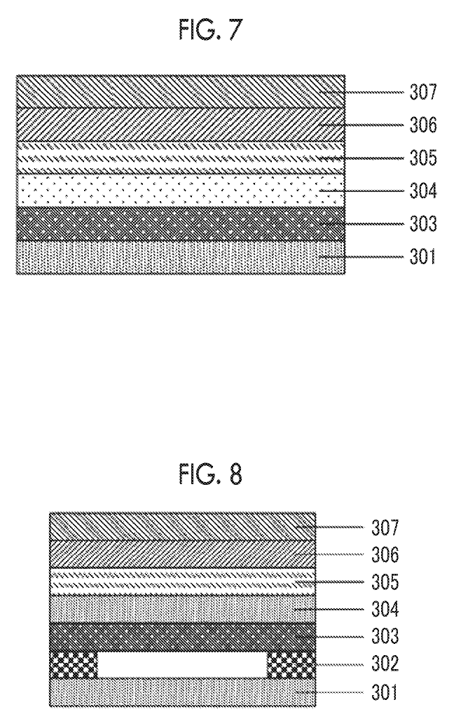

It goes without saying that the electrode pattern shape of the capacitance-type touch panel can be applied to, in addition to a so-called bar-and-stripe electrode pattern shape shown in FIG. 4, for example, the diamond pattern disclosed in FIG. 16 in WO2010/012179A and the electrode pattern shape disclosed in FIG. 7 or 20 in WO2013/094728A. Furthermore, the electrode pattern shape can be applied to electrode pattern shapes of other capacitance-type touch panels.

In addition, the electrode pattern shape can be applied to a touch panel disclosed in US2012/0262414 that has a constitution in which a detection electrode is provided only on one side of a substrate as in an electrode constitution without a crossing portion. The touch panel can be used in combination with other functional films such as the functional film for improving image quality disclosed in JP2014-013264A that prevents the occurrence of rainbow-like irregularities by using a substrate having a high retardation value, the circular polarization plate disclosed in JP2014-142462A that is for improving the visibility of a touch panel electrode, and the like.

<<Mirror with Image Display Function>>

The optical film according to the embodiment of the present invention may have a reflection layer (linear polarization reflection layer or a circular polarization reflection layer) on a surface, which is opposite to a surface having the HC layer, of the resin film. By being combined with an image display device, the optical film is preferably used as an optical film used in a front panel of a mirror with an image display function. A pressure sensitive adhesive layer may be disposed between the optical film according to the embodiment of the present invention and the reflection layer. As the pressure sensitive adhesive layer, an Optical Clear Adhesive or an Optical Clear Resin can be used.

In the present specification, the optical film having a linear polarization reflection layer or a circular polarization reflection layer that is used in a front panel of a mirror with an image display function is referred to as “half mirror” in some cases.

The image display device used in the mirror with an image display function is not particularly limited, and examples thereof include an image display device suitably used in the aforementioned image display apparatus.

The mirror with an image display function has a constitution in which an image display device is disposed on a side, which is provided with a linear polarization reflection layer or a circular polarization reflection layer, of the half mirror. In the mirror with an image display function, the half mirror and the image display device may directly contact each other, or another layer may be interposed between the half mirror and the image display device. For example, an air layer or an adhesive layer may be present between the image display device and the half mirror.

In the present specification, a surface, which is on the half mirror side, of the image display device is referred to as a front surface.

The mirror with an image display function can be used as a rearview mirror (inner mirror), for example. In order to be used as a rearview mirror, the mirror with an image display function may have a frame, a housing, a support arm for mounting the mirror on the body of a vehicle, and the like. Alternatively, the mirror with an image display function may be formed to be incorporated into a rearview mirror. In the mirror with an image display function having the aforementioned shape, generally, the directions, right and left and top and bottom, at the time of use can be specified.

The mirror with an image display function may be in the form of a plate or film and may have a curved surface. The front surface of the mirror with an image display function may be flat or curved. In a case where the mirror is curved such that the convex surface becomes the front surface side, the mirror can be used as a wide mirror which makes it possible to secure rearward visibility at a wide angle. The curved front surface can be prepared using a curved half mirror.

The mirror may be curved in either or both of a vertical direction and the horizontal direction. Furthermore, the radius of curvature of the curve may be 500 to 3,000 mm, and is preferably 1,000 to 2,500 mm. The radius of curvature is the radius of a hypothetic circumscribed circle of the curved portion in a cross section.

<<Reflection Layer>>

As the reflection layer, a reflection layer which can function as a half-transmission half-reflection layer may be used. That is, at the time of performing image display, the reflection layer may function to transmit the light emitted from a light source included in the image display device such that an image is displayed on the front surface of the mirror with an image display function. While image display is not being performed, the reflection layer may function to reflect at least some of the incoming rays in the front surface direction and transmit the light reflected from the image display device such that the front surface of the mirror with an image display function becomes a mirror.

As the reflection layer, a polarization reflection layer is used. The polarization reflection layer may be a linear polarization reflection layer or a circular polarization reflection layer.

[Linear Polarization Reflection Layer]

Examples of the linear polarization reflection layer include (i) linear polarization reflection plate having a multilayer structure, (ii) polarizer obtained by laminating thin films of different birefringences, (iii) wire grid-type polarizer. (iv) polarizing prism, and (v) scattering anisotropy-type polarizing plate.

Examples of (i) linear polarization reflection plate having a multilayer structure include a multilayer laminated thin film obtained by laminating dielectric materials of different refractive indices on a support by a vacuum vapor deposition method or a sputtering method in an oblique direction. In order to obtain a wavelength selective reflection film, it is preferable to alternately laminate a plurality of dielectric thin films of high refractive index and a plurality of dielectric thin films of low refractive index. However, the number of kinds of the thin films laminated is not limited to 2, and more kinds of thin films may be laminated. The number of thin films laminated is preferably 2 to 20, more preferably 2 to 12, even more preferably 4 to 10, and particularly preferably 6 to 8. In a case where the number of thin films laminated is greater than 20, the production efficiency is reduced, and hence the objects and effects of the present invention cannot be achieved in some cases.

The method for forming the dielectric thin film is not particularly limited, and can be appropriately selected according to the purpose. Examples thereof include a vacuum vapor deposition method such as ion plating and ion beams, a physical vapor deposition method (PVD method) such as sputtering, and a chemical vapor deposition method (CVD method). Among these, a vacuum vapor deposition method or a sputtering method is preferable, and a sputtering method is particularly preferable.

As (ii) polarizer obtained by laminating thin films of different birefringences, for example, it is possible to use the polarizer described in JP1997-506837A (JP-H09-506837A) and the like. Furthermore, by performing processing under the condition selected to obtain a relationship of refractive index, the polarizer can be formed using a wide variety of materials. Generally, it is preferable that one first material has a refractive index different from that of a second material in a selected direction. The difference in a refractive index can be achieved by various methods including stretching performed while a film is being formed or after a film is formed, extrusion molding, or coating. In addition, it is preferable that the two materials have similar rheological characteristics (for example, melt viscosity) such that the materials can be simultaneously extruded.

As the polarizer obtained by laminating thin films of different birefringences, commercial products can be used. Examples of the commercial products include DBEF (registered trademark) (manufactured by 3M).

(iii) Wire Grid-Type Polarizer is a Polarizer which Transmits One Polarization while Reflects the Other Polarization by the Birefringence of Metal Thin Wires.

The wire grid polarizer is a periodic array of metal wires. Therefore, this polarizer is mainly used in a terahertz wave band. In order for the wire grid to function as a polarizer, it is preferable that the wire interval is much smaller than the wavelength of the incoming electromagnetic wave.

In the wire grid polarizer, metal wires are arrayed at equal intervals. A polarization component in a polarization direction parallel to the longitudinal direction of the metal wire is reflected from the wire grid polarizer, and a polarization component in a polarization direction perpendicular to the longitudinal direction of the metal wire is transmitted through the wire grid polarizer.

As the wire grid-type polarizer, commercial products can be used. Examples of the commercial products include a wire grid polarization filter 50×50, NT46-636 (trade name) manufactured by Edmund Optics.

[Circular Polarization Reflection Layer]

In a case where a circular polarization reflection layer is used in the half mirror, the incoming rays from the front surface side can be reflected as circular polarization, and the incoming rays from the image display device can be transmitted as circular polarization. Therefore, with the mirror with an image display function in which the circular polarization reflection layer is used, a display image and an image reflected from the mirror can be observed through polarized sunglasses without relying on the direction of the mirror with an image display function.

Examples of the circular polarization reflection layer include a circular polarization reflection layer including a linear polarization reflection plate and a ¼ wavelength plate and a circular polarization reflection layer including a cholesteric liquid crystal layer (hereinafter, to distinguish between the two circular polarization reflection layers, the former will be referred to as “Polλ/4 circular polarization reflection layer” in some cases, and the latter will be referred to as “cholesteric circular polarization reflection layer” in some cases).

[[Polλ/4 Circular Polarization Reflection Layer]]

In the Polλ/4 circular polarization reflection layer, the linear polarization reflection plate and the ¼ wavelength plate may be disposed such that the slow axis of the ¼ wavelength plate intersects with the polarization reflection axis of the linear polarization reflection plate at 45°. The ¼ wavelength plate and the linear polarization reflection plate may be bonded to each other through an adhesive layer, for example.

In a case where the Polλ/4 circular polarization reflection layer is used in which the linear polarization reflection plate is disposed to become a surface close to the image display device, that is, in a case where the Polλ/4 circular polarization reflection layer is used in which the ¼ wavelength plate and the linear polarization reflection plate are disposed in this order on the optical film, it is possible to efficiently convert the light for image display from the image display device into circular polarization and to cause the circular polarization to be emitted from the front surface of the mirror with an image display function. In a case where the light for image display from the image display device is linear polarization, the polarization reflection axis of the linear polarization reflection plate may be adjusted such that the linear polarization is transmitted.

The thickness of the Polλ/4 circular polarization reflection layer is preferably 2.0 μm to 300 μm, and more preferably 8.0 μm to 200 μm.

As the linear polarization reflection plate, those described above as the linear polarization reflection layer can be used.

As the ¼ wavelength plate, a ¼ wavelength plate which will be described later can be used.

[Cholesteric Circular Polarization Reflection Layer]

The cholesteric circular polarization reflection layer includes at least one cholesteric liquid crystal layer. The cholesteric liquid crystal layer included in the cholesteric circular polarization reflection layer may perform selective reflection in the visible region.

The circular polarization reflection layer may include two or more cholesteric liquid crystal layers, and may include another layer such as an alignment layer. It is preferable that the circular polarization reflection layer includes only a cholesteric liquid crystal layer. In a case where the circular polarization reflection layer includes a plurality of cholesteric liquid crystal layers, it is preferable that the cholesteric liquid crystal layers adjacent to each other directly contact each other. It is preferable that the number of cholesteric liquid crystal layers included in the circular polarization reflection layer is equal to or greater than 3, such as 3 or 4.

The thickness of the cholesteric circular polarization reflection layer is preferably 2.0 μm to 300 μm, and more preferably 8.0 to 200 μm

In the present specification, “cholesteric liquid crystal layer” means a layer obtained by fixing a cholesteric liquid crystalline phase. The cholesteric liquid crystal layer is simply referred to as liquid crystal layer in some cases.

The cholesteric liquid crystalline phase is known to perform selective reflection of circular polarization, in which the circular polarization of one rotational sense of right circular polarization or left circular polarization is selectively reflected in a specific wavelength range while circular polarization of the other rotational sense is selectively transmitted. In the present specification, the selective reflection of circular polarization is simply referred to as selective reflection in some cases.

As films including a layer obtained by fixing a cholesteric liquid crystalline phase performing selective reflection of circular polarization, a number of films formed of a composition containing a polymerizable liquid crystal compound have been known in the related art. Regarding the cholesteric liquid crystal layer, common methods thereof can be referred to.

The cholesteric liquid crystal layer may be a layer in which the alignment of a liquid crystal compound in a state of a cholesteric liquid crystalline phase is maintained. Typically, the cholesteric liquid crystal layer may be a layer obtained by a process in which a polymerizable liquid crystal compound is aligned to be in the state of a cholesteric liquid crystalline phase and then polymerized and cured by ultraviolet irradiation, heating, or the like so as to form a layer without fluidity, and then the state of the layer is changed such that the alignment form does not change by the external field or the external force. The liquid crystal compound in the cholesteric liquid crystal layer does not need to exhibit liquid crystallinity as long as the optical properties of the cholesteric liquid crystalline phase are maintained in the layer. For example, the polymerizable liquid crystal compound may lose the liquid crystallinity by becoming a high-molecular weight compound through a curing reaction.

A central wavelength λ of selective reflection of the cholesteric liquid crystal layer depends on a pitch P (=period of helix) of the helical structure in the cholesteric liquid crystalline phase and has a relationship of λ=n×P with an average refractive index n of the cholesteric liquid crystal layer. A half-width of the central wavelength of selective reflection of the cholesteric liquid crystal layer can be determined as below.

In a case where the transmission spectrum (measured in a normal direction of the cholesteric liquid crystal layer) of the reflection layer is measured using a spectrophotometer UV3150 (manufactured by Shimadzu Corporation, trade name), transmittance falling peaks are found in a selective reflection region. Provided that the value of wavelength of a short wavelength side is λ1 (nm) and the value of wavelength of a long wavelength side is λ2 (nm) between two wavelengths at which the transmittance becomes equal to a height which is 1/2 of the height of the highest peak, the central wavelength of selective reflection and the half-width can be represented by the following formulae.

Central wavelength of selective reflection=(λ1+λ2)/2

Half-width=(λ2−λ1)

Generally, the central wavelength λ of selective reflection performed by the cholesteric liquid crystal layer that is determined as above coincides with the wavelength at the central position of the reflection peak of the circular polarization reflection spectrum measured in the normal direction of the cholesteric liquid crystal layer. In the present specification, “central wavelength of selective reflection” means the central wavelength at the time of measuring the transmission spectrum in the normal direction of the cholesteric liquid crystal layer.

As is evident from the above formulae, the central wavelength of selective reflection can be adjusted by controlling the pitch of the helical structure. By controlling the values of n and P, it is possible to control the central wavelength λ for selectively reflecting any of right-hand circular polarization and left-hand circular polarization for the light of a desired wavelength.

In a case where light obliquely comes into the cholesteric liquid crystal layer, the central wavelength of selective reflection shifts to the short wavelength side. Therefore, it is preferable to adjust the value of n×P such that λ calculated by the above formula λ=n×P becomes a long wavelength with respect to the central wavelength of selective reflection required for image display. In a case where a light ray passes through a cholesteric liquid crystal layer having a refractive index of n₂ at an angle of θ₂ with respect to the normal direction of the cholesteric liquid crystal layer (direction of the helical axis of the cholesteric liquid crystal layer), provided that the central wavelength of selective reflection is λ_{d}, λ_{d} is represented by the following formula.

λ_{d}=n₂×P×cos θ₂

In a case where the central wavelength of selective reflection of the cholesteric liquid crystal layer included in the circular polarization reflection layer is designed in consideration of the relationships described above, it is possible to prevent the reduction of the visibility of an obliquely observed image. Furthermore, it is possible to intentionally reduce the visibility of an obliquely observed image, and doing this thing is useful for preventing peeping in smartphones or personal computers, for example. In addition, due to the selective reflection properties described above, in a case where the mirror with an image display function having the optical film according to the embodiment of the present invention is seen in an oblique direction, sometimes tint appears in an image or an image reflected from the mirror. By incorporating the cholesteric liquid crystal layer having the central wavelength of selective reflection in the infrared region into the circular polarization reflection layer, the appearance of the tint can also be prevented. In this case, specifically, the central wavelength of selective reflection of the infrared region is preferably 780 to 900 nm, and more preferably 780 to 850 nm.

In a case where cholesteric liquid crystal layers having the central wavelength of selective reflection in the infrared region are provided, it is preferable that all the cholesteric liquid crystal layers each having the central wavelength of selective reflection in the visible region are on a side which is closest to the image display device side.

The pitch of the cholesteric liquid crystalline phase depends on the type of a chiral agent used together with the polymerizable liquid crystal compound or on the concentration of the chiral agent added. Consequently, by adjusting the type and concentration of the chiral agent, an intended pitch can be obtained. For measuring the sense or pitch of the helix, it is possible to use the methods described in “Introduction to Experiment of Liquid Crystal Chemistry” (edited by The Japanese Liquid Crystal Society, Sigma Publication Ltd, 2007, p. 46) and “Handbook of Liquid Crystal” (Editorial Committee of Handbook of Liquid Crystal, MARUZEN Co., Ltd. p. 196).

In the mirror with an image display function having the optical film according to the embodiment of the present invention, the circular polarization reflection layer preferably includes a cholesteric liquid crystal layer having a central wavelength of selective reflection in a wavelength range of red light, a cholesteric liquid crystal layer having a central wavelength of selective reflection in a wavelength range of green light, and a cholesteric liquid crystal layer having a central wavelength of selective reflection in a wavelength range of blue light. The reflection layer preferably includes, for example, a cholesteric liquid crystal layer having a central wavelength of selective reflection in a wavelength range of 400 nm to 500 nm, a cholesteric liquid crystal layer having a central wavelength of selective reflection in a wavelength range of 500 nm to 580 nm, and a cholesteric liquid crystal layer having a central wavelength of selective reflection in a wavelength range of 580 nm to 700 nm.

In a case where the circular polarization reflection layer includes a plurality of cholesteric liquid crystal layers, it is preferable that a cholesteric liquid crystal layer closer to the image display device has a longer central wavelength of selective reflection. By this constitution, the tint that obliquely appears in an image can be inhibited.

Particularly, in the mirror with an image display function in which the cholesteric circular polarization reflection layer without a ¼ wavelength plate is used, it is preferable that there is a difference equal to or greater than 5 nm between the central wavelength of selective reflection of each of the cholesteric liquid crystal layers and the emission peak wavelength of the image display device. The difference is more preferably equal to or greater than 10 nm. By causing a difference between the central wavelength of selective reflection and the emission peak wavelength for image display of the image display device, it is possible to brighten the display image without causing the light for image display from being reflected from the cholesteric liquid crystal layer. The emission peak wavelength of the image display device can be checked in an emission spectrum at the time of white display of the image display device. The peak wavelength may be a peak wavelength in a visible region of the emission spectrum. For example, as the peak wavelength, at least one or more wavelengths selected from the group consisting of an emission peak wavelength λR of red light, an emission peak wavelength λG of green light, and an emission peak wavelength λB of blue light of the image display device may be adopted. The difference between the central wavelength of selective reflection of the cholesteric liquid crystal layer and all of the emission peak wavelength λR of red light, the emission peak wavelength λG of green light, and the emission peak wavelength λB of blue light of the image display device is preferably equal to or greater than 5 nm, and more preferably equal to or greater than 10 nm. In a case where the circular polarization reflection layer includes a plurality of cholesteric liquid crystal layers, the difference between the central wavelength of selective reflection of all the cholesteric liquid crystal layers and the peak wavelength of the light emitted from the image display device is equal to or greater than 5 nm, and preferably equal to or greater than 10 nm. For example, in a case where the image display device is a full color display device showing the emission peak wavelength λR of red light, the emission peak wavelength λG of green light, and the emission peak wavelength λB of blue light in an emission spectrum at the time of white display, the difference between all the central wavelengths of selective reflection of the cholesteric liquid crystal layers and ΔR, ΔG, and ΔB is equal to or greater than 5 nm, and preferably equal to or greater than 10 nm.

By adjusting the central wavelength of selective reflection of the used cholesteric liquid crystal layer according to the emission wavelength range of the image display device and the aspect of using the circular polarization reflection layer, a bright image can be displayed with an excellent light use efficiency. Examples of the aspect of using the circular polarization reflection layer particularly include an incidence angle of light coming into the circular polarization reflection layer, an image observation direction, and the like.

As each of the cholesteric liquid crystal layers, a cholesteric liquid crystal layer in which the helix rotates in any of a right-hand sense or a left-hand sense is used. The sense of the circular polarization reflected from the cholesteric liquid crystal layer coincides with the sense of the helix. The senses of helices of a plurality of cholesteric liquid crystal layers may be the same as each other, or the senses of helices of some of the cholesteric liquid crystal layers may be different. That is, the cholesteric liquid crystal layers may include cholesteric liquid crystal layers of any of the right-hand sense or the left-hand sense or cholesteric liquid crystal layers of both of the right-hand sense and the left-hand sense. Here, in a mirror with an image display function including a ¼ wavelength plate, it is preferable that the senses of the helices of the plurality of cholesteric liquid crystal layers are the same as each other. In this case, the sense of the helix of each of the cholesteric liquid crystal layers may be determined according to the sense of the circular polarization obtained by the emission from the image display device and the transmission through the ¼ wavelength plate. Specifically, a cholesteric liquid crystal layer may be used which has the sense of a helix that transmits the circular polarization of a sense obtained by the emission from the image display device and the transmission through the ¼ wavelength plate.

A half-width Δλ (nm) of a selective reflection band in which Δλ depends on a birefringence Δn of the liquid crystal compound and the pitch P described above, and satisfies a relationship of Δλ=Δn×P. Therefore, by adjusting Δn, the width of the selective reflection band can be controlled. Δn can be controlled by adjusting the type of the polymerizable liquid crystal compound, adjusting a mixing ratio thereof, or controlling the temperature at the time of fixing the alignment.

In order to form one kind of cholesteric liquid crystal layers having the same central wavelength of selective reflection, a plurality of cholesteric liquid crystal layers having the same period P and the same helical sense may be laminated. By laminating cholesteric liquid crystal layers having the same period P and the same helical sense, the selectivity for circular polarization at a specific wavelength can be improved.

(¼ Wavelength Plate)

In the mirror with an image display function in which the cholesteric circular polarization reflection layer is used, the half mirror may further include a ¼ wavelength plate. It is preferable that the half mirror includes a phase difference film of high Re (in-plane retardation), a cholesteric circular polarization reflection layer, and a ¼ wavelength plate in this order.

In a case where the half mirror includes the ¼ wavelength plate between the image display device and the cholesteric circular polarization reflection layer, particularly, the light from the image display device displaying an image by linear polarization can be converted into circular polarization and come into the cholesteric circular polarization reflection layer. Accordingly, it is possible to significantly reduce the light which is reflected from the circular polarization reflection layer and returns to the image display device side, and a bright image can be displayed. In addition, because the mirror can have a constitution in which the circular polarization of a sense that is reflected to the image display device side in the cholesteric circular polarization reflection layer is not generated by the use of the ¼ wavelength plate, the deterioration of the quality of the displayed image resulting from the multiple reflection between the image display device and the half mirror does not easily occur.

That is, for example, even though the central wavelength of selective reflection of the cholesteric liquid crystal layer included in the cholesteric circular polarization reflection layer is approximately the same as the emission peak wavelength of blue light in the emission spectrum at the time of white display of the image display device (for example, even though the difference is less than 5 nm), it is possible to allow the light emitted from the image display device to be transmitted to the front surface side without generating circular polarization of a sense that is reflected to the image display side in the circular polarization reflection layer.

It is preferable that the angle of the ¼ wavelength plate, which is used by being combined with the cholesteric circular polarization reflection layer, is adjusted such that the image becomes the brightest in a case where the ¼ wavelength plate is bonded to the image display device. That is, particularly, in order that linear polarization is transmitted best for the image display device displaying an image by the linear polarization, it is preferable that the relationship between the polarization direction (transmission axis) of the linear polarization and the slow axis of the ¼ wavelength plate is adjusted. For example, in a case where a single layer-type ¼ wavelength plate is used, it is preferable that an angle of 45° is formed between the transmission axis and the slow axis. The light emitted from the image display device displaying an image by the linear polarization is transmitted through the ¼ wavelength plate and then becomes any of circular polarization of a right-hand sense and circular polarization of a left-hand sense. The circular polarization reflection layer may be constituted with a cholesteric liquid crystal layer having a twisted direction transmitting the circular polarization of the aforementioned sense.

The ¼ wavelength plate may be a phase difference layer which functions as a ¼ wavelength plate in a visible region. Examples of the ¼ wavelength plate include a single layer-type ¼ wavelength plate, a broadband ¼ wavelength plate obtained by laminating a ¼ wavelength plate and a ½ wavelength phase difference plate, and the like.

The frontal phase difference of the former ¼ wavelength plate may be equal to a length that is 1/4 of the emission wavelength of the image display device. Therefore, for example, in a case where the emission wavelength of the image display device is 450 nm, 530 nm, and 640 nm, as the ¼ wavelength plate, a phase difference layer having reverse dispersion properties is most preferable which results in a phase difference of 112.5 nm±10 nm, preferably 112.5 nm±5 nm, and more preferably 112.5 nm at a wavelength of 450 nm, a phase difference of 132.5 nm±10 nm, preferably 132.5 nm±5 nm, and more preferably 132.5 nm at a wavelength of 530 nm, and a phase difference of 160 nm±10 nm, preferably 160 nm±5 nm, and more preferably 160 nm at a wavelength of 640 nm. As the ¼ wavelength plate, it is also possible to use a phase difference plate which results in a phase difference having low wavelength dispersion properties or a phase difference plate having forward dispersion properties. “Reverse dispersion properties” mean properties in which the longer the wavelength is, the larger the absolute value of the phase difference becomes. “Forward dispersion properties” means properties in which the shorter the wavelength is, the greater the absolute value of the phase difference becomes.

In the laminate-type ¼ wavelength plate, a ¼ wavelength plate and a ½ wavelength phase difference plate are bonded to each other such that the slow axes thereof intersect at an angle of 60°, and the ½ wavelength phase difference plate is disposed such that it becomes a side into which linear polarization comes. Furthermore, the laminate-type ¼ wavelength plate is used in a state where the slow axis of the ½ wavelength phase difference plate intersects the polarization surface of the incoming linear polarization at an angle of 15° or 75°. Accordingly, the reverse dispersion properties of the phase difference are excellent, and hence the laminate-type ¼ wavelength plate can be suitably used.

A ¼ wavelength plate can be appropriately selected according to the purpose without particular limitation. For example, it is possible to use a quartz plate, a stretched polycarbonate film, a stretched norbornene-based polymer film, a transparent film containing aligned inorganic particles having birefringence such as strontium carbonate, a thin film obtained by obliquely vapor-depositing inorganic dielectric material on a support, and the like.

Examples of the ¼ wavelength plate include (1) phase difference plate described in JP 1993-027118A (JP-H05-027118A) and JP 1993-027119A (JP-H05-027119A) that is obtained by laminating a birefringent film having a large retardation and a birefringent film having a small retardation such that the optical axes of the films become orthogonal to each other, (2) phase difference plate described in JP1998-068816A (JP-H10-068816A) that is prepared by laminating a polymer film, which results in a ¼ wavelength at a specific wavelength, and a polymer film, which is formed of the same material as that of the aforementioned polymer film and results in a ½ wavelength at the same wavelength, so as to obtain a ¼ wavelength in a wide wavelength range, (3) phase difference plate described in JP1998-090521A (JP-H104)90521A) that can accomplish a ¼ wavelength in a wide wavelength range by the lamination of two sheets of polymer films, (4) phase difference plate described in WO00/026705A that can accomplish a ¼ wavelength in a wide wavelength range by using a modified polycarbonate film, (5) phase difference plate described in WO00/065384A that can accomplish a ¼ wavelength in a wide wavelength range by using a cellulose acetate film, and the like.

As the ¼ wavelength plate, commercial products can also be used. Examples of the commercial products include PUREACE (registered trademark) WR (polycarbonate film manufactured by TEIJIN LIMITED).

The ¼ wavelength plate may be formed by aligning and fixing a polymerizable liquid crystal compound and a high-molecular weight liquid crystal compound. For example, the ¼ wavelength plate can be formed by coating a temporary support, an alignment film, or a surface of a front panel with a liquid crystal composition, forming a nematic alignment of the polymerizable liquid crystal compound in the liquid crystal composition in a liquid crystal state, and then fixing the alignment state by means of photocrosslinking or thermal crosslinking. The details of the liquid crystal composition and the preparation method thereof will be described later. The ¼ wavelength plate may also be a layer obtained by coating a temporary support, an alignment film, or a surface of a front panel with a composition containing a high-molecular weight liquid crystal compound, forming a nematic alignment in a liquid crystal state, and then fixing the alignment state by cooling.

The ¼ wavelength plate may directly contact the cholesteric circular polarization reflection layer or may be bonded to the cholesteric circular polarization reflection layer through an adhesive layer. It is preferable that the ¼ wavelength plate directly contacts the cholesteric circular polarization reflection layer.

(Methods for Preparing Cholesteric Liquid Crystal Layer and ¼ Wavelength Plate Formed of Liquid Crystal Composition)

Hereinafter, the materials used for preparing the cholesteric liquid crystal layer and the ¼ wavelength plate formed of a liquid crystal composition and the methods for preparing the cholesteric liquid crystal layer and the ¼ wavelength plate will be described.

Examples of the material used for forming the ¼ wavelength plate include a liquid crystal composition containing a polymerizable liquid crystal compound, and the like. Examples of the material used for forming the cholesteric liquid crystal layer include a liquid crystal composition containing a polymerizable liquid crystal compound and a chiral agent (optically active compound), and the like. If necessary, by coating a temporary support, a support, an alignment film, a phase difference film of high Re, a cholesteric liquid crystal layer which will become an underlayer, a ¼ wavelength plate, or the like with the liquid crystal composition mixed with a surfactant, a polymerization initiator, or the like and then dissolved in a solvent, performing alignment and maturing, and then performing fixing by curing the liquid crystal composition, the cholesteric liquid crystal layer and/or the ¼ wavelength plate can be formed.

—Polymerizable Liquid Crystal Compound—

As the polymerizable liquid crystal compound, polymerizable rod-like liquid crystal compound may be used.

Examples of the rod-like polymerizable liquid crystal compound include rod-like nematic liquid crystal compounds. As the rod-like nematic liquid crystal compounds, azomethines, azoxys, cyanobiphenyls, cyanophenyl esters, benzoic acid esters, cyclohexanecarboxylic acid phenyl esters, cyanophenylcyclohexanes, cyano-substituted phenylpyrimidines, alkoxy-substituted phenylpyrimidines, phenyldioxanes, tolanes, and alkenylcyclohexyl benzonitriles are preferably used. Not only low-molecular weight liquid crystal compounds, but also high-molecular weight liquid crystal compounds can be used.

The polymerizable liquid crystal compound can be obtained by introducing a polymerizable group into a liquid crystal compound. Examples of the polymerizable group include an unsaturated polymerizable group, an epoxy group, and an aziridinyl group. Among these, an unsaturated polymerizable group is preferable, and an ethylenically unsaturated polymerizable group is particularly preferable. The polymerizable group can be introduced into a molecule of a liquid crystal compound by various methods. The number of polymerizable groups contained in the polymerizable liquid crystal compound is preferably 1 to 6, and more preferably 1 to 3. Examples of the polymerizable liquid crystal compound include the compounds described in Makromol. Chem., vol. 190, p. 2255 (1989), Advanced Materials, vol. 5, p. 107 (1993), U.S. Pat. Nos. 4,683,327A, 5,622,648A, 5,770,107A, WO95/022586A, WO95/024455A, WO97/000600A, WO98/023580A, WO98/052905A, JP1989-272551A (JP-H01-272551A), JP1994-016616A (JP-H06-016616A), JP1995-110469A (JP-H07-110469A), JP1999-080081A (JP-H1-080081A), JP2001-328973A, and the like. Two or more kinds of polymerizable liquid crystal compounds may be used in combination. In a case where two or more kinds of polymerizable liquid crystal compounds are used in combination, the alignment temperature can be reduced.

The content of the polymerizable liquid crystal compound in the liquid crystal composition is preferably 80% to 99.9% by mass, more preferably 85% to 99.5% by mass, and particularly preferably 90% to 99% by mass with respect to the mass (mass excluding a solvent) of the solid content of the liquid crystal composition.

—Chiral Agent: Optically Active Compound—

It is preferable that the material used for forming the cholesteric liquid crystal layer contains a chiral agent. The chiral agent has a function of inducing the helical structure of the cholesteric liquid crystalline phase. Because the sense or pitch of the induced helix varies with the compound as the chiral agent, the chiral agent may be selected according to the purpose.

The chiral agent is not particularly limited, and it is possible to use generally used compounds (for example, those described in Chapter 3, 4-3. <Chiral agents for TN and STN> in Handbook of Liquid Crystal Device, edited by the 142^{nd} committee of Japan Society for The Promotion of Science, p. 199. 1989.), isosorbide, and isomannide derivatives.

Generally, the chiral agent contains asymmetric carbon atoms. However, an axially asymmetric compound and a planarly asymmetric compound not containing asymmetric carbon atoms can also be used as the chiral agent. Examples of the axially asymmetric compound and the planarly asymmetric compound include binaphthyl, helicene, paracyclophane, and derivatives of these. The chiral agent may have a polymerizable group. In a case where both the chiral agent and the liquid crystal compound have a polymerizable group, by a polymerization reaction between the polymerizable chiral agent and the polymerizable liquid crystal compound, it is possible to form a polymer having a repeating unit derived from the polymerizable liquid crystal compound and a repeating unit derived from the chiral agent. In this aspect, the polymerizable group contained in the polymerizable chiral agent is preferably the same type of polymerizable group as the polymerizable group contained in the polymerizable liquid crystal compound. Accordingly, the polymerizable group of the chiral agent is also preferably an unsaturated polymerizable group, an epoxy group, or an aziridinyl group, more preferably an unsaturated polymerizable group, and particularly preferably an ethylenically unsaturated polymerizable group.

Furthermore, the chiral agent may be a liquid crystal compound.

In the liquid crystal composition, the content of the chiral agent with respect to the amount of the polymerizable liquid crystal compound is preferably 0.01 mol % to 200 mol %, and more preferably 1 mol % to 30 mol %.

—Polymerization Initiator—

It is preferable that the liquid crystal composition used in the present invention contains a polymerization initiator. In an aspect in which a polymerization reaction is caused by ultraviolet irradiation, as the polymerization initiator, it is preferable to use a photopolymerization initiator that can initiate the polymerization reaction by ultraviolet irradiation. Examples of the photopolymerization initiator include an α-carbonyl compound (described in U.S. Pat. Nos. 2,367,661A and 2,367,670A), an acyloin ether (described in U.S. Pat. No. 2,448,828A), an α-hydrocarbon-substituted aromatic acyloin compound (described in U.S. Pat. No. 2,722,512A), a polynuclear quinone compound (described in U.S. Pat. Nos. 3,046,127A and 2,951,758A), a combination of triarylimidazole dimer and p-aminophenylketone (described in U.S. Pat. No. 3,549,367A), acrydine and phenazine compounds (described in JP1985-105667A (JP-S60-105667A) and U.S. Pat. No. 4,239,850A), acylphosphine oxide compounds (described in JP1988-040799B (JP-S63-040799B, JP 1993-029234B (JP-H05-029234B). JP 1998-095788A (JP 10-095788A), JP 1988-029997A (JP-H10-029997A), oxime compounds (described in JP2000-066385A and JP4454067B) an oxadiazole compound (described in U.S. Pat. No. 4,212,970A), and the like.

The content of the photopolymerization initiator in the liquid crystal composition with respect to the amount of the polymerizable liquid crystal compound is preferably 0.1% to 20% by mass, and more preferably 0.5% to 5% by mass.

—Crosslinking Agent—

For the purpose of improving the film hardness after curing and improving durability, the liquid crystal composition may optionally contain a crosslinking agent. As the crosslinking agent, those cured by ultraviolet rays, heat, moisture, or the like can be suitably used.

The crosslinking agent is not particularly limited and can be appropriately selected according to the purpose. Examples of the crosslinking agent include a polyfunctional acrylate compound such as trimethylolpropane tri(meth)acrylate and pentaerythritol tri(meth)acrylate; an epoxy compound such as glycidyl (meth)acrylate and ethylene glycol diglycidyl ether; an aziridine compound such as 2,2-bishydroxymethylbutanol-tris[3-(1-aziridinyl)propionate] and 4,4-bis(ethyleneiminocarbonylamino)diphenylmethane; an isocyanate compound such as hexamethylene diisocyanate and biuret-type isocyanate; a polyoxazoline compound having an oxazoline group on a side chain; an alkoxysilane compound such as vinyltrimethoxysilane and N-(2-aminoethyl)3-aminopropyl trimethoxysilane; and the like. Furthermore, depending on the reactivity of the crosslinking agent, a generally used catalyst can be used. In a case where the catalyst is used, it is possible to improve the productivity in addition to the film hardness and durability. One kind of crosslinking agent may be used singly, or two or more kinds of crosslinking agents may be used in combination.

The content of the crosslinking agent in the liquid crystal composition is preferably 3% by mass to 20% by mass, and more preferably 5% by mass to 15% by mass. In a case where the content of the crosslinking agent is equal to or greater than the lower limit described above, a crosslinking density improving effect can be obtained. Furthermore, in a case where the content of the crosslinking agent is equal to or smaller than the upper limit described above, the stability of the formed layer can be maintained.

—Alignment Control Agent—

An alignment control agent, which makes a contribution to stably and rapidly form a planar alignment, may be added to the liquid crystal composition. Examples of the alignment control agent include fluorine (meth)acrylate-based polymers described in paragraphs “0018” to “0043” in JP2007-272185A, the compounds represented by Formulae (1) to (IV) described in paragraphs “0031” to “0034” in JP2012-203237A, and the like.

One kind of alignment control agent may be used singly, or two or more kinds of alignment control agents may be used in combination.

The amount of the alignment control agent added to the liquid crystal composition with respect to the total mass of the polymerizable liquid crystal compound is preferably 0.01% to 10% by mass, more preferably 0.01% to 5% by mass, and particularly preferably 0.02% to 1% by mass.

—Other Additives—

In addition, the liquid crystal composition may contain at least one kind of component selected from various additives such as a surfactant, which is for uniformizing the thickness by adjusting the surface tension of the coating film, and a polymerizable monomer. Furthermore, if necessary, within a range that does not deteriorate the optical performance, a polymerization inhibitor, an antioxidant, an ultraviolet absorber, a light stabilizer, a coloring material, metal oxide particles, and the like can be added to the liquid crystal composition.

—Solvent—

The solvent used for preparing the liquid crystal composition is not particularly limited and can be appropriately selected according to the purpose. However, it is preferable to use an organic solvent.

The organic solvent is not particularly limited and can be appropriately selected according to the purpose. Examples of the organic solvent include ketones, alkyl halides, amides, sulfoxides, heterocyclic compounds, hydrocarbons, esters, ethers, and the like. One kind of organic solvent may be used singly, or two or more kinds of organic solvents may be used in combination. Among these, considering the load imposed on the environment, ketones are particularly preferable.

—Coating, Alignment, and Polymerization—

The method for coating a temporary support, an alignment film, a phase difference film of high Re, a ¼ wavelength plate, and/or a cholesteric liquid crystal layer which will become an underlayer with the liquid crystal composition is not particularly limited, and can be appropriately selected according to the purpose. Examples of the coating method include a wire bar coating method, a curtain coating method, an extrusion coating method, a direct gravure coating method, a reverse gravure coating method, a die coating method, a spin coating method, a dip coating method, a spray coating method, a slide coating method, and the like. Furthermore, the coating method can be performed by transferring the liquid crystal composition which has been separately applied onto a support. By heating the liquid crystal composition used for coating, the liquid crystal molecules are aligned. At the time of forming the cholesteric liquid crystal layer, the liquid crystal molecules may be aligned in a cholesteric phase. At the time of forming the ¼ wavelength plate, the liquid crystal molecules are preferably aligned in a nematic phase. At the time of cholesteric alignment, the heating temperature is preferably equal to or lower than 200° C., and more preferably equal to or lower than 130° C. By the alignment treatment, an optical thin film is obtained in which the polymerizable liquid crystal compound is aligned in a twisted state so as to have a helical axis in a direction that is substantially perpendicular to the plane of the film. At the time of nematic alignment, the heating temperature is preferably 25° C. to 120° C., and more preferably 30° C. to 100° C.

The aligned liquid crystal compound can be further polymerized such that the liquid crystal composition is cured. The polymerization may be any of thermal polymerization and photopolymerization performed by light irradiation, but is preferably photopolymerization. It is preferable to use ultraviolet rays for the light irradiation. The irradiation energy is preferably 20 mJ/cm² to 50 J/cm², and more preferably 100 mJ/cm² to 1,500 mJ/cm². In order to accelerate the photopolymerization reaction, the light irradiation may be performed under heating conditions or in a nitrogen atmosphere. The wavelength of the ultraviolet rays for irradiation is preferably 350 nm to 430 nm. From the viewpoint of stability, it is preferable that the polymerization reaction rate is high. The polymerization reaction rate is preferably equal to or higher than 70%, and more preferably equal to or higher than 80%. The polymerization reaction rate can be determined by measuring the consumption rate of polymerizable functional groups by using an IR absorption spectrum.

The thickness of each cholesteric liquid crystal layer is not particularly limited as long as the thickness is within a range in which the aforementioned characteristics are exhibited. The thickness of each cholesteric liquid crystal layer is preferably within a range equal to or greater than 1.0 μm and equal to or smaller than 150 μm and more preferably within a range equal to or greater than 2.5 μm and equal to or smaller than 100 μm. Furthermore, the thickness of the ¼ wavelength plate formed of the liquid crystal composition is not particularly limited, but may be preferably 0.2 to 10 μm, and more preferably 0.5 to 2 μm.

### EXAMPLES

Hereinafter, the present invention will be more specifically described based on examples, but the present invention is not limited thereto. In the following examples, unless otherwise specified, “part” and “%” showing a composition are based on mass.

### EXAMPLES

### Example 1

<1. Preparation of Resin Film 1>

(1) Preparation of Cellulose Acylate Dope Solution for Core Layer

The following composition was put into a mixing tank and stirred, thereby preparing a cellulose acylate dope solution for a core layer.

Cellulose acylate dope solution for core layer

| | | |
|---|---|---|
| Cellulose acetate with degree of acetyl | 100 | parts by mass |
| substitution of 2.88 and weight-average | | |
| molecular weight of 260,000 | | |
| Phthalic acid ester oligomer A having the | 10 | parts by mass |
| following structure | | |
| Compound (A-1) represented by Formula I | 4 | parts by mass |
| Ultraviolet absorber represented by Formula II | 2.7 | parts by mass |
| (manufactured by BASF SE) | | |
| Light stabilizer (manufactured by BASF SE, | 0.18 | parts by mass |
| trade name: TINUVIN 123) | | |
| N-alkenylpropylenediamine triacetic acid | 0.02 | parts by mass |
| (manufactured by Nagase ChemteX Corporation, | | |
| trade name: TEKURAN DO) | | |
| Methylene chloride (first solvent) | 430 | parts by mass |
| Methanol (second solvent) | 64 | parts by mass |

The used compounds will be shown below.

Phthalic acid ester oligomer A (weight-average molecular weight: 750)

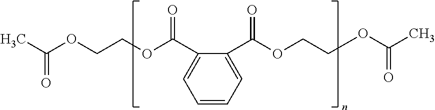

Compound (A-1) represented by Formula I

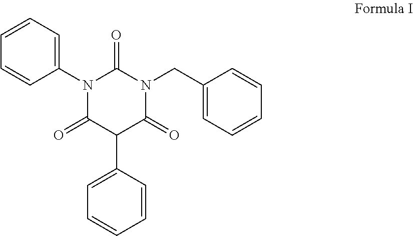 [SMILES: O=C1C(c2ccccc2)C(=O)N(c2ccccc2)C(=O)N1Cc1ccccc1]

Ultraviolet absorber represented by Formula II

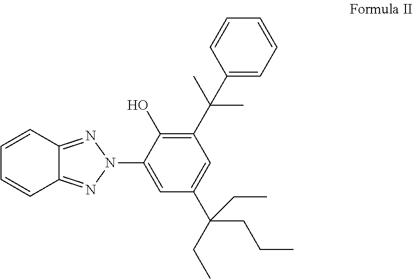 [SMILES: CCCC(CC)(CC)c1cc(-n2nc3ccccc3n2)c(O)c(C(C)(C)c2ccccc2)c1]

(2) Preparation of Cellulose Acylate Dope Solution for Outer Layer

A composition containing inorganic particles shown below (10 parts by mass) was added to 90 parts by mass of the aforementioned cellulose acylate dope solution for a core layer, thereby preparing a cellulose acylate dope solution for an outer layer.

Composition containing inorganic particles

| | | |
|---|---|---|
| Silica particles having average primary particle | 2 | parts by mass |
| diameter of 20 nm (manufactured by NIPPON | | |
| AEROSIL CO., LTD, trade name: AEROSIL R972) | | |
| Methylene chloride (first solvent) | 76 | parts by mass |
| Methanol (second solvent) | 11 | parts by mass |
| Cellulose acylate dope solution for core layer | 1 | part by mass |

(3) Preparation of First Resin Film

In order for the cellulose acylate dope solution for an outer layer to be positioned on both sides of the cellulose acylate dope solution for a core layer, three kinds of solutions including the cellulose acylate dope solution for an outer layer, the cellulose acylate dope solution for a core layer, and the cellulose acylate dope solution for an outer layer were simultaneously cast onto a casting band with a surface temperature of 20° C. from a casting outlet.

As the casting band, an endless band was used which was made of stainless steel and had a width of 2.1 m and a length of 70 m. The casting band was polished such that it had a thickness of 1.5 mm and a surface roughness equal to or lower than 0.05 μm. The material of the casting band used was SUS 316, and the casting band had sufficient corrosion resistance and hardness. The thickness unevenness of the entirety of the casting band was equal to or lower than 0.5%.

The surface of the obtained casting film was exposed to the air for fast drying with a gas concentration of 16% and a temperature of 60° C. at a wind speed of 8 m/s, thereby forming an initial film. Then, drying air with a temperature of 140° C. was blown to the film from the upstream side of the upper portion of the casting band. Furthermore, drying air with a temperature of 120° C. and drying air with a temperature of 60° C. were blown to the film from the downstream side.

After the amount of residual solvent became about 33% by mass, the film was peeled off from the band. Thereafter, both ends of the obtained film in the width direction were fixed to tenter clips, and then the film was transported between rolls of a heat treatment apparatus such that the film was further dried, thereby preparing a first resin film 1 having a thickness of 200 μm (outer layer/core layer/outer layer=3 μm/194 μm/3 μm). In Table 3-1 and Table 3-2, the resin film 1 is described as TAC.

<2. Preparation of Curable Composition for Forming Hardcoat Layer (HC Layer)>

Components were mixed together according to the composition shown in Table 1 and filtered through a filter made of polypropylene having a pore size of 10 μm, thereby preparing curable compositions HC-1 to HC-21 for forming an HC layer.

TABLE 1

| | | Curable composition for forming HC layer | | | | | | | | | | | |
|---|---|---|---|---|---|---|---|---|---|---|---|---|---|
| | | | | | | | | | | | HC- | HC- | HC- |
| | | HC-1 | HC-2 | HC-3 | HC-4 | HC-5 | HC-6 | HC-7 | HC-8 | HC-9 | 10 | 11 | 12 |
| Polymerizable | DPHA | 94.00 | 94.00 | 94.00 | 94.00 | 94.00 | 94.00 | 94.00 | 94.00 | 94.50 | 94.90 | 94.50 | 94.90 |
| compound | CYCLOMER M100 | | | | | | | | | | | | |
| Polymerization initiator | Radical | 4.00 | 4.00 | 4.00 | 4.00 | 4.00 | 4.00 | 4.00 | 4.00 | 4.00 | 4.00 | 4.00 | 4.00 |
| | photopolymerization | | | | | | | | | | | | |
| | initiator Irg184 | | | | | | | | | | | | |
| | Cationic | | | | | | | | | | | | |
| | photopolymerization | | | | | | | | | | | | |
| | initiator PAG-1 | | | | | | | | | | | | |
| Fluorine-containing | RS-90 | 1.00 | 1.00 | 1.00 | 1.00 | 1.00 | 1.00 | 1.00 | | 0.50 | 0.10 | 1.00 | 1.00 |
| compound | RS-78 | | | | | | | | 1.00 | | | | |
| Polysiloxane-containing | KF-96-10CS | 1.00 | | | | | | | | | | | |
| compound | X-22-164 | | 1.00 | | | | | | | | | | |
| | X-22-164AS | | | 1.00 | | | | | | | | | |
| | X-22-164A | | | | 1.00 | | | | | | | | |
| | X-22-164B | | | | | 1.00 | | | | | | | |
| | UMS-182 | | | | | | 1.00 | | | | | | |
| | 8SS-723 | | | | | | | 1.00 | 1.00 | 1.00 | 1.00 | 0.50 | 0.10 |
| Leveling agent | P-112 | | | | | | | | | | | | |
| Inorganic particles | MEK-AC-2140Z | | | | | | | | | | | | |
| Solvent | MEK | 40.00 | 40.00 | 40.00 | 40.00 | 40.00 | 40.00 | 40.00 | 40.00 | 40.00 | 40.00 | 40.00 | 40.00 |
| | Cyclohexanone | | | | | | | | | | | | |
| | MIBK | 60.00 | 60.00 | 60.00 | 60.00 | 60.00 | 60.00 | 60.00 | 60.00 | 60.00 | 60.00 | 60.00 | 60.00 |

| | | | | | | | | | | | | |
|---|---|---|---|---|---|---|---|---|---|---|---|---|
| Concentration of solid contents in composition | 25 | 25 | 25 | 25 | 25 | 25 | 25 | 25 | 25 | 25 | 25 | 25 |

| | | Curable composition for forming HC layer | | | | | | | | |
|---|---|---|---|---|---|---|---|---|---|---|
| | | HC-13 | HC-14 | HC-15 | HC-16 | HC-17 | HC-18 | HC-19 | HC-20 | HC-21 |
| Polymerizable | DPHA | 94.95 | 65.10 | 95.00 | 95.00 | 93.00 | 87.00 | 84.00 | 15.10 | 5.10 |
| compound | CYCLOMER M100 | | 30.00 | | | | | | 50.00 | 50.00 |
| Polymerization initiator | Radical | 4.00 | 4.00 | 4.00 | 4.00 | 4.00 | 4.00 | 4.00 | 4.00 | 4.00 |
| | photopolymerization | | | | | | | | | |
| | initiator Irg184 | | | | | | | | | |
| | Cationic | | 0.80 | | | | | | 0.80 | 0.80 |
| | photopolymerization | | | | | | | | | |
| | initiator PAG-1 | | | | | | | | | |
| Fluorine-containing | RS-90 | 1.00 | | 1.00 | | 1.00 | 1.00 | 1.00 | | |
| compound | RS-78 | | | | | | | | | |
| Polysiloxane-containing | KF-96-10CS | | | | | | | | | |
| compound | X-22-164 | | | | | | | | | |
| | X-22-164AS | | | | | | | | | |
| | X-22-164A | | | | | | | | | |
| | X-22-164B | | | | | | | | | |
| | UMS-182 | | | | | | | | | |
| | 8SS-723 | 0.05 | | | 1.00 | 1.00 | 1.00 | 1.00 | | |
| Leveling agent | P-112 | | 0.10 | | | | | | 0.10 | 0.10 |
| Inorganic particles | MEK-AC-2140Z | | | | | 1.00 | 7.00 | 10.00 | 30.00 | 40.00 |
| Solvent | MEK | 40.00 | 1.00 | 40.00 | 40.00 | 40.00 | 40.00 | 40.00 | 100.00 | 100.00 |
| | Cyclohexanone | | 99.00 | | | | | | | |
| | MIBK | 60.00 | | 60.00 | 60.00 | 60.00 | 60.00 | 60.00 | | |

| | | | | | | | | | |
|---|---|---|---|---|---|---|---|---|---|
| Concentration of solid contents in composition | 25 | 60 | 25 | 25 | 25 | 25 | 25 | 60 | 60 |

The unit of the numerical values in Table 1 is % by mass. In Table 1, the amount of each component is described such that the total amount of solid contents and solvents becomes 100% by mass.

The details of each compound described in Table 1 are as below.

<Polymerizable Compound>

DPHA: mixture of dipentaerythritol pentaacrylate and dipentaerythritol hexaacrylate (manufactured by Nippon Kayaku Co., Ltd., trade name: KAYARAD DPHA)

CYCLOMER M100: 3,4-epoxycyclohexylmethyl methacrylate (manufactured by DAICEL CORPORATION, trade name)

<Polymerization Initiator>

Irg 184: 1-hydroxy-cyclohexyl-phenyl-ketone (radical photopolymerization initiator based on α-hydroxyalkylphenone, manufactured by BASF SE, trade name: IRGACURE 184)

PAG-1: cationic photopolymerization initiator as iodonium salt compound shown below

Cationic photopolymerization initiator (iodonium salt compound)

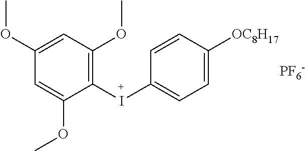

<Fluorine-Containing Compound>

RS-90: manufactured by DIC Corporation, fluorine-containing antifoulant having radically polymerizable group

RS-78: manufactured by DIC Corporation, fluorine-containing antifoulant having radically polymerizable group

<Polysiloxane-Containing Compound>

KF-96-10CS: polysiloxane antifoulant, manufactured by Shin-Etsu Chemical Co., Ltd., without radically polymerizable group

X-22-164: manufactured by Shin-Etsu Chemical Co., Ltd., polysiloxane antifoulant having methacryloyl group of reactive group equivalent of 190 g/mol

X-22-164AS: manufactured by Shin-Etsu Chemical Co., Ltd., polysiloxane antifoulant having methacryloyl group of reactive group equivalent of 450 g/mol

X-22-164A: manufactured by Shin-Etsu Chemical Co., Ltd., polysiloxane antifoulant having methacryloyl group of reactive group equivalent of 860 g/mol

X-22-164B: manufactured by Shin-Etsu Chemical Co., Ltd., polysiloxane antifoulant having methacryloyl group of reactive group equivalent of 1,600 g/mol

UMS-182: manufactured by GELEST, INC., polysiloxane antifoulant having acryloyl group of reactive group equivalent of 2,700 g/mol

8SS-723: manufactured by TAISEI FINE CHEMICAL CO., LTD., polysiloxane antifoulant having acryloyl group of reactive group equivalent of 338 g/mol

<Leveling Agent>

P-112: leveling agent, compound P-112 described in paragraph “0053” in JP5175831B

<Inorganic Particles>

MEK-AC-2140Z: manufactured by NISSAN CHEMICAL INDUSTRIES, LTD., spherical silica particles having average primary particle diameter of 10 to 20 nm

<Solvent>

MEK: methyl ethyl ketone

MIBK: methyl isobutyl ketone

<3. Preparation of Optical Film>

For the resin film 1 prepared as above having a film thickness of 200 μm, a surface of the resin film that was opposite to the surface thereof contacting the casting band was coated with the curable composition HC-1 for forming an HC layer, and the curable composition was cured so as to form an HC layer having a film thickness of 5 μm, thereby preparing an optical film of Example 1. As shown in FIG. 1, an optical film 4A has a structure in which a resin film 1A and an HC layer 2A are laminated in this order.

Specifically, the coating and curing method is as below. By means of the die coating method using a slot die described in Example 1 in JP2006-122889A, coating was performed using the curable composition for forming an HC layer under the condition of a transport speed of 30 m/min, and the curable composition was dried for 150 seconds at an atmospheric temperature of 60° C. Then, with nitrogen purging at an oxygen concentration of about 0.1% by volume, by using an air-cooled metal halide lamp (manufactured by EYE GRAPHICS Co., Ltd.) at 160 W/cm, the curable composition for forming an HC layer used for coating was cured by being irradiated with ultraviolet rays at an illuminance of 300 mW/cm² and an irradiation amount of 600 mJ/cm² such that an HC layer was formed, and the obtained film was wound up, thereby preparing an optical film of Example 1.

### Examples 2 to 8, 15 to 19, and 32 to 34

Optical films of Examples 2 to 8, 15 to 19, and 32 to 34 were prepared in the same manner as in Example 1, except that curable compositions HC-2 to HC-13 and HC-17 to HC-19 for forming an HC layer were used instead of the curable composition HC-1 for forming an HC layer.

### Example 9

An optical film of Example 9 was prepared in the same manner as in Example 7, except that the thickness of the resin film 1 was set to be 150 μm (outer layer/core layer/outer layer=3 μm/144 μm/3 μm).

### Example 10

An optical film of Example 10 was prepared in the same manner as in Example 7, except that the thickness of the resin film 1 was set to be 100 μm (outer layer/core layer/outer layer=3 μm/94 μm/3 μm).

### Example 11

An optical film of Example 11 was prepared in the same manner as in Example 7, except that the thickness of the resin film 1 was set to be 80 μm (outer layer/core layer/outer layer=3 μm/74 μm/3 μm).

### Example 12

An optical film of Example 12 was prepared in the same manner as in Example 7, except that the thickness of the resin film 1 was set to be 300 μm (outer layer/core layer/outer layer=3 μm/294 μm/3 μm).

### Example 13

An optical film of Example 13 was prepared by the same method as that in Example 7, except that instead of the resin film 1, a resin film 13 was used which was prepared by the following method.

<1> Preparation of Resin Film 13

In order for the cellulose acylate dope solution for an outer layer to be positioned on both sides of the cellulose acylate dope solution for a core layer, three kinds of solutions including the cellulose acylate dope solution for an outer layer, the cellulose acylate dope solution for a core layer, and the cellulose acylate dope solution for an outer layer were simultaneously cast onto a casting band with a surface temperature of 20° C. from a casting outlet.

As the casting band, an endless band was used which was made of stainless steel and had a width of 2.1 m and a length of 70 m. The casting band was polished such that it had a thickness of 1.5 mm and a surface roughness equal to or lower than 0.05 μm. The material of the casting band was SUS 316 and had sufficient corrosion resistance and hardness. The thickness unevenness of the entirety of the casting band was equal to or lower than 0.5%.

The surface of the obtained casting film was exposed to the air for fast drying with a gas concentration of 16% and a temperature of 60° C. at a wind speed of 8 m/s, thereby forming an initial film. Then, drying air with a temperature of 140° C. was blown to the film from the upstream side of the upper portion of the casting band. Furthermore, drying air with a temperature of 120° C. and drying air with a temperature of 60° C. were blown to the film from the downstream side.

After the amount of residual solvent became about 33% by mass, the film was peeled off from the band. Then, both ends of the obtained film in the width direction were fixed to tenter clips, and after the amount of residual solvent became 3% to 15% by mass, the film was dried while being stretched 106% in the cross direction. Thereafter, the film was transported between rolls of a heat treatment apparatus and then further dried, thereby preparing a first resin film 13 having a thickness of 100 μm (outer layer/core layer/outer layer=3 μm/94 μm/3 μm).

### Example 14

An optical film of Example 14 was prepared in the same manner as in Example 13, except that instead of the resin film 13, a resin film 14 bonded by the following method was used.

<1> Preparation of Resin Film 14

(1) Saponification Treatment for Resin Film

The resin film 13 prepared in Example 13 was immersed for 2 minutes in a 1.5 mol/L aqueous NaOH solution (saponification solution) kept at a liquid temperature of 55° C., and then rinsed with water. The film was then immersed for 30 seconds in a 0.05 mol/L aqueous sulfuric acid solution kept at a liquid temperature of 25° C. and then rinsed with flowing water for 30 seconds such that the film became neutral. Thereafter, by using an air knife, water was repeatedly blown off three times, and then the film was caused to stay for 15 seconds in a drying zone with an atmospheric temperature of 70° C. such that the film was dried, thereby preparing resin film having undergone a saponification treatment. By performing the saponification treatment in the same manner, a total of two sheets of resin films 13 having undergone a saponification treatment were prepared.

(2) Preparation of Solution for Forming Adhesive Layer

By using a solution A-1 for forming an adhesive layer shown in the following Table 2, two sheets of the saponified resin films 13 were bonded to each other by the method described below.

Hereinafter, details of steps for bonding and used compounds will be described.

TABLE 2

| Component | A-1 |
|---|---|
| HEC | 4.75% |
| Boric acid | 0.25% |
| Water | 95.00% |
| Concentration of solid contents in composition | 5.0% |

In Table 2, the amount of each component is described such that the total amount of the components becomes 100% by mass.

The details of each compound described in Table 2 are as below.

<Resin>

HEC: hydroxyethyl cellulose, weight-average molecular weight: 391,000

(3) Bonding of Resin Film

The components were mixed together according to the composition shown in Table 2 and filtered through a filter made of polypropylene having a pore size of 10 μm, thereby preparing a solution A-1 for forming an adhesive layer.

A surface of the resin film 13 that contacted the casting band side was coated with the solution A-1 for forming an adhesive layer prepared as above such that the thickness of the adhesive layer became 1 μm after drying. Then, a surface of another sheet of resin film 13 that contacted the casting band side and the aforementioned adhesive layer were bonded to each other by using a roller under the conditions of a pressure of 3 MPa and a speed of 900 rpm and dried for 10 or more minutes at an atmospheric temperature of 70° C., thereby preparing a resin film 14 in which two sheets of the resin films 13 were bonded to each other through the adhesive layer.

### Example 20

An optical film of Example 20 was prepared by the same method as that in Example 7, except that the HC layer was prepared in the following manner.

<1> Preparation of HC Layer

(1) Preparation of First HC Layer

Components were mixed together according to the composition shown in Table 1 and filtered through a filter made of polypropylene having a pore size of 10 μm, thereby preparing a curable compositions HC-14 for forming an HC layer.

A surface of the resin film 1 that was opposite to the surface thereof contacting the casting band was coated with the curable composition HC-14 for forming an HC layer, and the curable composition was cured, thereby forming an HC layer.

Specifically, coating and curing were performed by the following method. By a die coating method using a slot die described in Example 1 in JP2006-122889A, coating was performed using the curable composition for forming an HC layer under the condition of a transport speed of 30 m/min, and the curable composition was dried for 150 seconds at an atmospheric temperature of 60° C. Then, with nitrogen purging at an oxygen concentration of about 0.1% by volume, by using an air-cooled metal halide lamp (manufactured by EYE GRAPHICS Co., Ltd.) at 160 W/cm, the curable composition for forming an HC layer used for coating was cured by being irradiated with ultraviolet rays at an illuminance of 20 mW/cm² and an irradiation amount of 30 mJ/cm² such that a first HC layer was formed, and the obtained film was wound up.

(2) Preparation of Second HC Layer

The surface of the first HC layer formed as above was coated with the curable composition HC-7 for forming an HC layer, and the curable composition was cured, thereby forming an HC layer.

Specifically, coating and curing were performed by the following method. By a die coating method using a slot die described in Example 1 in JP2006-122889A, coating was performed using the curable composition for forming an HC layer under the condition of a transport speed of 30 m/min, and the curable composition was dried for 150 seconds at an atmospheric temperature of 60° C. Then, with nitrogen purging at an oxygen concentration of about 0.1% by volume, by using an air-cooled metal halide lamp (manufactured by EYE GRAPHICS Co., Ltd.) at 160 W/cm, the curable composition was irradiated with ultraviolet rays at an illuminance of 300 mW/cm² and an irradiation amount of 600 mJ/cm² such that a second HC layer was formed, thereby preparing an optical film of Example 20.

### Example 21

An optical film of Example 21 was prepared by the same method as that in Example 7, except that instead of the resin film 1, an acrylic resin film 21 prepared as below was used.

<1> Preparation of Acrylic Resin Film

Pellets of an acrylic resin (trade name: SUMIPEX EX) manufactured by Sumitomo Chemical Co., Ltd were put into a single-screw extruder having an extrusion diameter of 65 mm, melted, and integrated by being melted and laminated by a multi-manifold method. Then, the extruder was controlled such that the film thickness of each layer became 5 μm/190 μm/5 μm after drying, and the resin was extruded through T-shaped dies at a set temperature of 260° C. The obtained film-shaped substance was molded by being sandwiched between a pair of metal rolls, thereby preparing an acrylic resin film 21 which had a thickness of 200 μm. In the following Table 3-1, the acrylic resin film is described as PMMA.

### Example 22

An optical film of Example 22 was prepared by the same method as that in Example 7, except that a PET-based resin film 22 prepared as below was used instead of the resin film 1.

<1> Preparation of PET-Based Resin Film

(1) Preparation of Composition for Forming Easily Adhesive Layer

(1-1) Preparation of Polyester-Based Resin

Polymerizable compounds composed as below were copolymerized, thereby obtaining a sulfonic acid-based aqueous dispersion of a polyester-based resin.

(Acid components) terephthalic acid/isophthalic acid/sodium 5-sulfoisophthalate//(diol components) ethylene glycol/diethylene glycol=44/46/10/84/16 (molar ratio)

(1-2) Preparation of Crosslinking Agent (Isocyanate-Based Compound A)

Nitrogen purging was performed in a 4-neck flask (reactor) equipped with a stirrer, a thermometer, a reflux cooling pipe, and a nitrogen inlet pipe. The reactor was filled with 1,000 parts by mass of hexamethylene diisocyanate (HDI) and 22 parts by mass of trimethylolpropane (molecular weight: 134) as a trihydric alcohol, and in a state where the temperature of the reaction solution in the reactor was being kept at 90° C., the reaction solution was stirred for 1 hour so as to perform urethanization. Then, in a state where the temperature of the reaction solution was being kept at 60° C., trimethylbenzyl ammonium.hydroxide as an isocyanuration catalyst was added to the reaction solution. At a point in time when the rate of inversion into isocyanurate reached 48%, phosphoric acid was added thereto such that the reaction stopped. Thereafter, the reaction solution was filtered, and then the unreacted HDI was removed using a thin-film evaporator, thereby obtaining an isocyanate-based compound a.

The viscosity of the obtained isocyanate-based compound a at 25° C. was 25,000 mPa·s, the content of an isocyanate group in the compound was 19.9% by mass, the number-average molecular weight of the compound was 1,080, and the average number of isocyanate groups in the compound was 5.1. Through Nuclear Magnetic Resonance (NMR) analysis, the existence of a urethane bond, an allophanate bond, and an isocyanurate bond was checked.

Nitrogen purging was performed in a 4-neck flask (reactor) equipped with a stirrer, a thermometer, a reflux cooling pipe, a nitrogen inlet tube, and a dropping funnel. The reactor was filled with 100 parts by mass of the isocyanate-based compound a obtained as above, 42.3 parts by mass of methoxypolyethylene glycol having a number-average molecular weight of 400, and 76.6 parts by mass of dipropylene glycol dimethyl ether, and the reaction solution was kept at 80° C. for 6 hours. Then, the temperature of the reaction solution was cooled to 60° C., 72 parts by mass of diethyl malonate and 0.88 parts by mass of a 28% by mass methanol solution of sodium methylate were added thereto, the solution was kept as it was for 4 hours, and then 0.86 parts by mass of 2-ethylhexyl acid phosphate was added thereto. Subsequently, 43.3 parts by mass of diisopropylamine was added thereto, and the temperature of the reaction solution was kept at 70° C. for 5 hours. By analyzing the reaction solution through gas chromatography, it was confirmed that a reaction rate of diisopropylamine was 70%. In this way, an isocyanate-based compound A was obtained (concentration of solid content: 70% by mass, mass of effective NCO group: 5.3% by mass).

(1-3) Preparation of Composition for Forming Easily Adhesive Layer

Carboxylic acid-modified polyvinyl alcohol resin (manufactured by KURARAY CO., LTD., 57.6 parts by mass) having a degree of saponification of 77% and a degree of polymerization of 600. 28.8 parts by mass (solid content) of the polyester-based resin prepared as above, 4.0 parts by mass of the isocyanate-based compound A prepared as above, 0.7 parts by mass of an organic tin-based compound (ELASTRON Cat-21 manufactured by DKS Co., Ltd.), and 8.1 parts by mass of silica sol having an average primary particle diameter of 80 nm were mixed together and diluted with water such that the solid content thereof became 8.9 parts by mass, thereby preparing a composition for forming an easily adhesive layer.

(2) Preparation of PET Film

(2-1) Preparation of Raw Material Polyester 1

Terephthalic acid and ethylene glycol were directly reacted with each other as shown below, water was distilled away, and esterification was performed. Then, by using a direct esterification method in which polycondensation is performed under reduced pressure, a raw material polyester 1 (Sb catalyst-based PET) was obtained using a continuous polymerization apparatus.

(2-1-1) Esterification Reaction

High-purity terephthalic acid (4.7 tons) and 1.8 tons of ethylene glycol were mixed together for 90 minutes, thereby forming a slurry. The slurry was continuously supplied to a first esterification reactor at a flow rate of 3,800 kg/h. Furthermore, antimony trioxide in an ethylene glycol solution was continuously supplied thereto, and a reaction was performed with stirring at an internal temperature of the reactor of 250° C. and an average residence time of about 4.3 hours. At this time, the antimony trioxide was continuously added such that the amount of Sb added became 150 mass parts per million (ppm) in terms of the element.

The reactant was moved to a second esterification reactor and reacted with stirring at an internal temperature of the reactor of 250° C. and an average residence time of 1.2 hours. To the second esterification reactor, magnesium acetate in an ethylene glycol solution and trimethyl phosphate in an ethylene glycol solution were continuously supplied such that the amount of Mg added and the amount of P added became 65 mass ppm and 35 mass ppm respectively in terms of the elements.

(2-1-2) Polycondensation Reaction

The esterification reaction product obtained as above was continuously supplied to a first polycondensation reactor and subjected to polycondensation with stirring at a reaction temperature of 270° C., an internal pressure of the reactor of 20 torr (2.67×10⁻⁴ MPa, 1 Torr equals about 133.3224 Pa), and an average residence time of about 1.8 hours.

The reactant was moved to a second polycondensation reactor and reacted (polycondensed) with stirring under the condition of an internal temperature of the reactor of 276° C., an internal pressure of the reactor of 5 torr (6.67×10⁻⁴ MPa), and a residence time of about 1.2 hours.

Then, the reactant was moved to a third polycondensation reactor and reacted (polycondensed) under the condition of an internal temperature of the reactor of 278° C., an internal pressure of the reactor of 1.5 torr (2.0×10⁻⁴ MPa), and a residence time of 1.5 hours, thereby obtaining a reactant (polyethylene terephthalate (PET)).

(2-1-3) Preparation of Raw Material Polyester 1

Thereafter, the obtained reactant was jetted to cold water in the form of strands and immediately cut, thereby preparing polyester pellets <cross-section: major axis of about 4 mm, minor axis of about 2 mm, and length of about 3 mm>. Intrinsic viscosity (IV) of the obtained polymer was 0.63 dL/g. The polymer was named raw material polyester 1.

(2-2) Preparation of Raw Material Polyester 2

Dried ultraviolet absorber (2,2′-(1,4-phenylene)bis(4H-3, l-benzoxazin-4-one)) (10 parts by mass) and 90 parts by mass of the raw material polyester 1 (IV=0.63 dL/g) were mixed together and made into pellets in the same manner as in Preparation of raw material polyester 1 by using a kneading extruder, thereby obtaining a raw material polyester 2 containing an ultraviolet absorber.

(2-3) Preparation of PET Film

A polyester-based resin film (laminated film) constituted with three layers (layer I/layer II/layer III) was prepared by the following method.

A composition for the layer II described below was dried until the moisture content thereof became equal to or lower than 20 mass ppm, put into a hopper of a single-screw kneading extruder having a diameter of 50 mm and melted at 300° C. in the extruder, thereby preparing a molten resin material for forming the layer II positioned between the layer I and the layer III.

Composition for layer II

| | |
|---|---|
| Raw material polyester 1 | 90 parts by mass |
| Raw material polyester 2 containing 10 parts by mass | 10 parts by mass |
| of ultraviolet absorber (2,2′-(1,4-phenylene)bis(4H- | |
| 3,1-benzoxazin-4-one)) | |

The raw material polyester 1 was dried until the moisture content thereof became equal to or lower than 20 mass ppm, put into a hopper of a single-screw kneading extruder having a diameter of 30 mm, and melted at 300° C. in the extruder, thereby preparing a molten resin material for forming the layer I and the layer III.

These two kinds of molten resin materials were passed through a gear pump and a filter (pore size: 20 μm) respectively. Then, through a block by which the two kinds of resins become confluent as three layers, the resin materials were laminated such that the molten resin material extruded from the extruder for the layer II became the inner layer and that the molten resin material extruded from the extruder for the layer I and the layer III became the outer layers, and then extruded in the form of a sheet from a die having a width of 120 mm.

The molten resin sheet extruded from the die was extruded onto a cooling casting drum set to have a surface temperature of 25° C. and caused to come into close contact with the cooling casting drum by using a method of applying static electricity. By using a peeling roll disposed to face the cooling casting drum, the film obtained after cooling was peeled from the drum, thereby obtaining a non-stretched film. At this time, the amount of resin jetted from each extruder was adjusted such that a thickness ratio of layer I:layer II:layer III became 10:80:10.

By using a group of heated rolls and an infrared heater, the non-stretched film was heated such that the surface temperature of the film became 95° C. Then, by using a group of rolls having different circumferential speeds, the film was stretched 400% in a direction perpendicular to the transport direction of the film, thereby obtaining a resin film having a thickness of 200 μm.

(3) Preparation of Resin Film (PET) with Easily Adhesive Layer

One surface of the resin film prepared as above was subjected to a corona discharge treatment at a throughput of 500 J/m². Then, by a reverse roll method, the surface having undergone the corona discharge treatment was coated with the composition for forming an easily adhesive layer prepared as above such that the thickness became 0.1 μm after drying. In this way, a resin film 22 with an easily adhesive layer was prepared. The obtained resin film with an easily adhesive layer was named PET-based resin film and described as PET in the following Table 3-1.

### COMPARATIVE EXAMPLES

### Comparative Example 1

An optical film of Comparative Example 1 was prepared in the same manner as in Example 7, except that the curable composition HC-15 for forming an HC layer was used instead of the curable composition HC-7 for forming an HC layer.

### Comparative Example 2

An optical film of Comparative Example 2 was prepared in the same manner as in Example 7, except that the curable composition HC-16 for forming an HC layer was used instead of the curable composition HC-7 for forming an HC layer.

### Comparative Example 3

An optical film of Comparative Example 3 was prepared in the same manner as in Example 7, except that the thickness of the resin film 1 was set to be 60 μm (outer layer/core layer/outer layer=3 μm/54 μm/3 μm).

<Test>

The optical films prepared as above were tested as below. The test results are summarized in the following Table 3-1 and Table 3-2.

### [Test Example 1] Keystroke Durability

A glass plate (manufactured by Corning Incorporated, trade name: EAGLE XG, thickness: 1 mm) and each of the optical films (resin films with an HC layer) prepared as above were bonded to each other through a pressure sensitive adhesive having a thickness of 20 μm (manufactured by Soken Chemical & Engineering Co., Ltd., trade name: SK-2057) by using a rubber roller under a load of 2 kg applied thereto such that the glass plate and the resin film side faced each other, and the resulting film was humidified for 2 hours at a temperature of 25° C. and a relative humidity of 60%. Then, by using a keystroke tester (manufactured by YSC), an input stylus (material of the stylus tip: polyacetal, radius R=0.8 mm, manufactured by Wacom) was pressed on the film from above the HC layer (keystroke speed: 2 times/min, load: 250 g). By using a bundle of 10 sheets of SAVINA (trade name, manufactured by KB SEIREN, LTD., void volume: 1 μm) stacked, a keystroke test portion on the HC layer side was wiped twice back and force under a load by which the bundle of cloth was depressed, and in a state where the optical film was being irradiated with a three-wave fluorescent lamp (NATIONAL PALOOK FLUORESCENT LAMP FL20SS.EX-D/18) from the front surface thereof, the optical film was visually observed, and attachments and recesses after the keystroke durability test were evaluated based on the following standards.

<Attachment after Keystroke Durability Test: Evaluation Standards>

A: No attachment was found on the surface of the HC layer even after the keystroke was performed 100,000 times.

B: While the keystroke was being performed 50,001 to 100,000 times, attachments were found on the surface of the HC layer.

C: While the keystroke was being performed 10,001 to 50,000 times, attachments were found on the surface of the HC layer.

D: While the keystroke was being performed 1,001 to 10,000 times, attachments were found on the surface of the HC layer.

E: While the keystroke was being performed 1,000 times, attachments were found on the surface of the HC layer.

<Recesses after Keystroke Durability Test: Evaluation Standards>

A: No recess was made even though keystroke was performed 50,000 times.

B: While the keystroke was being performed 10,001 to 50,000 times, recesses were made.

C: While the keystroke was being performed 1,001 to 10,000 times, recesses were made.

D: While the keystroke was being performed 101 to 1,000 times, recesses were made.

E: While the keystroke was being performed 100 times, recesses were made.

### [Test Example 2] Rub Resistance

Steel wool (manufactured by NIHON STEEL WOOL Co., Ltd., No. 0) was wound around the tip rubbing portion (1 cm×1 cm), which will contact the optical film, of a rubbing tester and fixed using a band so as to prevent the steel wool from moving. Then, in an environment with a temperature of 25° C. and a relative humidity of 60%, the surface of the HC layer of the optical film of each of the examples and the comparative examples was rubbed using the rubbing tester under the following conditions.

Moving distance (one way): 13 cm, rubbing speed: 13 cm/sec, load: 1,000 g, contact area of tip portion: 1 cm×1 cm

After the test, an oil-based black ink was applied to the resin film side of the optical film of each of the examples and the comparative examples. The reflected light was visually observed, the number of times of rubbing that caused scratches in the portion contacting the steel wool was counted, and the rub resistance was evaluated based on the following standards.

<Evaluation Standards>

A: No scratch was made even after the resin film was rubbed 10,000 times.

B: While the resin film was being rubbed 1,001 to 10,000 times, scratches were made for the first time.

C: While the resin film was being rubbed 101 to 1,000 times, scratches were made for the first time.

D: While the resin film was being rubbed 11 to 100 times, scratches were made for the first time.

E: While the resin film was being rubbed for 10 times, scratches were made, and the rub resistance was problematic for practical use.

### [Test Example 3] Film Thickness

“Thickness” was observed and measured by the following method by using a Scanning Electron microscope (SEM).

The cross-section of each of the constituent members (the resin film, the adhesive layer, or the HC layer) or the cross-section of a member (for example, the liquid crystal panel or a portion thereof) including each of the constituent members was exposed by a common method such as an ion beam or a microtome. Then, the exposed cross-section was observed using SEM. During the cross-section observation, the cross-section was divided into four equal parts in the width direction of the member, and the arithmetic mean of thicknesses at three points of divisions except for both ends was calculated and adopted as the thickness of various films.

### [Test Example 4] Surface Roughness

For viewing side surface of the HC layer of the optical film of each of the examples and the comparative examples, by using Vertscan 2.0 (manufactured by MITSUBISHI CHEMICAL SYSTEMS, Inc.), a surface roughness Sa in a visual field having a size of 3,724 μm×4,965 μm was measured in a Wave mode at a lens magnification of 2.5× and a lens barrel magnification of 0.5×.

### [Test Example 5] Glass Quality

The glass quality of the optical film was evaluated according to the following procedure.

By using a pressure sensitive adhesive sheet prepared as below, the optical film and optical glass for a liquid crystal cell (manufactured by Corning Incorporated, trade name: EAGLE XG, thickness: 400 μm) were bonded to each other by a rubber roller under a load of 2 kg applied thereto such that HC layer of optical film/resin film of optical film/pressure sensitive adhesive layer of pressure sensitive adhesive sheet/optical glass were laminated in this order. A surface, which was not bonded to the optical film, of the optical glass and a black PET film with a pressure sensitive adhesive (trade name: KUKKIRI MIERU, manufactured by TOMOEGAWA CO., LTD.) were bonded to each other by a rubber roller under a load of 2 kg applied thereto such that the optical glass and the pressure sensitive adhesive became adjacent to each other. The light from a fluorescent lamp was projected onto the uppermost surface on the viewing side of the optical film, and the reflected image of the fluorescent lamp was observed and evaluated as below.

<Evaluation Standards>

A: The reflected image of the fluorescent lamp was not distorted (the quality of the optical film was the same as that of glass).

B: Distortion was observed in the reflected image of the fluorescent lamp, but the distortion was extremely slight.

C: Distortion was observed in the reflected image of the fluorescent lamp, but the distortion was slight.

<1> Preparation of Pressure Sensitive Adhesive Sheet

(1) Preparation of Pressure Sensitive Adhesive Composition

A reaction container comprising a cooling pipe, a nitrogen introduction pipe, a thermometer, and a stirrer was filled with an emulsion of raw materials of monomers that was obtained by emulsifying 96 parts of butyl acrylate (BA), 4 parts of acrylic acid (AA), 0.08 parts of t-dodecanethiol (chain transfer agent), 2 parts of sodium polyoxyethylene lauryl sulfate (emulsifier), and 153 parts of deionized water. In a state where nitrogen gas was being introduced into the container, the emulsion was stirred for 1 hour at room temperature (25° C.).

Then, the emulsion was heated to a liquid temperature of 60° C., and 0.1 parts (solid contents) of 2,2′-azobis[N-(2-carboxyethyl)-2-methylpropionamidine]hydrate (polymerization initiator) (trade name: VA-057, manufactured by Wako Pure Chemical Industries, Ltd.) prepared as a 10% aqueous solution was added thereto, and the mixture was polymerized by being stirred for 3 hours at 60° C. Aqueous ammonia (10%/o) was added to the reaction solution so as to adjust the pH of the solution to be 7.5, thereby obtaining an aqueous dispersion-type (meth)acrylic polymer (A).

The aqueous dispersion-type (meth)acrylic polymer (A) (70 parts, solid contents) obtained as above was mixed with 30 parts (solid contents) of synthetic polyisoprene latex (trade name: CEPOREX IR-100K, manufactured by Sumitomo Seika Chemicals Company, Ltd). Then, as a viscosity imparting agent, 25 parts (solid contents) of aromatic modified terpene resin emulsion (trade name: NANOLET R-1050, manufactured by YASUHARA CHEMICAL CO., LTD., softening point: 100° C.) was mixed with the mixture, and the mixture was further mixed with 0.07 parts of an epoxy-based crosslinking agent (trade name: TETRAD-C, manufactured by MITSUBISHI GAS CHEMICAL COMPANY, INC.), thereby preparing an aqueous dispersion-type pressure sensitive adhesive composition.

(2) Preparation of Pressure Sensitive Adhesive Sheet

A release-treated surface of a release sheet (manufactured by Lintec Corporation, trade name: SP-PET3811), which was obtained by performing a release treatment on one surface of a polyethylene terephthalate film by using a silicone-based release agent, was coated with the pressure sensitive adhesive composition prepared as above, such that the thickness thereof became 15 μm after driving. The composition was heated for 1 minute at an atmospheric temperature of 100° C., thereby forming a pressure sensitive adhesive layer. The pressure sensitive adhesive layer was bonded to a release-treated surface of another release sheet (manufactured by Lintec Corporation, trade name: SP-PET3801) obtained by performing a release treatment on one surface of a polyethylene terephthalate film by using a silicone-based release agent, thereby preparing a pressure sensitive adhesive sheet constituted with release sheet/pressure sensitive adhesive layer/release sheet laminated in this order.

TABLE 3-1

| | First HC layer | | | | | | |
|---|---|---|---|---|---|---|---|
| | | | Fluorine-containing | | Polysiloxane-containing compound | | |
| | | Film | compound | | | Reactive group | |
| | | thickness | | Addition | | equivalent | Addition |
| | Formulation | μm | Compound | ratio | Compound | g/mol | ratio |
| Example 1 | HC1 | 5 | RS-90 | 1.00% | KF-96-10CS | | 1.00% |
| Example 2 | HC2 | 5 | RS-90 | 1.00% | X-22-164 | 190 | 1.00% |
| Example 3 | HC3 | 5 | RS-90 | 1.00% | X-22-164AS | 450 | 1.00% |
| Example 4 | HC4 | 5 | RS-90 | 1.00% | X-22-164A | 860 | 1.00% |
| Example 5 | HC5 | 5 | RS-90 | 1.00% | X-22-164B | 1600 | 1.00% |
| Example 6 | HC6 | 5 | RS-90 | 1.00% | UMS-182 | 2700 | 1.00% |
| Example 7 | HC7 | 5 | RS-90 | 1.00% | 8SS-723 | 338 | 1.00% |
| Example 8 | HC8 | 5 | RS-78 | 1.00% | 8SS-723 | 338 | 1.00% |
| Example 9 | HC7 | 5 | RS-90 | 1.00% | 8SS-723 | 338 | 1.00% |
| Example 10 | HC7 | 5 | RS-90 | 1.00% | 8SS-723 | 338 | 1.00% |
| Example 11 | HC7 | 5 | RS-90 | 1.00% | 8SS-723 | 338 | 1.00% |
| Example 12 | HC7 | 5 | RS-90 | 1.00% | 8SS-723 | 338 | 1.00% |
| Example 13 | HC7 | 5 | RS-90 | 1.00% | 8SS-723 | 338 | 1.00% |
| Example 14 | HC7 | 5 | RS-90 | 1.00% | 8SS-723 | 338 | 1.00% |
| Example 15 | HC9 | 5 | RS-90 | 0.50% | 8SS-723 | 338 | 1.00% |
| Example 16 | HC10 | 5 | RS-90 | 0.10% | 8SS-723 | 338 | 1.00% |
| Example 17 | HC11 | 5 | RS-90 | 1.00% | 8SS-723 | 338 | 0.50% |
| Example 18 | HC12 | 5 | RS-90 | 1.00% | 8SS-723 | 338 | 0.10% |
| Example 19 | HC13 | 5 | RS-90 | 1.00% | 8SS-723 | 338 | 0.05% |
| Example 20 | HC7 | 5 | RS-90 | 1.00% | 8SS-723 | 338 | 1.00% |
| Example 21 | HC7 | 5 | RS-90 | 1.00% | 8SS-723 | 338 | 1.00% |
| Example 22 | HC7 | 5 | RS-90 | 1.00% | 8SS-723 | 338 | 1.00% |
| Example 32 | HC17 | 5 | RS-90 | 1.00% | 8SS-723 | 338 | 1.00% |
| Example 33 | HC18 | 5 | RS-90 | 1.00% | 8SS-723 | 338 | 1.00% |
| Example 34 | HC19 | 5 | RS-90 | 1.00% | 8SS-723 | 338 | 1.00% |

| | Second HC layer | | Resin film | | Evaluation | | |
|---|---|---|---|---|---|---|---|
| | | Film | | Film | After keystroke | | |
| | | thickness | Type of | thickness | durability test | | Rub |
| | Formulation | μm | resin | μm | Attachment | Recess | resistance |
| Example 1 | N/A | N/A | TAC | 200 | D | A | A |
| Example 2 | N/A | N/A | TAC | 200 | C | A | A |
| Example 3 | N/A | N/A | TAC | 200 | A | A | A |
| Example 4 | N/A | N/A | TAC | 200 | B | A | A |
| Example 5 | N/A | N/A | TAC | 200 | C | A | A |
| Example 6 | N/A | N/A | TAC | 200 | D | A | A |
| Example 7 | N/A | N/A | TAC | 200 | A | A | A |
| Example 8 | N/A | N/A | TAC | 200 | A | A | B |
| Example 9 | N/A | N/A | TAC | 150 | A | B | A |
| Example 10 | N/A | N/A | TAC | 100 | A | C | A |
| Example 11 | N/A | N/A | TAC | 80 | A | D | A |
| Example 12 | N/A | N/A | TAC | 300 | A | A | A |
| Example 13 | N/A | N/A | TAC | 100 | A | A | A |
| Example 14 | N/A | N/A | TAC | 201 | A | A | A |
| Example 15 | N/A | N/A | TAC | 200 | A | A | C |
| Example 16 | N/A | N/A | TAC | 200 | A | A | D |
| Example 17 | N/A | N/A | TAC | 200 | B | A | A |
| Example 18 | N/A | N/A | TAC | 200 | C | A | A |
| Example 19 | N/A | N/A | TAC | 200 | D | A | A |
| Example 20 | HC14 | 15 | TAC | 200 | A | A | A |
| Example 21 | N/A | N/A | PMMA | 200 | A | A | A |
| Example 22 | N/A | N/A | PET | 200 | A | A | A |
| Example 32 | N/A | N/A | TAC | 200 | A | A | B |
| Example 33 | N/A | N/A | TAC | 200 | A | A | C |
| Example 34 | N/A | N/A | TAC | 200 | A | A | D |

TABLE 3-2

| | First HC layer | | | | | | |
|---|---|---|---|---|---|---|---|
| | | | Fluorine-containing | | Polysiloxane-containing compound | | |
| | | Film | compound | | | Reactive group | |
| | | thickness | | Addition | | equivalent | Addition |
| | Formulation | μm | Compound | ratio | Compound | g/mol | ratio |
| Comparative | HC15 | 5 | RS-90 | 1.00% | N/A | N/A | N/A |
| Example 1 | | | | | | | |
| Comparative | HC16 | 5 | N/A | N/A | 8SS-723 | 338 | 1.00% |
| Example 2 | | | | | | | |
| Comparative | HC7 | 5 | RS-90 | 1.00% | 8SS-723 | 338 | 1.00% |
| Example 3 | | | | | | | |

| | Second HC layer | | Resin film | | Evaluation | | |
|---|---|---|---|---|---|---|---|
| | | Film | | Film | After keystroke | | |
| | | thickness | Type of | thickness | durability test | | Rub |
| | Formulation | μm | resin | μm | Attachment | Recess | resistance |
| Comparative | N/A | N/A | TAC | 200 | E | A | A |
| Example 1 | | | | | | | |
| Comparative | N/A | N/A | TAC | 200 | A | A | E |
| Example 2 | | | | | | | |
| Comparative | N/A | N/A | TAC | 60 | A | E | A |
| Example 3 | | | | | | | |

The film thickness of the optical film means the total film thickness of the resin film and the HC layer.

As described in Table 3-2, in Comparative Example 1, the HC layer contains a fluorine-containing compound but does not contain a polysiloxane-containing compound. As a result of keystroke durability test performed on Comparative Example 1, attachments were found while keystroke was being performed 1,000 times (evaluation: E). In Comparative Example 2, the HC layer contains a polysiloxane-containing compound but does not contain a fluorine-containing compound. Comparative Example 2 had insufficient rub resistance and was problematic for practical use because scratches were made while the resin film was being rubbed for 10 times. In Comparative Example 3, the film thickness of the resin film is less than 80 μm. As a result of keystroke durability test performed on Comparative Example 3, recesses occurred while keystroke was being performed 100 times (evaluation: E).

In contrast, in all of the optical films of Examples 1 to 22 and 32 to 34, in which the HC layer contained both the fluorine-containing compound and polysiloxane-containing compound and the film thickness of the resin film was equal to or greater than 80 μm, the occurrence of recesses after keystrokes and the adhesion of contaminants after keystrokes were sufficiently inhibited, and the rub resistance was excellent as well.

As described in the following Table 4, all of Examples 1 to 22 and 32 to 34, in which the surface roughness Sa (visual field for measurement: 4 mm×5 mm) of the HC layer on the viewing side in the optical film according to the embodiment of the present invention that was in a laminated state was within a specific range, exhibited excellent glass quality.

TABLE 4

| | Surface roughness Sa | Glass quality |
|---|---|---|
| Example 1 | 13 nm | B |
| Example 2 | 13 nm | B |
| Example 3 | 13 nm | B |
| Example 4 | 13 nm | B |
| Example 5 | 13 nm | B |
| Example 6 | 13 nm | B |
| Example 7 | 13 nm | B |
| Example 8 | 13 nm | B |
| Example 9 | 13 nm | B |
| Example 10 | 13 nm | B |
| Example 11 | 13 nm | B |
| Example 12 | 13 nm | B |
| Example 13 | 5 nm | A |
| Example 14 | 5 nm | A |
| Example 15 | 13 nm | B |
| Example 16 | 13 nm | B |
| Example 17 | 13 nm | B |
| Example 18 | 13 nm | B |
| Example 19 | 13 nm | B |
| Example 20 | 13 nm | B |
| Example 21 | 12 nm | B |
| Example 22 | 22 nm | C |
| Example 32 | 13 nm | B |
| Example 33 | 13 nm | B |
| Example 34 | 13 nm | B |

It is considered that in a case where the optical film according to the embodiment of the present invention is used in a front panel of an image display apparatus, an image display apparatus, a mirror with an image display function, a resistive film-type touch panel, and a capacitance-type touch panel, in the front panel and the like, the occurrence of recesses after keystrokes and the adhesion of contaminants after keystrokes may be sufficiently inhibited, and excellent rub resistance may be exhibited.

### Examples 23 to 26, 29 to 31, and 35 to 40

In the following manner, optical films of Examples 23 to 26, 29 to 31, and 35 to 40 were prepared in which a cushioning layer, a resin film, and an HC layer were laminated in this order.

(1) Preparation of Composition for Forming Cushioning Layer (Cu Layer)

Components were mixed together according to the composition described in the following Table 5 and filtered through a filter made of polypropylene having a pore size of 10 μm, thereby preparing compositions CU-1 to CU-11 for forming a cushioning layer (Cu layer).

TABLE 5

| | | Composition for forming cushioning layer | | | | | | | | | | |
|---|---|---|---|---|---|---|---|---|---|---|---|---|
| | | CU-1 | CU-2 | CU-3 | CU-4 | CU-5 | CU-6 | CU-7 | CU-8 | CU-9 | CU-10 | CU-11 |
| Resin | VYLON | 100% | | | | | | | | | | |
| | UR-6100 | | | | | | | | | | | |
| | KURARITY | | 100% | | | | | | | | | |
| | LA2250 | | | | | | | | | | | |
| | KURARITY | | | 100% | 95% | 85% | 70% | | 90% | | | |
| | LA2140E | | | | | | | | | | | |
| | HYBRAR 7311F | | | | | | | 100% | | | | |
| | KURAPRENE | | | | | | | | | 87% | 67% | 47% |
| | UC-203M | | | | | | | | | | | |
| | DPHA | | | | | | | | | | 20% | 40% |
| Inorganic | MIBK-ST | | | | 5% | 15% | 30% | | | | | |
| particles | | | | | | | | | | | | |
| Additive | SUPER ESTER | | | | | | | | 10% | | | |
| | A115 | | | | | | | | | | | |
| | CLEARON P150 | | | | | | | | | 10% | 10% | 10% |
| Polymerization | Irg184 | | | | | | | | | 3% | 3% | 3% |
| initiator | | | | | | | | | | | | |
| Solvent | MIBK | | 100% | 100% | 100% | 100% | 100% | | 100% | | | |
| | Toluene | | | | | | | 100% | | 100% | 100% | 100% |

| | | | | | | | | | | | |
|---|---|---|---|---|---|---|---|---|---|---|---|
| Solid contents | 45% | 25% | 25% | 25% | 25% | 25% | 25% | 25% | 50% | 50% | 50% |

The details of each compound described in Table 5 are as below.

<Resin>

VYLON UR-6100: manufactured by Toyobo Co., Ltd, 45% diluted solution of polyester urethane resin (composition of dilution solvents: cyclohexanone:SOLVESSO 150:isophorone=40:40:20 (mass ratio))

KURARITY LA2250: manufactured by KURARAY CO., LTD., PMMA-PnBA copolymer elastomer

KURARITY LA2140E: manufactured by KURARAY CO., LTD., PMMA-PnBA copolymer elastomer

HYBRAR 7311F: manufactured by KURARAY CO., LTD., polystyrene-hydrogenated isoprene copolymer elastomer

KURAPRENE UC-203M: manufactured by KURARAY CO., LTD., polymerizable group-containing polyisoprene

DPHA: mixture of dipentaerythritol pentaacrylate and pentaerythritol hexaacrylate (manufactured by Nippon Kayaku Co., Ltd., trade name: KAYARAD DPHA)

<Inorganic Particles>

MIBK-ST: manufactured by Nippon Kayaku Co., Ltd., spherical silica particles having average particle diameter of 10 to 20 nm

<Polymerization Initiator>

Irg 184: 1-hydroxy-cyclohexyl-phenyl-ketone (a-hydroxyalkylphenone-based radical photopolymerization initiator, manufactured by BASF SE, trade name: IRGACURE 184)

<Additives>

SUPER ESTER A-115: manufactured by Arakawa Chemical Industries. Ltd., rosin ester

CLEARON P150: manufactured by YASUHARA CHEMICAL CO., LTD., hydrogenated terpene

In Table 5, the amount of each component is described such that the total amount of solid contents and solvents becomes 100% by mass.

(2) Preparation of Cushioning Layer

The surface on the resin film side in the optical film (resin film with an HC layer) of Example 20 was coated with the compositions CU-1 to CU-11 for forming a CU layer, and the compositions were dried, thereby forming a Cu layer.

Specifically, coating and curing were performed by the following method. By a die coating method using a slot die described in Example 1 in JP2006-122889A, coating was performed using the composition for forming a Cu layer under the condition of a transport speed of 30 m/min such that the film thickness became 20 μm after drying, and the composition was dried for 150 seconds at an atmospheric temperature of 60° C., thereby preparing optical films of Examples 23 to 26, 29 to 31, and 35 to 38.

### Example 27

An optical film of Example 27 was prepared in the same manner as in Example 26, except that coating was performed using the composition for forming a Cu layer such that the film thickness became 5 μm after drying.

### Example 28

An optical film of Example 28 was prepared in the same manner as in Example 26, except that coating was performed using the composition for forming a Cu layer such that the film thickness became 40 m after drying.

### Example 39

An optical film of Example 39 was prepared in the same manner as in Example 38, except that the first HC layer was prepared using the curable composition HC-20 for forming an HC layer.

### Example 40

An optical film of Example 40 was prepared in the same manner as in Example 38, except that the first HC layer was prepared using the curable composition HC-21 for forming an HC layer.

The optical films prepared as above were tested as below. The test results are summarized in the following Table 6.

### [Test Example 6] Cushioning Properties 1

A glass plate (manufactured by Corning Incorporated, trade name: EAGLE XG, thickness: 0.4 mm) and the optical film of Example 23 or the optical film of Example 20 prepared as above were bonded to each other through a pressure sensitive adhesive having a thickness of 20 μm (manufactured by Soken Chemical & Engineering Co., Ltd., trade name: SK-2057) by using a rubber roller under a load of 2 kg applied thereto such that a surface of the optical film that was opposite to the HC layer and the glass plate faced each other. Then, the glass plate bonded to the optical film was installed on a base formed of stainless steel such that the glass plate contacted the base. This state is shown in FIG. 7. In FIG. 7, a base 301, a glass plate 303, a pressure sensitive adhesive layer 304, a Cu layer 305 (Example 23), a resin film 306, and an HC layer 307 are laminated in this order. Thereafter, an iron ball (diameter: 3.3 cm, mass: 150 g) was allowed to fall from a predetermined height such that the iron ball contacted and collided with the HC layer of the optical film. Subsequently, the glass plate was observed. Among the heights from which the iron ball fell and did not result in observable fissures, cracks, and the like, the greatest height was adopted as an impact resistance height (cm), and the cushioning properties were evaluated.

### [Test Example 7] Cushioning Properties 2

A glass plate (manufactured by Corning Incorporated, trade name: EAGLE XG, thickness: 0.4 mm, 10 cm×10 cm) and the optical film of each of Examples 23 to 31 and 35 to 40 or the optical film of Example 20 prepared as above were bonded to each other through a pressure sensitive adhesive having a thickness of 20 μm (manufactured by Soken Chemical & Engineering Co., Ltd., trade name: SK-2057) by using a rubber roller under a load of 2 kg applied thereto such that a surface of the optical film that was opposite to the HC layer and the glass plate faced each other. Then, the glass plate bonded to the optical film was installed on a base formed of stainless steel such that a spacer made of TEFLON (registered trademark) having a thickness of 20 mm and a width of 5 mm (a spacer of a shape obtained by punching the central portion of a 10 cm×10 cm spacer in a size of 9 cm×9 cm) was interposed between the glass plate and the stainless steel base. This state is shown in FIG. 8. In FIG. 8, a base 301, a spacer 302, a glass plate 303, a pressure sensitive adhesive layer 304, a Cu layer 305 (Examples 23 to 31 and 35), a resin film 306, and an HC layer 307 are laminated in this order. Thereafter, an iron ball (diameter: 3.2 cm, mass: 130 g) was allowed to fall from a predetermined height such that the iron ball contacted and collided with the HC layer of the optical film. Subsequently, the glass plate was observed. Among the heights from which the iron ball fell and did not result in observable fissures, cracks, and the like, the greatest height was adopted as an impact resistance height (cm), and the cushioning properties were evaluated.

### [Test Example 8] Pencil Hardness

Pencil hardness was evaluated according to JIS K 5400 (JIS stands for Japanese Industrial Standards).

The optical film of each of the examples was humidified for 2 hours at a temperature of 25° C. and a relative humidity of 60%, and then 5 different sites within the surface of the HC layer were scratched under a load of 4.9 N by using a testing pencil with hardness of H to 9H specified in JIS S 6006. Then, among the hardnesses of the pencil by which a visually recognized scratch was formed at 0 to 2 sites, the highest pencil hardness was taken as an evaluation result.

It is preferable that the numerical value described before “H” is high, because then the pencil hardness is high.

As a result of test for cushioning properties 1, as described in the following Table 6, among the optical films according to the embodiment of the present invention, the optical film of Example 20 did not experience the occurrence of cracks on the glass up to the height of 60 cm. Furthermore, the optical film of Example 23, in which the cushioning layer was provided on the surface (surface opposite to the HC layer) of the resin film, did not experience the occurrence of cracks on the glass up to the height of 140 cm and exhibited excellent cushioning properties.

TABLE 6

| | Cushioning layer | | |
|---|---|---|---|
| | Formulation | Film thickness | Cushioning properties |
| Example 20 | N/A | N/A | 60 cm |
| Example 23 | CU-1 | 20 μm | 140 cm |

As a result of test for cushioning properties 2, as described in the following Table 7, among the optical films according to the embodiment of the present invention, the optical films of Examples 23 to 31 and 35 to 40, in which the cushioning layer was provided on the surface (surface opposite to the HC layer) of the resin film, exhibited excellent cushioning properties.

TABLE 7

| | Cushioning layer | | | | | | |
|---|---|---|---|---|---|---|---|
| | | | Frequency at peak | Storage | | | |
| | | Film | tan δ | modulus | | Pencil | Cushioning |
| | Formulation | thickness | (Hz) | [MPa] | Peak tan δ | hardness | properties 2 |
| Example 20 | N/A | N/A | N/A | N/A | N/A | 5H | 5 cm |
| Example 23 | CU-1 | 20 μm | 1.0 × 10⁶ | 3,200 | 0.1 | 5H | 10 cm |
| Example 24 | CU-2 | 20 μm | 2.8 × 10⁷ | 400 | 0.5 | 5H | 30 cm |
| Example 25 | CU-3 | 20 μm | 1.6 × 10⁷ | 40 | 1.4 | 3H | 50 cm |
| Example 26 | CU-4 | 20 μm | 1.6 × 10⁷ | 60 | 1.3 | 4H | 50 cm |
| Example 27 | CU-4 | 5 μm | 1.6 × 10⁷ | 60 | 1.3 | 5H | 20 cm |
| Example 28 | CU-4 | 40 μm | 1.6 × 10⁷ | 60 | 1.3 | 5H | 70 cm |
| Example 29 | CU-5 | 20 μm | 1.6 × 10⁷ | 100 | 1.2 | 5H | 50 cm |
| Example 30 | CU-6 | 20 μm | 1.6 × 10⁷ | 200 | 0.7 | 5H | 30 cm |
| Example 31 | CU-7 | 20 μm | 3.1 × 10³ | 210 | 2.2 | 2H | 70 cm |
| Example 35 | CU-8 | 20 μm | 1.1 × 10⁵ | 20 | 1.6 | 5H | 50 cm |
| Example 36 | CU-9 | 20 μm | 2.5 × 10⁵ | 10 | 2.4 | 5H | 50 cm |
| Example 37 | CU-10 | 20 μm | 7.0 × 10⁴ | 30 | 1.9 | 5H | 40 cm |
| Example 38 | CU-11 | 20 μm | 2.0 × 10⁴ | 70 | 1.2 | 5H | 30 cm |
| Example 39 | CU-11 | 20 μm | 2.0 × 10⁴ | 70 | 1.2 | 7H | 30 cm |
| Example 40 | CU-11 | 20 μm | 2.0 × 10⁴ | 70 | 1.2 | 9H | 30 cm |

### EXPLANATION OF REFERENCES

1A: resin film
2A: hardcoat layer (HC layer)
3A: pressure sensitive adhesive layer
4A, 4B: optical film
1: conductive film for touch panel
2: touch panel
3: pressure sensitive adhesive layer
4C: optical film
5: transparent insulating substrate
6A, 6B: conductive member
7A, 7B: protective layer
8: first conductive layer
9: second conductive layer
11A: first dummy electrode
11: first electrode
12: first peripheral wiring
13: first external connection terminal
14: first connector portion
15: first metal thin wire
21: second electrode
22: second peripheral wiring
23: second external connection terminal
24: second connector portion
25: second metal thin wire
C1: first cell
C2: second cell
D1: first direction
D2: second direction
M1: first mesh pattern
M2: second mesh pattern
S1: active area
S2: peripheral region

What is claimed is:

1. An optical film comprising:
a resin film; and
a hardcoat layer disposed on one surface of the resin film,
wherein the hardcoat layer contains a polysiloxane-containing compound and a fluorine-containing compound, and
a film thickness of the resin film is equal to or greater than 80 μm.

2. The optical film according to claim 1,
wherein within a surface of the hardcoat layer that is opposite to the resin film, a surface roughness Sa in a visual field of 4 mm×5 mm for measurement is equal to or lower than 60 nm.

3. The optical film according to claim 1,
wherein the hardcoat layer is formed by polymerizing and curing the polysiloxane-containing compound having a polymerizable group in a molecule, the fluorine-containing compound having a polymerizable group in a molecule, and a polymerizable compound which is neither the polysiloxane-containing compound nor the fluorine-containing compound and has a polymerizable group in a molecule.

4. The optical film according to claim 3,
wherein the polymerizable group that each of the polysiloxane-containing compound, the fluorine-containing compound, and the polymerizable compound has is a radically polymerizable group.

5. The optical film according to claim 1,
wherein the film thickness of the resin film is equal to or greater than 100 μm.

6. The optical film according to claim 1,
wherein the film thickness of the resin film is equal to or greater than 150 μm.

7. The optical film according to claim 1,
wherein the film thickness of the resin film is equal to or greater than 200 μm.

8. The optical film according to claim 1,
wherein the resin film contains a cellulose ester resin.

9. The optical film according to claim 1, further comprising:
a cushioning layer on a surface of the resin film that is opposite to the surface of the resin film that is provided with the hardcoat layer.

10. The optical film according to claim 9,
wherein the cushioning layer is constituted with at least one kind of resin selected from a urethane-modified polyester resin and a urethane resin.

11. The optical film according to claim 9,
wherein provided that a ratio of a loss modulus to a storage modulus is represented by tan δ, the cushioning layer has a peak of tan δ within a frequency range of 10 to 10¹⁵ Hz at 25° C.

12. The optical film according to claim 11,
wherein the cushioning layer is constituted with at least one kind of resin selected from a (meth)acrylate resin and an elastomer.

13. The optical film according to claim 11,
wherein the cushioning layer contains at least one kind of copolymer selected from a block copolymer of methyl methacrylate and n-butyl acrylate and a block copolymer of isoprene and/or butene and styrene.

14. The optical film according to claim 11,
wherein the cushioning layer is further constituted with a polymerizable group-containing compound.

15. The optical film according to claim 1,
wherein the hardcoat layer further contains inorganic particles, and a content rate of the inorganic particles in the hardcoat layer is less than 8% by mass.

16. The optical film according to claim 9,
wherein the cushioning layer contains a filler.

17. The optical film according to claim 16,
wherein the filler is silica particles.

18. A front panel of an image display apparatus, comprising:
the optical film according to claim 1.

19. An image display apparatus comprising:
the front panel according to claim 18, and
an image display device.

20. The image display apparatus according to claim 19,
wherein the image display device is a liquid crystal display device.

21. The image display apparatus according to claim 19,
wherein the image display device is an organic electroluminescence display device.

22. The image display apparatus according to claim 19,
wherein the image display device is an in-cell touch panel display device.

23. The image display apparatus according to claim 19,
wherein the image display device is an on-cell touch panel display device.

24. A resistive film-type touch panel comprising:
the front panel according to claim 18.

25. A capacitance-type touch panel comprising:
the front panel according to claim 18.

26. A mirror with an image display function comprising:
the image display apparatus according to claim 19.
